(19) United States
(12) Patent Application Publication
(10) Pub. No.: US 2025/0015002 A1
(43) Pub. Date: Jan. 9, 2025

(54) SEMICONDUCTOR MODULE, METHOD OF MANUFACTURING THE SAME, ELECTRONIC APPARATUS, ELECTRONIC MODULE, AND METHOD OF MANUFACTURING ELECTRONIC APPARATUS

(71) Applicant: AOI ELECTRONICS CO., LTD., Takamatsu-shi, Kagawa (JP)

(72) Inventor: Yoichiro KURITA, Tokyo (JP)

(21) Appl. No.: 18/684,440

(22) PCT Filed: Aug. 17, 2022
(86) PCT No.: PCT/JP2022/031116

§ 371 Date: Sep. 18, 2024

(30) Foreign Application Priority Data
Aug. 20, 2021 (JP) 2021-135043
Mar. 2, 2022 (JP) 2022-032024

(51) Int. Cl. H01L 23/538; G02B 6/42; G02B 6/43; H01L 21/48; H01L 21/56; H01L 23/00; H01L 23/29; H01L 23/31; H01L 23/367; H01L 25/16

(52) U.S. Cl. CPC H01L 23/5381; H01L 21/4853; H01L 21/4857; H01L 21/565; H01L 23/295; H01L 23/3128; H01L 23/5386; H01L 24/32; H01L 24/80; G02B 6/4214; G02B 6/43; H01L 23/3677; H01L 24/16; H01L 24/73; H01L 24/96; H01L 24/97; H01L 25/167; H01L 2224/16227; H01L 2224/32137; H01L 2224/32225; H01L 2224/73204; H01L 2224/80895; H01L 2224/80896; H01L 2224/96; H01L 2224/97; H01L 2924/1815

(57) ABSTRACT

In a method of manufacturing a semiconductor module, a first die including a first die electrode, a second die including a second die electrode, a first connection section connected to the first die electrode, and a second connection section connected to the second die electrode are sealed by a sealing body, and then, a bridge including a first bridge electrode and a second bridge electrode is mounted on a structure sealed by the sealing body. The first die and the second die are electrically connected via the bridge.

### CROSS-REFERENCE TO RELATED APPLICATIONS

This application is a National Stage application of International Patent Application No. PCT/JP2022/031116, filed on Aug. 17, 2022, which claims priority to Japanese Patent Applications No. 2021-135043, filed on Aug. 20, 2021, and No. 2022-032024, filed on Mar. 2, 2022, each of which is hereby incorporated by reference in its entirety.

### TECHNICAL FIELD

The present invention relates to a semiconductor module and a method of manufacturing the same.

### BACKGROUND

There are techniques of connecting a plurality of IC (integrated circuit) chips. For example, a Patent Document 1 describes a semiconductor package in which two IC chips are connected by a bridge (nested component) molded with an interposer. A Patent Document 2 describes a semiconductor package in which two IC chips are electrically connected via a bridge unified with an interposer via an underfill material.
Patent Document 1: U.S. Patent Application Laid-open Publication No. 2021/0005542
Patent Document 2: U.S. Patent Application Laid-open Publication No. 2020/0395313

### SUMMARY

### Problems to be Solved by the Invention

As a result of the studies made by the present inventors regarding a semiconductor package including a plurality of IC chips connected via a bridge and a semiconductor module using the semiconductor package, it has been found out that the semiconductor package and the semiconductor module have room to be improved. For example, when two IC chips are electrically connected via a bridge unified with an interposer, it is difficult to accurately positionally align each terminal of the two IC chips and a terminal of the bridge. In this case, higher density at the terminals electrically connecting the IC chips and the bridge is restricted.

The present invention has been made under such circumstances, and a typical object of one aspect of the present invention is to provide a technique capable of coupling the IC chips and the bridge at higher density.

### Means for Solving the Problems

A method of manufacturing a semiconductor module according to one embodiment includes: a step (a) of, on a first surface of a first support body, forming a first connection section including a first pillar connection section extending in an out-of-surface direction of the first surface and a second connection section including a second pillar connection section extending in an out-of-surface direction of the first surface; a step (b) of preparing a first semiconductor die including a first IC chip and a first die electrode connected to the first IC chip and a second semiconductor die including a second IC chip and a second die electrode connected to the second IC chip, and mounting the first semiconductor die and the second semiconductor die on the first support body such that the first die electrode is arranged on the first connection section while the second die electrode is arranged on the second connection section; a step (c) of sealing the first semiconductor die, the second semiconductor die, the first connection section, and the second connection section by a first sealing body after the step (b); a step (d) of removing the first support body, and exposing a part of the first pillar connection section and a part of the second pillar connection section from the first sealing body after the step (c); and a step (e) of preparing a bridge including a first bridge electrode connected to the first connection section and a second bridge electrode connected to the second connection section, and mounting the bridge on a structure sealed by the first sealing body such that the first bridge electrode is arranged on the first pillar connection section while the second bridge electrode is arranged on the second pillar connection section after the step (d).

A method of manufacturing a semiconductor module according to another embodiment includes: a step (a) of forming a first insulative layer on a first surface of a first support body, and then, forming a first opening and a second opening in the first insulative layer; a step (b) of forming a first connection section including a first pillar connection section formed inside the first opening and a second connection section including a second pillar connection section formed inside the second opening; a step (c) of preparing a first semiconductor die including a first IC chip, a first die electrode connected to the first IC chip, and a second insulative layer sealing the first die electrode, and a second semiconductor die including a second IC chip, a second die electrode connected to the second IC chip, and a third insulative layer sealing the second die electrode, and mounting the first semiconductor die and the second semiconductor die on the first support body such that the first die electrode is arranged on the first connection section while the second die electrode is arranged on the second connection section; a step (d) of sealing the first semiconductor die and the second semiconductor die by a first sealing body after the step (c); a step (e) of removing the first support body, and exposing a part of the first pillar connection section and a part of the second pillar connection section from the first insulative layer after the step (d); and a step (f) of preparing a bridge including a first bridge electrode connected to the first connection section and a second bridge electrode connected to the second connection section, and mounting the bridge on a structure sealed by the first sealing body such that the first bridge electrode is arranged on the first pillar connection section while the second bridge electrode is arranged on the second pillar connection section after the step (e). In the step (c), the first insulative layer and the second insulative layer are bonded to each other, and the first die electrode is sealed by the first insulative layer and the second insulative layer. In the step (c), the first insulative layer and the third insulative layer are bonded to each other, and the second die electrode is sealed by the first insulative layer and the third insulative layer.

A semiconductor module according to another embodiment includes: a first semiconductor die including a first IC chip and a first die electrode connected to the first IC chip; a second semiconductor die including a second IC chip and a second die electrode connected to the second IC chip; a first connection section electrically connected to the first die electrode; a second connection section electrically connected to the second die electrode; a bridge including a first bridge electrode connected to the first connection section and a second bridge electrode connected to the second connection section; and a first sealing body sealing the first semiconductor die and the second semiconductor die. The first connection section includes a first pillar connection section which is arranged between the first semiconductor die and the bridge and which extends in a direction from one of the first semiconductor die and the bridge toward the other of the first semiconductor die and the bridge. The first connection section includes a second pillar connection section which is arranged between the first semiconductor die and the bridge and which extends in a direction from one of the first semiconductor die and the bridge toward the other of the first semiconductor die and the bridge. The first bridge electrode and the second bridge electrode are exposed from the first sealing body. The first pillar connection section and the second pillar connection section are sealed by the first sealing body.

Another aspect of the present invention relates to an electronic apparatus. The electronic apparatus includes: a first die including a first electrode; a second die including a second electrode; a first connection section electrically connected to the first electrode; a second connection section electrically connected to the second electrode; and a bridge electrically connected to the first connection section and the second connection section. The first connection section includes a pillar connection section facing in a direction from the bridge toward the first die.

Another aspect of the present invention relates to an electronic module. The electronic module includes: the electronic apparatus; a wiring layer provided with a wiring therein; and a pillar connection section electrically connecting the wiring and the electronic apparatus.

Another aspect of the present invention relates to a method of manufacturing an electronic apparatus. The method of manufacturing the electronic apparatus includes: a forming step of, on a support body, forming a first connection section including a pillar connection section having a pillar shape and protruding from the support body, and a second connection section; a die coupling step of coupling a first electrode of a first die to the first connection section and coupling a second electrode of a second die to the second connection section; a sealing step of sealing the first die, the second die, and the first connection section by resin; and a bridge coupling step of coupling a bridge to a lower part of the first connection section and a lower part of the second connection section.

Note that any combination of the above components and exchange of expressions of the present invention in terms of method, apparatus, system, recording medium, computer program, and the like are also effective as aspects of the present invention.

### Effects of the Invention

According to the embodiments described above, an IC chip and a bridge can be coupled at higher density.

### BRIEF DESCRIPTIONS OF THE DRAWINGS

FIG. 1 is a schematic diagram of a chip integrated system according to one embodiment.

FIG. 2 is a perspective view illustrating an exemplary configuration of a chip integrated body illustrated in FIG. 1.

FIG. 3 is an explanatory diagram illustrating an exemplary configuration of the chip integrated body illustrated in FIG. 2.

FIG. 4 is an enlarged cross-sectional view illustrating an exemplary configuration of a part of a chip integrated module illustrated in FIG. 3.

FIG. 5 is an explanatory diagram schematically illustrating an exemplary configuration of an optical module illustrated in FIG. 3.

FIG. 6 is an explanatory diagram illustrating an outline of a method of manufacturing a chip integrated module according to a study example of one embodiment.

FIG. 7 is an explanatory diagram illustrating an outline of steps of manufacturing the chip integrated module illustrated in FIG. 4.

FIG. 8 is an enlarged cross-sectional view illustrating details of a connection-section forming step illustrated in FIG. 7.

FIG. 9 is an enlarged cross-sectional view illustrating details of the connection-section forming step continued from FIG. 8.

FIG. 10 is an enlarged cross-sectional view illustrating details of the connection-section forming step continued from FIG. 9.

FIG. 11 is an enlarged cross-sectional view illustrating details of the connection-section forming step continued from FIG. 10.

FIG. 12 is an enlarged cross-sectional view illustrating details of the connection-section forming step continued from FIG. 11.

FIG. 13 is an enlarged cross-sectional view illustrating details of a semiconductor-die mounting step illustrated in FIG. 7.

FIG. 14 is an enlarged cross-sectional view illustrating details of the semiconductor-die mounting step continued from FIG. 13.

FIG. 15 is an enlarged cross-sectional view illustrating details of the semiconductor-die mounting step continued from FIG. 14.

FIG. 16 is an enlarged cross-sectional view illustrating details of a first sealing step illustrated in FIG. 7.

FIG. 17 is an enlarged cross-sectional view illustrating details of a support-body removing step illustrated in FIG. 7.

FIG. 18 is an enlarged cross-sectional view illustrating details of a connection-section exposing step illustrated in FIG. 7.

FIG. 19 is an enlarged cross-sectional view illustrating details of the connection-section exposing step continued from FIG. 18.

FIG. 20 is an enlarged cross-sectional view illustrating details of a bridge mounting step illustrated in FIG. 7.

FIG. 21 is an enlarged cross-sectional view illustrating details of the bridge mounting step continued from FIG. 20.

FIG. 22 is an enlarged cross-sectional view illustrating details of the bridge mounting step continued from FIG. 21.

FIG. 23 is an enlarged cross-sectional view illustrating details of a second sealing step illustrated in FIG. 7.

FIG. 24 is an enlarged cross-sectional view illustrating a modification example of FIG. 23.

FIG. 25 is an enlarged cross-sectional view illustrating a modification example of the sealing body illustrated in FIG. 4.

FIG. 26 is an enlarged cross-sectional view illustrating another modification example of the sealing body illustrated in FIG. 4.

FIG. 27 is an enlarged cross-sectional view illustrating still another modification example of the sealing body illustrated in FIG. 4.

FIG. 28 is an enlarged cross-sectional view illustrating a chip integrated module according to a modification example of FIG. 4.

FIG. 29 is an explanatory diagram illustrating an outline of steps of manufacturing the chip integrated module illustrated in FIG. 28.

FIG. 30 is an enlarged cross-sectional view illustrating details of an insulative-layer forming step illustrated in FIG. 29.

FIG. 31 is an enlarged cross-sectional view illustrating details of the insulative-layer forming step continued from FIG. 30.

FIG. 32 is an enlarged cross-sectional view illustrating details of a connection-section forming step illustrated in FIG. 29.

FIG. 33 is an enlarged cross-sectional view illustrating details of a semiconductor-die mounting step illustrated in FIG. 29.

FIG. 34 is an enlarged cross-sectional view illustrating details of the semiconductor-die mounting step continued from FIG. 33.

FIG. 35 is an enlarged cross-sectional view illustrating details of the semiconductor-die mounting step continued from FIG. 34.

FIG. 36 is an enlarged cross-sectional view illustrating details of a sealing step illustrated in FIG. 29.

FIG. 37 is an enlarged cross-sectional view illustrating details of a connection-section exposing step illustrated in FIG. 29.

FIG. 38 is an enlarged cross-sectional view illustrating details of the connection-section exposing step continued from FIG. 37.

FIG. 39 is an enlarged cross-sectional view illustrating details of a bridge mounting step illustrated in FIG. 29.

FIG. 40 is an enlarged cross-sectional view illustrating details of the bridge mounting step continued from FIG. 39.

FIG. 41 is an enlarged cross-sectional view illustrating details of the bridge mounting step continued from FIG. 40.

FIG. 42 is an explanatory diagram illustrating a modification example of the chip integrated body illustrated in FIG. 3.

FIG. 43 is an explanatory diagram illustrating another modification example of the chip integrated body illustrated in FIG. 3.

FIG. 44 is a cross-sectional view illustrating a modification example of the bridge illustrated in FIG. 4.

FIG. 45 is a cross-sectional view illustrating an outline of a wiring layer forming step in steps of manufacturing the bridge illustrated in FIG. 44.

FIG. 46 is a cross-sectional view illustrating an outline of a wiring-layer transferring step in the steps of manufacturing the bridge illustrated in FIG. 44.

FIG. 47 is a cross-sectional view illustrating an outline of a support-body removing step in the steps of manufacturing the bridge illustrated in FIG. 44.

FIG. 48 is an explanatory diagram illustrating another modification example of the bridge illustrated in FIG. 4.

FIG. 49 is a diagram illustrating a configuration of a part of a chip integrated module according to a modification example of FIG. 4.

FIG. 50 is a diagram illustrating a configuration of a chip integrated module according to a first modification example of the chip integrated module illustrated in FIG. 49.

FIG. 51 is a diagram illustrating a configuration of a chip integrated module according to a second modification example of the chip integrated module illustrated in FIG. 49.

FIG. 52 is a diagram illustrating a configuration of a chip integrated module according to a third modification example of the chip integrated module illustrated in FIG. 49.

FIG. 53 is a diagram illustrating a configuration of a chip integrated module according to a fourth modification example of the chip integrated module illustrated in FIG. 49.

FIG. 54 is a diagram illustrating a configuration of a chip integrated module according to a fifth modification example of the chip integrated module illustrated in FIG. 49.

FIG. 55 is a diagram for explaining a method of manufacturing a chip integrated module according to another embodiment.

FIG. 56 is a diagram for explaining the method of manufacturing the chip integrated module according to the embodiment.

FIG. 57 is a diagram for explaining the method of manufacturing the chip integrated module according to the embodiment.

FIG. 58 is a diagram for explaining the method of manufacturing the chip integrated module according to the embodiment.

FIG. 59 is a diagram for explaining the method of manufacturing the chip integrated module according to the embodiment.

FIG. 60 is a diagram for explaining the method of manufacturing the chip integrated module according to the embodiment.

FIG. 61 is a diagram for explaining a method of manufacturing a chip integrated module according to a sixth modification example of the method of manufacturing the chip integrated module illustrated in FIGS. 55 to 60.

FIG. 62 is a diagram for explaining the method of manufacturing the chip integrated module according to the sixth modification example of the method of manufacturing the chip integrated module illustrated in FIGS. 55 to 60.

FIG. 63 is a diagram for explaining the method of manufacturing the chip integrated module according to the sixth modification example of the method of manufacturing the chip integrated module illustrated in FIGS. 55 to 60.

FIG. 64 is a diagram for explaining the method of manufacturing the chip integrated module according to the sixth modification example of the method of manufacturing the chip integrated module illustrated in FIGS. 55 to 60.

FIG. 65 is a diagram for explaining a method of manufacturing a chip integrated module according to a seventh modification example of the method of manufacturing the chip integrated module illustrated in FIGS. 55 to 60.

FIG. 66 is a diagram for explaining the method of manufacturing the chip integrated module according to the seventh modification example of the method of manufacturing the chip integrated module illustrated in FIGS. 55 to 60.

FIG. 67 is a diagram for explaining a method of manufacturing a chip integrated module according to an eighth modification example of the method of manufacturing the chip integrated module illustrated in FIGS. 55 to 60.

FIG. 68 is a diagram for explaining the method of manufacturing the chip integrated module according to the eighth modification example of the method of manufacturing the chip integrated module illustrated in FIGS. 55 to 60.

FIG. 69 is a diagram for explaining the method of manufacturing the chip integrated module according to the eighth modification example of the method of manufacturing the chip integrated module illustrated in FIGS. 55 to 60.

FIG. 70 is a diagram for explaining a method of manufacturing an optical module according to one embodiment.

FIG. 71 is a diagram for explaining the method of manufacturing the optical module according to the embodiment.

FIG. 72 is a diagram for explaining the method of manufacturing the optical module according to the embodiment.

FIG. 73 is a diagram for explaining the method of manufacturing the optical module according to the embodiment.

FIG. 74 is a diagram for explaining the method of manufacturing the optical module according to the embodiment.

FIG. 75 is a diagram for explaining a method of manufacturing a chip integrated body according to another embodiment.

FIG. 76 is a diagram for explaining the method of manufacturing the chip integrated body according to the embodiment.

FIG. 77 is a diagram for explaining the method of manufacturing the chip integrated body according to the embodiment.

FIG. 78 is a diagram for explaining the method of manufacturing the chip integrated body according to the embodiment.

FIG. 79 is a diagram for explaining the method of manufacturing the chip integrated body according to the embodiment.

FIG. 80 is a diagram illustrating an exemplary configuration of an integrated circuit chip according to one embodiment.

### DETAILED DESCRIPTION

Embodiments of the present invention will be described below with reference to the drawings. In the following description, a structure in which a circuit element such as a transistor or a wiring is formed on a semiconductor substrate is called IC chip. The IC chips include a superconductive integrated circuit (quantum computer) and the like. A structure including a wiring layer stacked on a main surface of the IC chip is called semiconductor die. A redistribution layer may be additionally formed on the IC chip. In this case, the redistribution layer is included in the wiring layer. A structure in which a plurality of semiconductor dies are sealed and unified by a sealing body is called chip integrated module. A bridge electrically connecting the plurality of semiconductor dies to each other is also included in the chip integrated module. A structure in which the plurality of modules including the chip integrated modules are unified is called chip integrated body. The chip integrated body may include a module such as an optical module in addition to the chip integrated module. The chip integrated body may include a plurality of the chip integrated modules. Further, the chip integrated body may include a wide-range wiring layer electrically connecting the plurality of modules, or a heat radiating mechanism or heat radiating member having a function to radiate heat generated in each module to the outside. A part of the chip integrated body except for the radiating part is called integrated layer. In the following description, the chip integrated module will be exemplified as an exemplary semiconductor module. Further, the integrated layer will be exemplified as an exemplary semiconductor package.

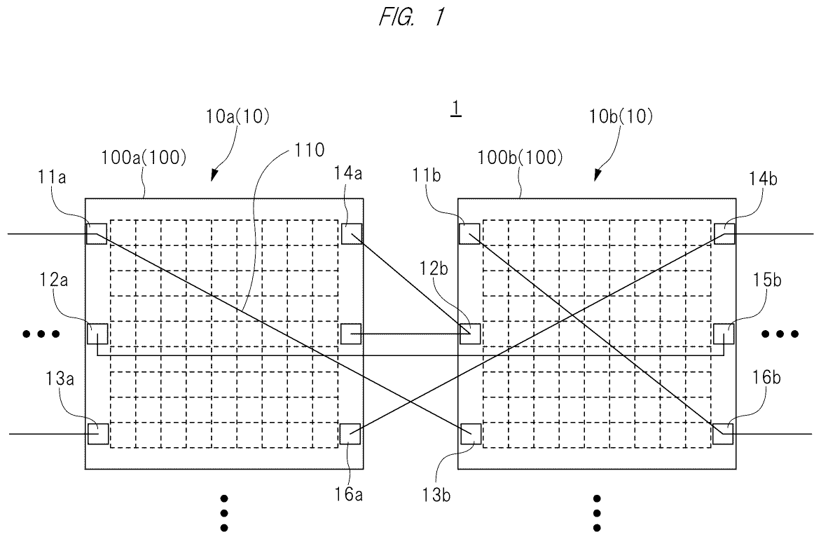

However, a scope of the semiconductor module and a scope of the semiconductor package are not limited to the above definitions. For example, as illustrated in FIG. 1 described later, a chip integrated body 10 is single electronic component (module) embedded in a chip integrated system 1. In this case, the chip integrated body 10 can be regarded as the semiconductor module embedded in the chip integrated system 1. Further, each of the chip integrated module, the integrated layer, and the chip integrated body described later may be available as a distributed semiconductor package including and packaging the IC chip therein. Thus, each of the forms of the chip integrated module, the integrated layer, and the chip integrated body can be regarded as the semiconductor package.

### Chip Integrated System

FIG. 1 is a schematic diagram of a chip integrated system according to one embodiment of the present invention. The chip integrated system 1 according to the present embodiment includes a plurality of chip integrated bodies 10. The chip integrated bodies 10 are mutually connected by an optical wiring 110. The optical wiring may connect, for example, different chip integrated bodies, or may be used to connect different parts in the chip integrated body if a scale of the chip integrated body is large. The chip integrated system 1 may be available for, for example, an artificial intelligence system in which various processors and memories are sophisticatedly integrated. Although FIG. 1 illustrates two chip integrated bodies 10a and 10b, note that the chip integrated system 1 may include three or more chip integrated bodies 10, or the chip integrated system 1 may include only one chip integrated body 10.

The chip integrated body 10 is an integrated body including a plurality of chip integrated modules therein. A size of the chip integrated module may be, for example, around 50 mm square up to around 300 mm square although not particularly limited thereto. Here, the chip integrated module is a semiconductor module including a plurality of IC chips. In FIG. 1, a region where the chip integrated module is arranged in the chip integrated body 10 is illustrated with a broken line. In the example of FIG. 1, eight chip integrated modules are arranged vertically while eight chip integrated modules are arranged horizontally, and the chip integrated body 10 includes a total of 64 chip integrated modules. However, the number of chip modules included in the chip integrated body 10 is not limited thereto, and may be 63 or less or 65 or more.

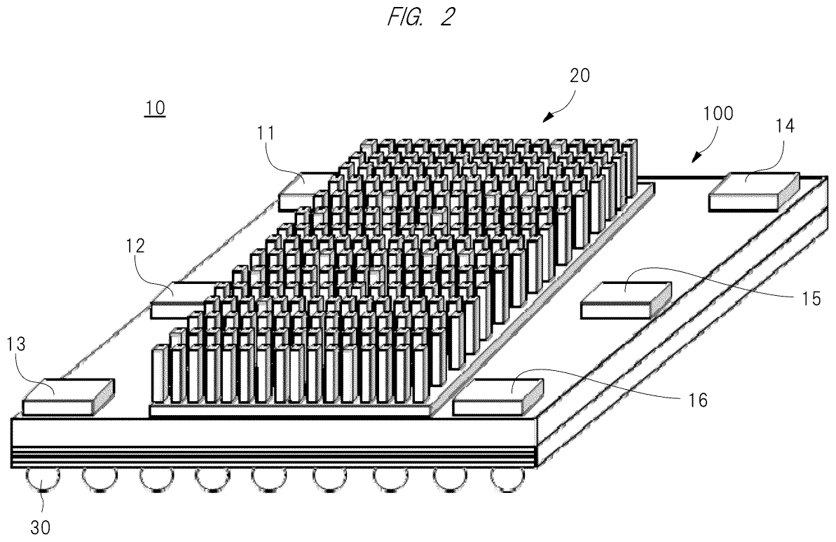

Further, the chip integrated body 10 according to the present embodiment includes an optical transceiver module (referred to as “optical module” below). The chip integrated body 10 according to the present embodiment includes, for example, six optical modules. In the example of FIG. 1, a chip integrated body 10a includes optical modules 11a, 12a, 13a, 14a, 15a, and 16a. A chip integrated body 10b includes optical modules 11b, 12b, 13b, 14b, 15b, and 16b. The optical modules 11a to 16a and the optical modules 11b to 16b illustrated in FIG. 1 correspond to optical modules 11 to 16 illustrated in FIG. 2 described below, respectively. By the optical wiring 110, these optical modules are connected to optical modules provided in the same chip integrated body 10 or optical modules provided in a different chip integrated body 10. An optical fiber is exemplified as a representative example of the optical wiring. However, the optical wiring is not limited thereto, and, for example, a planar panel or sheet including an optical waveguide or an optical wiring using free space may be also applicable. In the chip integrated system 1 according to the present embodiment, signals in the chip integrated body 10 are optically transmitted, and thus, the signals are transmitted faster than a case of transmission of signals as only electric signals.

### Chip Integrated Body

FIG. 2 is a perspective view illustrating an exemplary configuration of the chip integrated body illustrated in FIG. 1. The chip integrated body 10 according to the present embodiment includes: an integrated layer (also referred to as semiconductor package or electronic module) 100; the optical modules 11 to 16 arranged on an upper surface of the integrated layer 100; a heat radiating mechanism 20 arranged on the upper surface of the integrated layer 100; and an external terminal 30 arranged on a lower surface of the integrated layer 100.

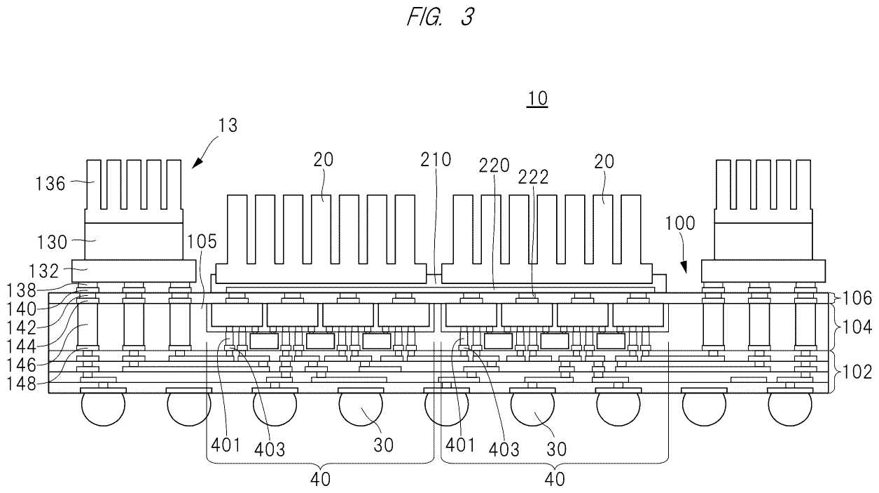

The integrated layer 100 has a stacked structure, and is a layer including a plurality of chip integrated modules (also referred to as semiconductor modules or electronic devices). A detailed configuration of the integrated layer 100 will be described later with reference to FIG. 3.

The heat radiating mechanism 20 is a mechanism of radiating heat generated in the chip integrated body 10. The heat radiating mechanism 20 has a function to radiate the heat generated at the time of, for example, operation of the plurality of IC chips embedded in the integrated layer 100 and the IC chips included in the respective optical modules 11 to 16. In other words, the heat radiating mechanism 20 can radiate the heat generated at the time of, for example, operation of the integrated circuit chips included in the integrated layer 100 and the integrated circuit chips included in the optical modules 11 to 16 (see FIG. 2).

The external terminal 30 is a terminal electrically connected to any of the optical modules 11 to 16 or a chip integrated module 40 (see FIG. 3 described later). In the example of FIG. 2, the external terminals 30 is a solder ball, and configures a part of an electric signal transmission path. In the present embodiment, the external terminal 30 can be used to supply power to the optical module or the chip integrated module, or input/output the electric signal from/to the outside. A shape of the external terminal may be spherical as illustrated in FIG. 2, or may be various shapes such as pin-shape or pad-shape.

FIG. 3 is an explanatory diagram illustrating an exemplary configuration of the chip integrated body illustrated in FIG. 2. FIG. 3 is a diagram illustrating a cross-section configuration of the chip integrated body, and is not hatched for visibility. Further, in FIG. 3, two of the 64 chip integrated modules illustrated in FIG. 1 are illustrated.

Each of the plurality of optical modules 11 to 16 illustrated in FIG. 2 includes an optical transceiver, a connector, and a heat radiating member. For example, the optical module 13 illustrated in FIG. 3 includes an optical transceiver 130, a connector 132, and a heat radiating member 136. The heat radiating member 136 includes: a support plate (heat spreader) fixed on the optical transceiver 130; and a plurality of radiating fins fixed on the support plate and protruding to be away from the optical transceiver 130.

The optical transceiver 130 is a photoelectric conversion component having a function to convert an optical signal received via the optical wiring 110 (see FIG. 1) into an electric signal and a function to convert an electric signal into an optical signal and to transmit the optical signal to the outside via the optical wiring 110. The connector 132 is connected to a lower surface of the optical transceiver 130. Further, the connector 132 is connected to an electrode 140 formed on the surface of the integrated layer 100 via solder 138. The optical transceiver 130 can transmit/receive the electric signal to/from the integrated layer 100 via the connector 132. Because of the use of the connector, the optical transceiver can be easily attached and detached, and can be promptly replaced at the time of, for example, malfunction of the optical transceiver.

Further, the heat radiating member 136 is arranged on the upper surface of the optical transceiver 130. The heat radiating member 136 can radiate heat of, for example, the optical transceiver 130 and the like. The heat radiating member 136 includes the heat spreader having an upper surface provided with a heat radiating fin achieving a large surface area in a small volume. The heat radiating fin can radiate heat of, for example, the optical transceiver 130 and the like.

The heat radiating mechanism 20 is supported by a support member 210 arranged on the surface of the integrated layer 100. The heat radiating mechanism 20 includes: a support plate fixed on the support member 210; and a plurality of heat radiating fins fixed on the support plate and protruding to be away from the chip integrated module 40. The heat radiating mechanism 20 is thermally connected to the chip integrated module 40 (in other words, each of the plurality of IC chips) arranged inside the integrated layer 100 (more specifically, in a chip layer 104) via the support member 210. The support member 210 is, for example, a thermal interface material (TIM), and is thermally connected to the IC chip arranged inside the integrated layer 100.

The integrated layer 100 illustrated in FIG. 3 includes a wide-range wiring layer 102, the chip layer 104, and a connection layer 106.

The wide-range wiring layer 102 is a layer having a stacked structure made of a plurality of layers. Each of the plurality of layers of the wide-range wiring layer 102 includes a conductor pattern such as wiring and an insulative layer covering the conductor pattern. The insulative layer is made of, for example, insulative resin. The conductor pattern such as wiring is formed on the underlying insulative layer. Two wirings which are provided in mutually adjacent layers in a thickness direction are electrically connected to each other via a conductor via. In the example of FIG. 3, the wide-range wiring layer 102 includes four layers, and the external terminal 30 is formed on the wiring provided in the lowermost layer (the farthest layer from the chip layer 104). Further, a wiring in the uppermost layer (the nearest layer to the chip layer 104) in the wide-range wiring layer 102 is electrically connected to the electrode provided in the chip layer 104.

The chip layer 104 is a layer including an insulative sealing body 105 and various conductors and functional devices embedded in the sealing body 105. In the sealing body 105, for example, a conductor post 146, a plurality of chip integrated modules 40 and the like are embedded. In the example of FIG. 3, an electrode 148 is provided on the lower surface of the conductor post 146, and the conductor post 146 is electrically connected to the wiring arranged in the uppermost layer of the wide-range wiring layer 102 via the electrode 148.

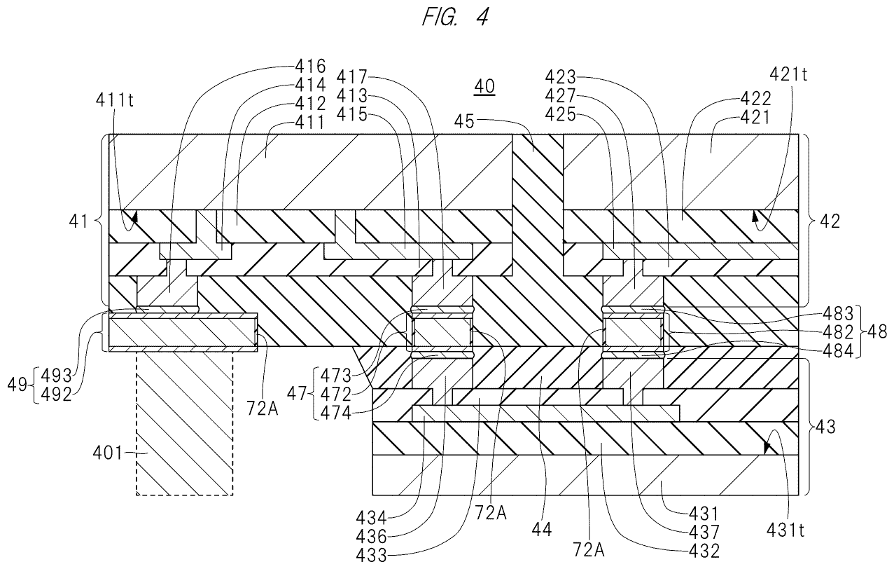

In the example of FIG. 3, the chip integrated module 40 is electrically connected to the wiring arranged in the uppermost layer of the wide-range wiring layer 102 via a conductor tall pillar 401 and an electrode 403. A detailed configuration of the chip integrated module 40 will be described later with reference to FIG. 4.

The connection layer 106 is a layer connecting the chip layer 104 and the component arranged on the surface of the integrated layer 100. For example, the connection layer 106 includes a conductor via 142 and an electrode 144 connecting the conductor post 146 of the chip layer 104 and the electrode 140 electrically connected to the optical transceiver 130.

Further, the connection layer 106 includes a metal contact section 222 thermally connected to the respective chip integrated modules 40, and the contact section 222 is connected to a coupling section 220 provided inside the support member 210 of the heat radiating mechanism 20. In this manner, the chip integrated module 40 according to the present embodiment is thermally connected to the heat radiating mechanism 20 via the contact section 222 and the coupling section 220.

### Chip Integrated Module

FIG. 4 is an enlarged cross-sectional view illustrating an exemplary configuration of a part of the chip integrated module illustrated in FIG. 3. As illustrated in FIG. 4, the chip integrated module 40 according to the present embodiment includes a semiconductor die 41, a semiconductor die 42, and a sealing body 45 sealing the semiconductor die 41 and the semiconductor die 42. The chip integrated module 40 further includes a bridge 43 electrically connecting the semiconductor die 41 and the semiconductor die 42. The chip integrated module 40 further includes a connection section 47 electrically connecting the semiconductor die 41 and the bridge 43 and a connection section 48 electrically connecting the semiconductor die 42 and the bridge 43. The connection section 47 and the connection section 48 are sealed by the sealing body 45. Further, the semiconductor die 41 is electrically connected to the outside (such as the external terminal 30 illustrated in FIG. 3) of the chip integrated module 40 via a connection section 49.

The semiconductor die 41 includes an IC chip 411 having a main surface 411t, an insulative layer 412 stacked on the main surface 411t of the IC chip 411, and an insulative layer 413. The semiconductor die 41 includes a wiring 414 and a wiring 415 which are electrically connected to the IC chip 411. The semiconductor die 41 further includes a die electrode 416 connected to the wiring 414 and a die electrode 417 connected to the wiring 415. In the example of FIG. 4, the semiconductor die 41 includes the two insulative layers 412 and 413. However, the total number of insulative layers in the semiconductor die 41 is not limited to two, and, for example, three or more insulative layers may be included.

The IC chip 411 includes a semiconductor substrate made of, for example, silicon or the like, and a circuit element such as a transistor or a diode. Various integration forms of the circuit element of the IC chip 411 may be applicable. For example, an integration form in which the circuit elements are two-dimensionally or three-dimensionally formed on the main surface 411t of the IC chip, an integration form in which the circuit elements are formed on the respective layers of multilayered semiconductor substrates and are connected by through silicon vias (TSV) penetrating through the semiconductor substrates, and other integration forms are variously expected.

The semiconductor die 42 includes an IC chip 421 having a main surface 421t, an insulative layer 422 stacked on the main surface 421t of the IC chip 421, and an insulative layer 423. The semiconductor die 42 includes a wiring 425 electrically connected to the IC chip 421. The semiconductor die 42 further includes a die electrode 427 connected to the wiring 425. In the example of FIG. 4, the semiconductor die 42 includes the two insulative layers 422 and 423. However, the total number of insulative layers in the semiconductor die 42 is not limited to two, and, for example, three or more insulative layers and two or more wiring layers may be included. Further, a configuration of the semiconductor die 42 is similar to, for example, the configuration of the semiconductor die 41.

The bridge 43 includes a chip 431 having a main surface 431t, an insulative layer 432 stacked on the main surface 431t of the chip 431, and an insulative layer 433. The bridge 43 includes a wiring 434 formed on the insulative layer 432. The chip 431 is made of, for example, a semiconductor substrate such as silicon wafer, or may be made of an inorganic material such as glass as a modification example. However, the total number of insulative layers in the bridge 43 is not limited to two, and, for example, three or more insulative layers and two or more wiring layers may be included. Further, when the chip 431 includes a circuit, the circuit may be electrically connected to the wiring 434. The bridge 43 includes a bridge electrode 436 connected to the connection section 47 and a bridge electrode 437 connected to the connection section 48. The bridge electrode 436 and the bridge electrode 437 are electrically connected to each other via the wiring 434.

The bridge 43 according to the present embodiment is a pillar suspended bridge. The wiring 434 according to the present embodiment is electrically connected to the chip 431, and the wiring 434 and the chip 431 function together as the bridge. As described later, however, when the bridge 43 has a function to electrically connect the semiconductor die 41 and the semiconductor die 42, the bridge 43 can serve as a bridge circuit. Thus, as a modification example, the chip 431 may not be included, or the chip 431 and the wiring 434 may not be electrically connected. Further, in the example of FIG. 4, the bridge 43 includes the two insulative layers 432 and 433. However, the total number of insulative layers in the bridge 43 is not limited to two, and, for example, three or more insulative layers may be included.

The connection section 47 includes a pillar connection section 472. In the example of FIG. 4, the connection section 47 includes the pillar connection section 472, a solder layer 473 connecting the pillar connection section 472 and the die electrode 417, and a solder layer 474 connecting the pillar connection section 472 and the bridge electrode 436.

The connection section 48 includes a pillar connection section 482. In the example of FIG. 4, the connection section 48 includes the pillar connection section 482, a solder layer 483 connecting the pillar connection section 482 and the die electrode 427, and a solder layer 484 connecting the pillar connection section 482 and the bridge electrode 437.

In the present embodiment, each of the pillar connection section 472 and the pillar connection section 482 is a pillar conductor (also referred to as micro pillar) having a size of um order. Each main body of the pillar connection section 472 and the pillar connection section 482 is made of a metallic material containing, for example, copper as a main component. An alloy layer made of a metallic material such as gold and solder containing, for example, tin as a main component is formed on each of a bonded interface between the pillar connection section 472 and the solder layer 473 and a bonded interface between the pillar connection section 472 and the solder layer 474, the alloy layer having higher resistance against oxidation than that of the main body, in other words, having larger free energy for forming metal oxides that that. The alloy layer is a layer formed by eutectic reaction between the metal film and the solder layer formed on the bonded interface between the pillar connection section and the solder layer when the pillar connection section 472 is bonded to the solder layers 473 and 474. The alloy layers will be described in detail later.

Similarly, a bonded film made of a metallic material such as gold is formed on each of a bonded interface between the pillar connection section 482 and the solder layer 483 and a bonded interface between the pillar connection section 482 and the solder layer 484, the bonded film having higher resistance against oxidation than that of the main body. However, at the time of the bonding of the pillar connection section 482 to the solder layers 483 and 484, the alloy layer with the solder layers 483 and 484 may be formed near the bonded films, and the original components of the bonded films may diffuse in the solder layers.

In the example of FIG. 4, the connection section 49 includes an electrode 492 connected to the tall pillar 401, and a solder layer 493 connecting the electrode 492 and a die electrode 426. In the example of FIG. 4, the tall pillar 401 connected to the electrode 492 is not included in the chip integrated module 40, and thus, is illustrated with a dotted line. However, the tall pillar 401 may be regarded as a part of the chip integrated module 40 as a modification example.

In the present embodiment, in the example of FIG. 4, the bridge electrode 436 and the bridge electrode 437 are sealed by a sealing body 44 differently formed from the sealing body 45. The sealing body 44 is, for example, underfill resin. As a modification example, a sealing body collectively sealing the chip 431 and the bridge electrodes 436, 437 may be used. Alternatively, as another modification example, a part of the sealing body 44 may be replaced with the sealing body 105 illustrated in FIG. 3. As illustrated in FIG. 4, the configuration in which the connection section 47 and the connection section 48 are sealed by the sealing body 45 while the bridge 43 is exposed from the sealing body 45 is a configuration obtained by a method of manufacturing the chip integrated module 40 described below. The reasons why the configuration of FIG. 4 is obtained will be described in detail later.

Note that an example in which the bridge 43 is the semiconductor die including the chip 431 has been described in the present embodiment. However, the bridge may not include the chip 431 and may be mainly made of the wiring 434, the insulative layers 432 and 433 into which the wiring is embedded, and the bridge electrodes 436 and 437. Further, in the present embodiment, the connection section 47 and the connection section 48 include the pillar connection sections 472 and 482, respectively. However, each of the connection section 47 and the connection section 48 may include two or more stacked pillar connection sections depending on a distance between the semiconductor die 41 and the bridge 43. The cross-sectional shapes and the cross-sectional areas of the stacked pillar connection sections may be different.

### Optical Module

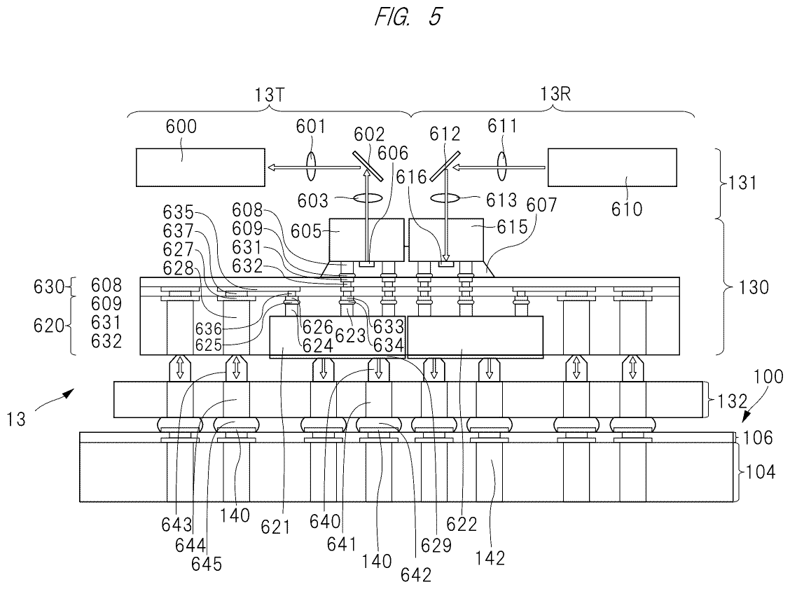

FIG. 5 is an explanatory diagram schematically illustrating an exemplary configuration of the optical module illustrated in FIG. 3. The optical module 13 according to the present embodiment mainly includes an optical system mechanism 131, the optical transceiver 130, and the connector 132. The optical module 13 may further include a mechanism (also referred to as “transmission mechanism 13T” below) transmitting an optical signal to the outside and a mechanism (also referred to as “reception mechanism 13R” below) receiving an optical signal from the outside. In FIG. 5, the transmission mechanism 13T is illustrated on the left of the drawing sheet, and the reception mechanism 13R is illustrated on the right thereof. However, a positional relationship between the transmission mechanism 13T and the reception mechanism 13R may include various modification examples in addition to the aspect of FIG. 5. Further, a configuration of the transmission mechanism 13T will be described below, and common configuration points of the reception mechanism 13R with the configuration of the transmission mechanism 13T may not be described.

The optical system mechanism 131 in the transmission mechanism 13T includes an optical fiber 600, a lens 601, a reflex mechanism (reflecting mirror in FIG. 5) 602, and a lens 603. Light incident from the optical transceiver 130 into the lens 603 passes through the lens 603 and is reflected by the reflex mechanism 602. The reflected light passes through the lens 601 and enters the optical fiber 600. In this manner, the optical signal is transmitted to the outside via the optical fiber 600.

The optical system mechanism 131 in the reception mechanism 13R includes an optical fiber 610, a lens 611, a reflex mechanism (reflecting mirror in FIG. 5) 612, and a lens 613. Light emitted from the optical fiber 610 passes through the lens 611 and is reflected by the reflex mechanism 612. The reflected light passes through the lens 613 and enters the optical transceiver 130. In this manner, the optical signal received by the optical fiber 610 is converted into the electric signal to be subjected to various processing. The lens or the reflex mechanism configuring the optical system mechanism 131 may be appropriately added or deleted depending on design requirements. For example, the optical fiber may be directly coupled to an optical element chip in the optical transceiver, or in some cases, to a light emitting element or a light receiving element without via the lens or the reflex mechanism.

The optical transceiver 130 mainly includes a chip layer 620, a wiring layer 630, two optical element chips 605, 615 arranged on the wiring layer 630, a light emitting element 606, and a light receiving element 616. In the present embodiment, the two optical element chips 605, 615, the light emitting element 606, and the light receiving element 616 are electrically connected to the wiring layer 630, and their connection parts are sealed by the underfill resin 607 or the like. In other words, in the present embodiment, the two optical element chips 605, 615, the light emitting element 606, and the light receiving element 616 are fixed by a fixing member (underfill resin 607) made of resin or the like.

The wiring layer 630 according to the present embodiment is configured to have, for example, a two-layer structure. For example, a conductor pattern of the wiring or the electrode is formed in each layer of the wiring layer 630. Further, the chip layer 620 includes an optical element driving chip 621 and an optical element driving chip 622. The optical element driving chips 621 and 622 are chips for controlling driving of the optical element chip 605 and the optical element chip 615, respectively. The optical element driving chips 621 and 622 may have a function to convert an electric signal level (voltage, current) required by the optical elements for appropriate photoelectric conversion and an electric signal level input/output from/to the outside of the optical transceiver and the like.

The light emitting element 606 in the transmission mechanism is an element being provided on the surface of the optical element chip 605 and emitting the optical signal in response to the electric signal transmitted from the optical element chip 605. The optical signal emitted by the light emitting element 606 enters the lens 603 in the optical system mechanism 131.

The optical element chip 605 is connected to an electrode 631 formed in the upper layer of the wiring layer 630 via an electrode terminal 608 and a solder layer 609, and the optical element driving chip 621 is connected to an electrode 633 formed in the lower layer of the wiring layer 630 via an electrode terminal 623 and a solder layer 634. Thus, the optical element chip 605 and the optical element driving chip 621 are electrically connected via the wiring layer 630. This configuration achieves multi-parallel and short-distance connection because of substantially vertical electric connection between the optical element chip and the optical element driving chip in the wiring layer 630. This enables wideband signal transmission between a group of optical elements arranged in a two-dimensional array and optical element driving chips. Note that the solder layer 634 is not necessarily required depending on a method of manufacturing the optical transceiver. Further, when the electrode terminal 608, a conductor via 632, and the electrode terminal 623 are substantially linearly arranged, an electric connection path length between the optical element chip and the optical element driving chip can be minimized, and excellent electric connection with small parasitic impedance can be achieved.

A metal layer 629 made of a metal is formed on the lower surface of the optical element driving chip 621. The metal layer 629 is thermally connected to a conductor via 641 provided in the connector 132 via a coupling member 640. In this manner, heat generated at the time of driving of the optical element driving chip 621 is radiated via the coupling member 640 in an arrow direction schematically indicated in FIG. 5 (that is a direction from the metal layer 629 toward the connector 132). Note that the metal layer 629 desirably exists for the heat radiation, but does not always need to exist to obtain its effect.

The conductor via 641 in the connector 132 is connected to the electrode 140 formed on the surface of the connection layer 106 via a solder layer 642. Further, as illustrated in FIG. 3, the electrode 140 is connected via the conductor via 142 to the electrode 148 connected to the conductor post 146 formed in the chip layer 104. Thus, heat radiated by the connector 132 is radiated through the conductor post 146.

An electrode terminal 624 is formed on the upper surface of the optical element driving chip 621, and the electrode terminal 624 is connected via a solder layer or conductor connection section 625 to an electrode 626 formed at the bottom of the wiring layer 630. Further, a wiring 635 is formed in the wiring layer 630. The wiring 635 is connected via a conductor via 636 to the electrode 626 electrically connected to the optical element driving chip 621. Further, the wiring 635 is connected via a conductor via 637 to an electrode 627 coupled with a conductor post 628 formed in the chip layer 620.

The conductor post 628 is electrically connected via a coupling member 643 to a conductor via 644 in the connector 132. In the example of FIG. 5, for example, the electric signal is mutually transmitted between the optical transceiver 130 and the connector 132 via the coupling member 643. However, as a modification example, a direction of the transmission of the electrical signal between the optical transceiver 130 and the connector 132 may be one way. That is, in the transmission mechanism 13T, the electric signal is transmitted from the connector 132 toward the optical transceiver 130. In the reception mechanism 13R, the electric signal is transmitted from the optical transceiver 130 toward the connector 132.

### Method of Manufacturing Chip Integrated Module

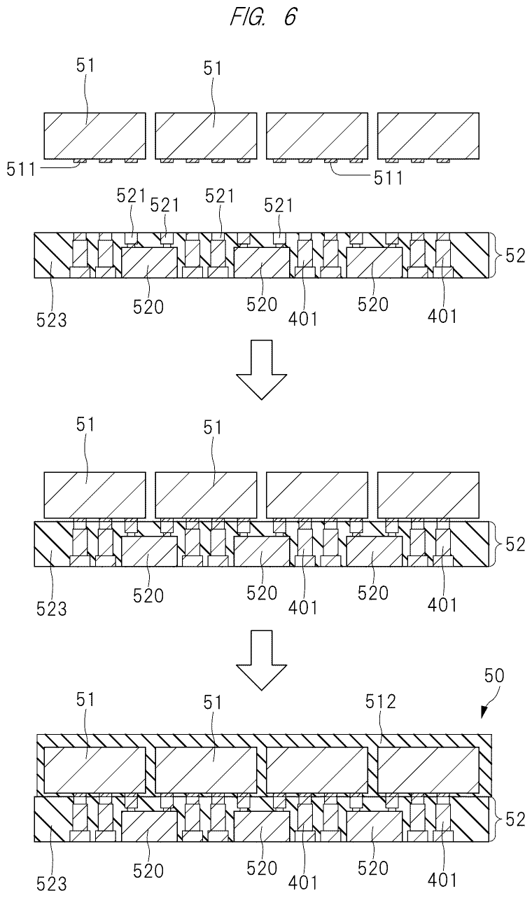

Next, a method of manufacturing the chip integrated module 40 illustrated in FIGS. 3 and 4 will be described. Prior to describing the method of manufacturing the chip integrated module according to the present embodiment, an outline of a manufacturing method studied by the present inventors will be briefly described. FIG. 6 is an explanatory diagram illustrating the outline of the method of manufacturing the chip integrated module according to the study example of the present embodiment.

In the method of manufacturing the chip integrated module illustrated in FIG. 6, firstly, a plurality of semiconductor dies 51 and a bridge structure 52 are prepared as illustrated in the upper part of FIG. 6. The bridge structure 52 is a structure in which a plurality of bridges 520 and a plurality of connection sections 521 are sealed and unified by a sealing body 523. In the example of FIG. 6, the plurality of tall pillars 401 are sealed together with the plurality of bridges 520 by the sealing body 523.

Next, as illustrated in the middle part of FIG. 6, the semiconductor dies 51 are mounted on the bridge structure 52. At this time, a plurality of die electrodes 511 of the semiconductor dies 51 are bonded to the connection sections 521 in the bridge structure 52, respectively.

Next, as illustrated in the lower part of FIG. 6, the semiconductor dies 51 are sealed by a sealing body 512 to integrate the semiconductor dies 51 and the bridge structure 52 to obtain a chip integrated module 50.

In the example of FIG. 6, a plurality of bridge structures 52 are previously integrated to efficiently make electric connection between the semiconductor dies 51 and the bridges 520.

However, the manufacturing method of FIG. 6 has turned out to have the following problem. That is, it has been found out that the positional accuracy of the respective connection sections 521 is difficult to be improved due to contraction or expansion of the sealing body 523 configuring the bridge structure 52. To solve the problem, there is assumed a method of increasing the area of a bonded interface of each of the connection sections 521 and increasing an allowable margin for positional misalignment. In this case, however, arrangement pitches between adjacent connection sections 521 also need to be increased, and higher density of the connection sections 521 is inhibited. That is, higher density of the terminal parts for electrically connecting the semiconductor dies 51 and the bridges 520 is restricted.

As described above, it may be assumed that positional accuracy of the respective connection sections 521 is difficult to be improved due to a large volume of the sealing body 523. Measures to reduce a liner coefficient of expansion of the sealing body 523 by mixing inorganic filler particles described below into the sealing body 523 are assumed, but the measures also have limitations.

The present inventors have found the method of manufacturing a chip integrated module according to the present embodiment in consideration of the above result of study. Though the manufacturing method will be described below in detail, the method of manufacturing a chip integrated module according to the present embodiment is to prepare a structure in which a plurality of semiconductor dies and a plurality of connection sections are integrated by a sealing body and to mount a plurality of bridges on the structure. The volume of the sealing body in the structure in which the semiconductor dies and the connection sections are integrated can be made smaller than the volume of the sealing body 523 in the bridge structure 52 of FIG. 6. In particular, a gap between adjacent IC chips is reduced to reduce effects of thermal contraction and thermal expansion. Consequently, the method of manufacturing a chip integrated module according to the present embodiment improves the positional accuracy of the respective connection sections to achieve higher density of the terminal parts for electrically connecting the semiconductor dies and the bridges.

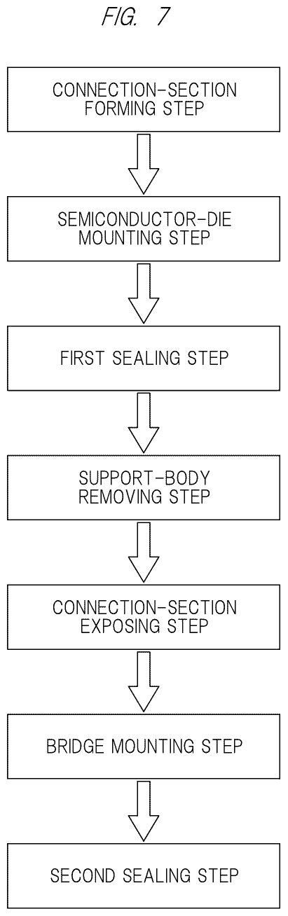

The method of manufacturing a chip integrated module according to the present embodiment will be described below in detail. FIG. 7 is an explanatory diagram illustrating an outline of steps of manufacturing the chip integrated module of FIG. 4. As illustrated in FIG. 7, the method of manufacturing a chip integrated module according to the present embodiment includes a connection-section forming step, a semiconductor-die mounting step, a first sealing step, a support-body removing step, a connection-section exposing step, a bridge mounting step, and a second sealing step.

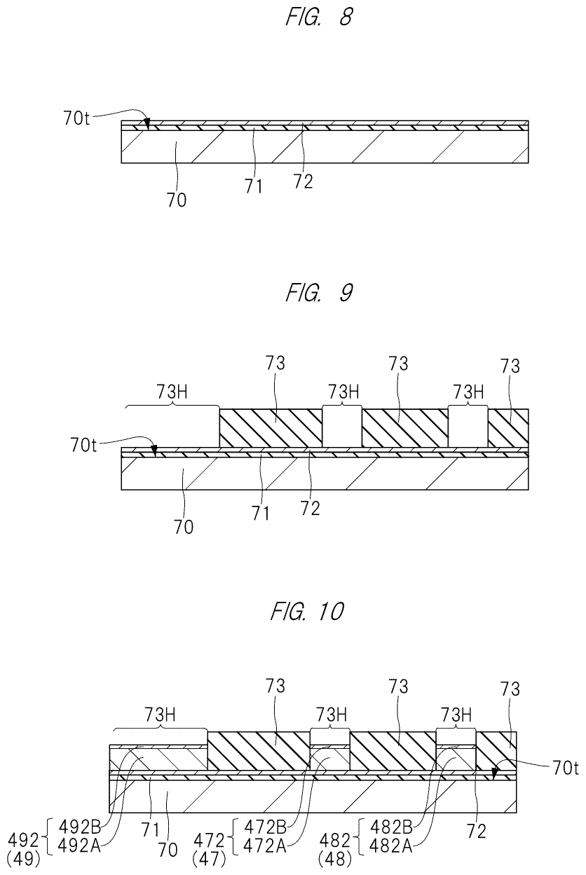

The connection-section forming step of FIG. 7 includes the steps illustrated in FIGS. 8 to 12. FIGS. 8 to 12 are enlarged cross-sectional views illustrating details of the connection-section forming step of FIG. 7. As illustrated in FIG. 11, the connection section 47 including the pillar connection section 472 extending in an out-of-surface direction of an upper surface 70t and the connection section 48 including the pillar connection section 482 extending in an out-of-surface direction of the upper surface 70t are formed on the upper surface 70t of a support body 70 in the connection-section forming step.

Specifically, firstly, the support body 70 having the upper surface 70t is prepared as illustrated in FIG. 8. A release layer 71 and a seed layer 72 are previously formed on the upper surface 70t of the support body 70. The support body 70 is not particularly limited in its materials as long as it is a plate which is rigid enough not to lose workability in each step until the support-body removing step of FIG. 7. For example, a semiconductor substrate such as silicon wafer, a plate made of an inorganic material such as glass or sapphire substrate, a resin plate, and the like may be exemplified. However, in consideration of expansion due to heating on connection, it is desirable that a linear coefficient of expansion of the support body is close to a linear coefficient of expansion of the semiconductor dies.

The release layer 71 is a functional layer with a function to release the support body 70 in the support-body removing step of FIG. 7, for which various materials are selected depending on various methods including a release method using energy beam such as laser, a mechanical release method and the like. The seed layer 72 is a seed film that is a base for forming conductive members such as the connection sections 47, 48, and 49 by a plating method. The seed layer 72 can be formed by, for example, depositing copper to form a film on the release layer 71 by a sputtering method.

Next, as illustrated in FIG. 9, a resist mask 73 is formed on the upper surface 70t of the support body 70, specifically on the seed layer 72. A plurality of openings 73H are formed in the resist mask 73 by, for example, a photolithography technique.

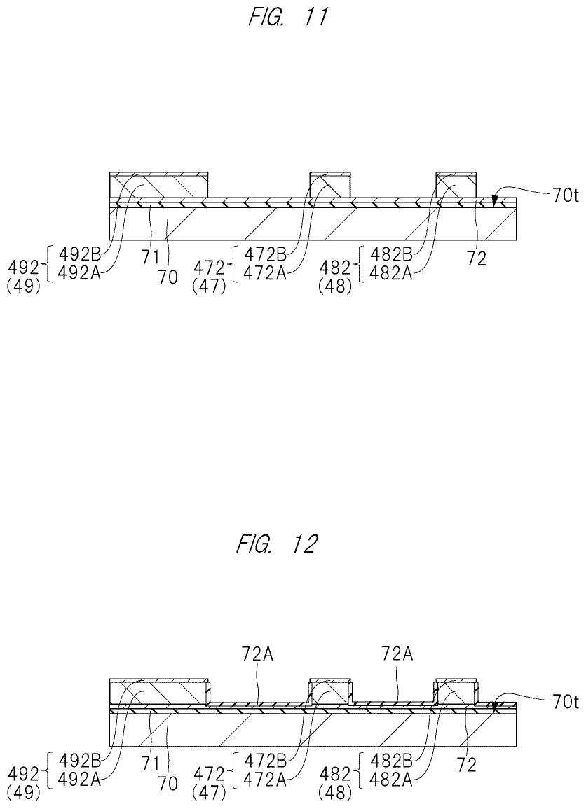

Next, as illustrated in FIG. 10, a metal film is deposited in the openings 73H of the resist mask 73 by a plating method or the like to form the connection section 47, the connection section 48, and the connection section 49. The seed layer 72 is previously formed on the upper surface 70t of the support body 70, and thus, the pillar connection section 472 as a part of the connection section 47, the pillar connection section 482 as a part of the connection section 48, and the electrode 492 as a part of the connection section 49 can be formed by, for example, a plating method. In the example of FIG. 10, the pillar connection section 472 includes a main body 472A and a metal film 472B. The pillar connection section 482 includes a main body 482A and a metal film 482B. The electrode 492 includes a main body 492A and a metal film 492B. Each of the main bodies 472A, 482A, and 492A is made of, for example, copper, and each of the metal films 472B, 482B, and 492B is made of a metallic material such as gold having higher resistance against oxidation than copper. Each of the metal film 472B, 482B, 492B has a function to prevent oxidization of a bonded surface of each of the main body 472A, 482A, 492A made of copper, and to enable fluxless solder bonding in a semiconductor-die mounting step described later.

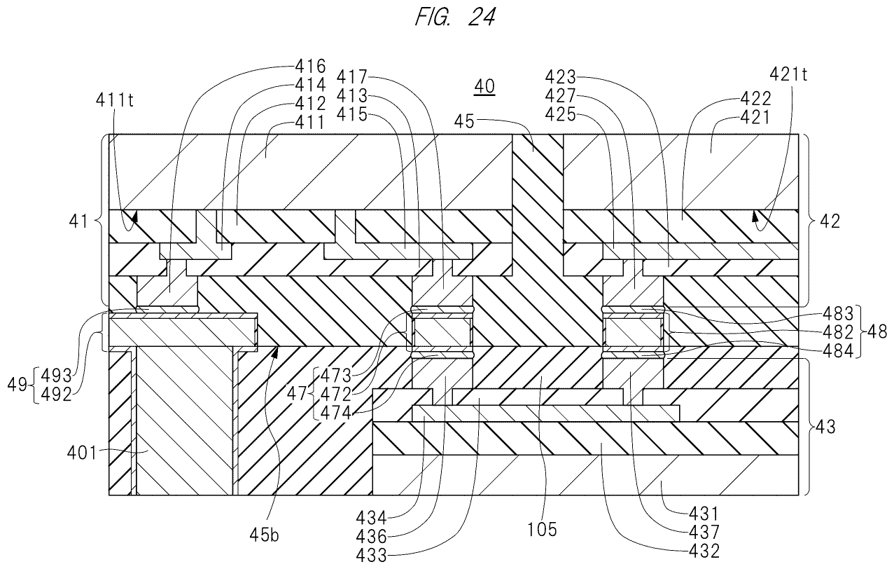

Next, as illustrated in FIG. 11, the resist mask 73 (see FIG. 10) is removed. By the removal of the resist mask 73, the side surfaces of the connection sections 47, 48, and 49 and a part of the upper surface of the seed layer 72 are exposed. The process may proceed to the semiconductor-die mounting step illustrated in FIG. 7 under the state of FIG. 11. However, as illustrated in FIG. 12, the process preferably includes a step of forming an oxide film 72A on the side surfaces of the connection sections 47, 48, and 49 and the exposed surface of the seed layer 72. When the oxide film 72A is formed before the semiconductor-die mounting step, the solder in the semiconductor-die mounting step is prevented from wetly spreading over the side surfaces of the connection sections, and the bonding state is prevented from being unstable. If the process includes the step of forming the oxide film 72A on the side surfaces of the connection sections 47, 48, and 49 and the exposed surface of the seed layer 72, the side surfaces of the connection sections 47, 48, and 49 are covered with the oxide film 72A as illustrated in FIG. 4. If the oxide film 72A is not formed in this step, for example, the oxide film 72A illustrated in FIG. 4 may not be formed as illustrated in FIG. 24 described later.

As the method of forming the oxide film 72A, for example, the following methods are exemplified. For example, there is a method of exposure to oxygen-containing atmosphere until the oxide film 72A illustrated in FIG. 12 is formed while the resist mask 73 illustrated in FIG. 10 is removed. Further, as a method of forming the oxide film 72A in a shorter period of time, there is a method of heating the side surfaces of the connection sections 47, 48, and 49 and the exposed surface of the seed layer 72 under the oxygen-containing atmosphere. In FIG. 12, note that the oxide film 72A is thickly illustrated for easily understanding. However, the oxide film 72A only needs to be thinly formed on the side surfaces of the connection sections 47, 48, and 49 and the exposed surface of the seed layer 72.

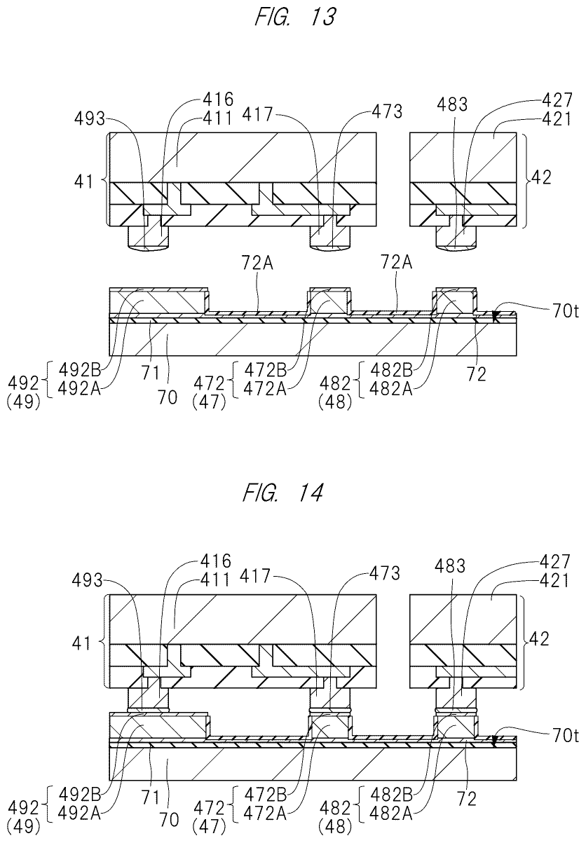

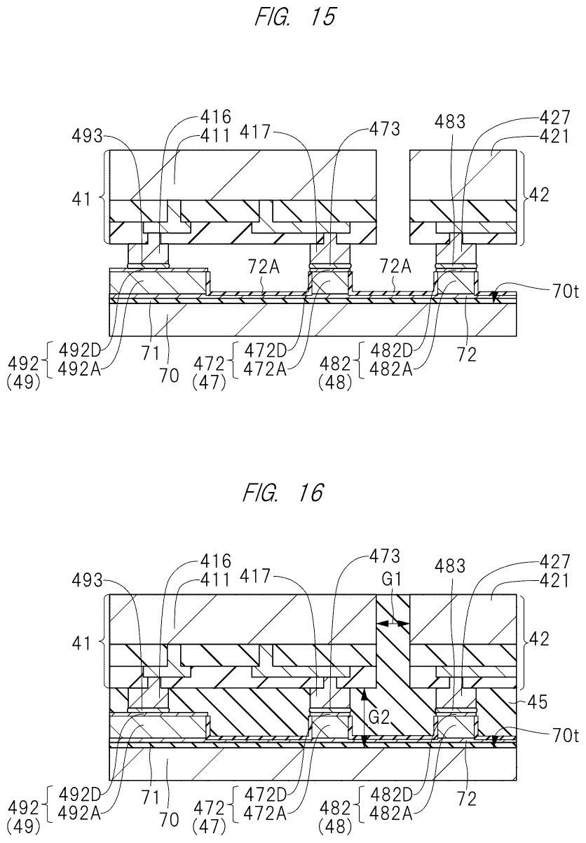

The semiconductor-die mounting step illustrated in FIG. 7 includes the steps illustrated in FIGS. 13 to 15. Each of FIGS. 13 to 15 is an enlarged cross-sectional view illustrating details of the semiconductor-die mounting step illustrated in FIG. 7. In the semiconductor-die mounting step, as illustrated in FIG. 15, the semiconductor die 41 including the IC chip 411 and the die electrode 417 connected to the IC chip 411 and the semiconductor die 42 including the IC chip 421 and the die electrode 427 connected to the IC chip 421 are prepared. Further, in the semiconductor-die mounting step, the semiconductor die 41 and the semiconductor die 42 are mounted on the support body 70 such that the die electrode 417 is arranged on the connection section 47 while the die electrode 427 is arranged on the connection section 48.

Specifically, as illustrated in FIG. 13, firstly, the semiconductor die 41 and the semiconductor die 42 are prepared. The detailed configurations of the semiconductor die 41 and the semiconductor die 42 are as previously described with reference to FIG. 4, and thus, will not be repeatedly described. Next, as illustrated in FIG. 13, the semiconductor die 41 and the semiconductor die 42 are aligned with the support body 70 such that the die electrode 417 is arranged on the connection section 47 while the die electrode 427 is arranged on the connection section 48. The solder layer 473 is formed on the die electrode 417 in the semiconductor die 41. The solder layer 493 is formed on the die electrode 416 in the semiconductor die 41. The solder layer 483 is formed on the die electrode 427 in the semiconductor die 42.

Next, as illustrated in FIG. 14, the die electrode 417 in the semiconductor die 41 is pressed against the connection section 47 via the solder layer 473. At this time, the die electrode 416 in the semiconductor die 41 is pressed against the connection section 49 via the solder layer 493. Similarly, the die electrode 427 in the semiconductor die 42 is pressed against the connection section 48 via the solder layer 483. In this step, the solder layer 473 and the pillar connection section 472 of the connection section 47 are temporarily bonded by solid phase diffusion bonding. Similarly, the solder layer 493 and the electrode 492 of the connection section 49 are temporarily bonded by solid phase diffusion bonding. Similarly, the solder layer 483 and the pillar connection section 482 of the connection section 48 are temporarily bonded by solid phase diffusion bonding.

Next, a bonded interface between the solder layer 473 and the metal film 472B of the pillar connection section 472, a bonded interface between the solder layer 493 and the metal film 492B of the electrode 492, and a bonded interface between the solder layer 483 and the metal film 482B of the pillar connection section 482 illustrated in FIG. 14 are heated up to and maintained at a melting temperature of the solder. In this manner, a liquid phase can be caused in each of the bonded interfaces. As illustrated in FIG. 15, an alloy layer 472D, an alloy layer 482D, and an alloy layer 492D are formed in the bonded interfaces, respectively. When a temperature at which the liquid phase is caused is maintained, the elements in the liquid phase diffuse toward an alloy layer, and thus, the melting point of the liquid phase increases. Consequently, the liquid phase is solidified. Such a bonding system is called liquid phase diffusion bonding. As described in the present embodiment, a combination of the temporary bonding by the solid phase diffusion bonding and the bonding by the liquid phase diffusion bonding can achieve a strong and thermally-stable bonding state without using the flux in the bonding step using the solder. In a reflow bonding system using the flux, a flux residue is likely to remain around a bonded part in the fine bonding as described in the present embodiment. To the contrary, in the present embodiment, no flux residue remains, and thus, a step of cleansing the residue can be omitted. Further, the step of cleansing and removing the flux residue is made difficult in the case of the finer and higher-density connection sections. In the present embodiment, since the flux residue does not need to be cleansed, the finer and higher-density connection sections can be achieved. Depending on the sizes or arrangements of the bonded parts, note that general solder bonding (brazing), solder bonding using the flux, and solid phase diffusion bonding between metals may be employed as options of the bonding processes in addition to the above-described methods.

When the solder bonding is performed, it is preferable to suppress the solder component of each solder layer from wetly spreading over the side surfaces of the pillar connection sections. This is because the wet spread of the solder component over the side surfaces of the pillar connection sections or the upper surface of the seed layer 72 makes the shape of the bonded part unstable or highly likely makes the solder adversely affect the seed layer or the release layer. In the present embodiment, as described above, the oxide film 72A is formed on the side surfaces of the pillar connection sections and the exposed surface of the seed layer 72. This case can prevent the wet spread of the solder component, and thus, the die electrodes and the connection sections can be bonded with a small amount of the solder.

In the first sealing step illustrated in FIG. 7 after the semiconductor-die mounting step, as illustrated in FIG. 16, the semiconductor die 41, the semiconductor die 42, the connection section 47, and the connection section 48 are sealed by the sealing body 45. FIG. 16 is an enlarged cross-sectional view illustrating details of the first sealing step illustrated in FIG. 7. In this step, the semiconductor die 41, the semiconductor die 42, the connection section 47, and the connection section 48 are unified by the sealing body 45. Further, in the example of FIG. 16, the connection section 49 is also sealed by the sealing body 45. As a material of the sealing body 45, for example, a resin material containing thermosetting resin or the like can be exemplified. As a modification example of the sealing body 45, a large number of inorganic filler particles may be contained in a resin as described later.

In the chip integrated module 40 illustrated in FIG. 4, a distance between the semiconductor die 41 and the semiconductor die 42 is small. For example, in the example of FIG. 16, a distance G1 between the semiconductor die 41 and the semiconductor die 42 is smaller than a minimum distance G2 between the upper surface 70t of the support body 70 and the semiconductor die 41 except the die electrodes 416 and 417. Further, the IC chips occupying most of the semiconductor die 41 and the semiconductor die 42 are made of a semiconductor material with a remarkably lower linear coefficient of expansion than that of the sealing body 45. Thus, even when the sealing body 45 thermally expands or thermally shrinks, the positions of the die electrodes 416, 417, and 427 are less influenced. Further, the connection sections 47, 48, and 49 are already fixed to the semiconductor die 41 or the semiconductor die 42 before the first sealing step. Thus, the connection sections 47, 48, and 49 can maintain the high positional accuracy even when being sealed by the sealing body 45. Thus, the present embodiment is difficult to cause the problem that is the difficulty in improving the positional accuracy of the connection sections 521 in the bridge structure 52 described with reference to FIG. 6.

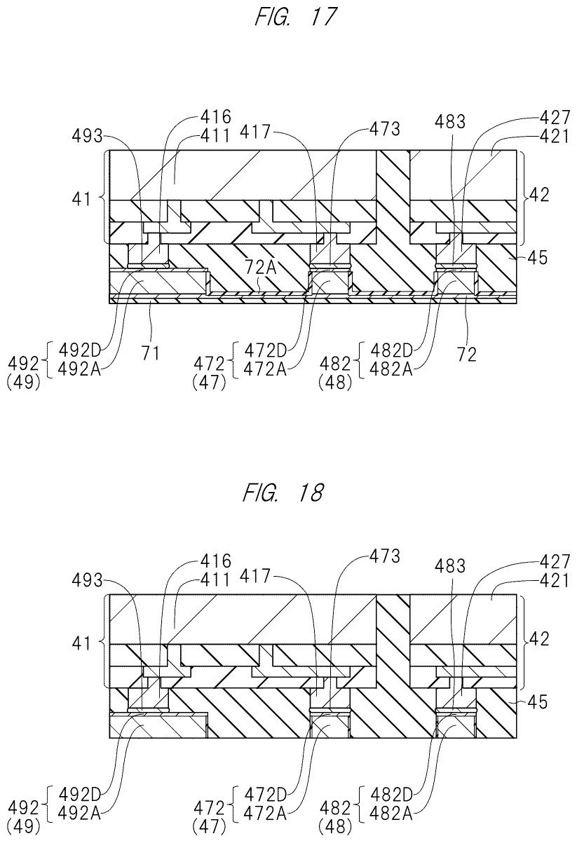

In the support-body removing step illustrated in FIG. 7 after the first sealing step, as illustrated in FIG. 17, the support body 70 (see FIG. 16) is removed. FIG. 17 is an enlarged cross-sectional view illustrating details of the support-body removing step illustrated in FIG. 7. In this step, the release layer 71 is decomposed (ablated) by emitting laser or the like to the release layer 71 to apply energy thereto, and thus, the adhesion of the release layer 71 to the support body is remarkably reduced, and, as a result, the support body 70 can be easily released. Additionally, the release may be performed in the release layer by mechanical stress in the support-body removing step.

In the connection-section exposing step illustrated in FIG. 7 after the support-body removing step, as illustrated in FIG. 18, a part (the lower surface) of the pillar connection section 472 and a part (the lower surface) of the pillar connection section 482 are exposed from the sealing body 45. FIG. 18 is an enlarged cross-sectional view illustrating details of the connection-section exposing step illustrated in FIG. 7. In this step, the release layer 71 and the seed layer 72 illustrated in FIG. 17 are removed by, for example, etching. Further, in this step, a part of the oxide film 72A illustrated in FIG. 17, the part being formed on the upper surface of the seed layer 72, is removed. In the example of FIG. 18, in this step, a part (the lower surface) of the electrode 492 is also exposed from the sealing body 45.

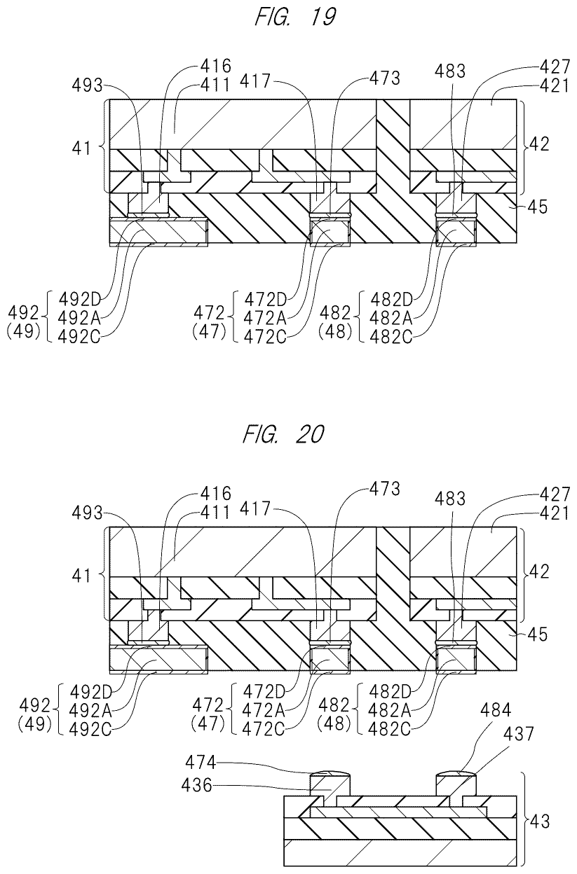

In this step, as illustrated in FIG. 19, it is preferable that the connection sections are exposed from the sealing body 45 and then metal films 472C, 482C, and 492C are formed on the exposed surfaces of the connection sections, respectively. FIG. 19 is an enlarged cross-sectional view illustrating details of the connection-section exposing step continued from FIG. 18. As illustrated in FIG. 19, in this step, the metal film 472C is formed on the surface of the pillar connection section 472 exposed from the sealing body 45. Similarly, the metal film 482C is formed on the surface of the pillar connection section 482 exposed from the sealing body 45. The metal film 492C is formed on the surface of the electrode 492 exposed from the sealing body 45. The metal films 472C, 482C and 492C each has a function to prevent the oxidation of the bonded surface of the respective main bodies 472A, 482A and 492A made of copper and a function to enable the bonding in a low-temperature process by eutectic reaction with the solder mainly containing tin in the semiconductor-die mounting step described later. For example, as similar to the metal films 472B, 482B, and 492B, the metal films 472C, 482C, and 492C are made of a metallic material (such as gold) with higher resistance against the oxidation than that of each material of the main bodies 472A, 482A, and 492A. Gold is exemplified as the metallic material having the above-described functions. Since the metal films 472C, 482C, and 492C are provided, the above-described solder bonding can be performed in the bridge mounting step illustrated in FIG. 7.

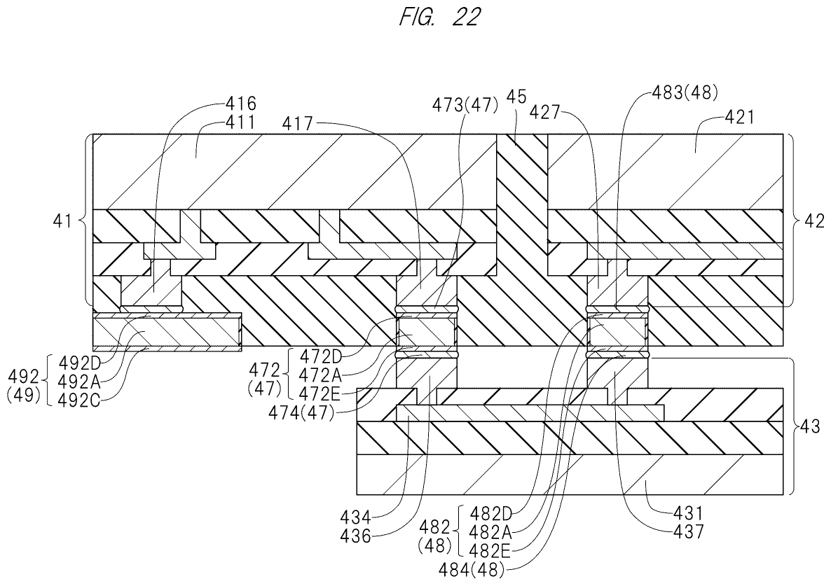

The bridge mounting step illustrated in FIG. 7 includes the steps illustrated in FIGS. 20 to 22. Each of FIGS. 20 to 22 is an enlarged cross-sectional view illustrating details of the bridge mounting step illustrated in FIG. 7. In the bridge mounting step, as illustrated in FIG. 22, the bridge 43 including the bridge electrode 436 connected to the connection section 47 and the bridge electrode 437 connected to the connection section 48 is prepared. Further, in the bridge mounting step after the connection-section exposing step, the bridge 43 is mounted on the structure sealed by the sealing body 45 such that the bridge electrode 436 is arranged on the pillar connection section 472 while the bridge electrode 437 is arranged on the pillar connection section 482.

Specifically, firstly, the bridge 43 is prepared as illustrated in FIG. 20. The detailed configuration of the bridge 43 is as previously described with reference to FIG. 4, and will not be repeatedly described. Next, as illustrated in FIG. 20, the bridge 43 and the structure sealed by the sealing body 45 are positionally aligned such that the bridge electrode 436 is arranged on the pillar connection section 472 while the bridge electrode 437 is arranged on the pillar connection section 482. The solder layer 474 is formed on the bridge electrode 436. The solder layer 484 is formed on the bridge electrode 437.

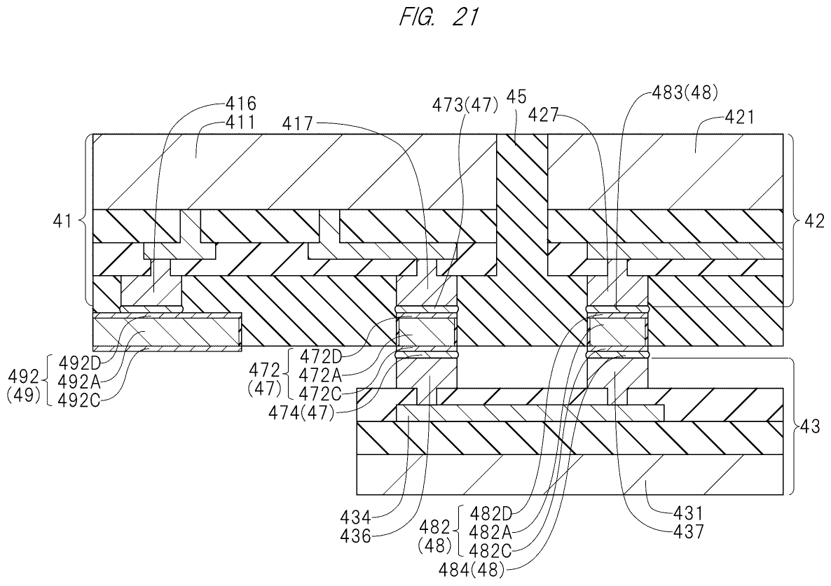

Next, as illustrated in FIG. 21, the bridge electrode 436 of the bridge 43 is pressed against the pillar connection section 472 of the connection section 47 via the solder layer 474. At this time, the bridge electrode 437 of the bridge 43 is pressed against the pillar connection section 482 of the connection section 48 via the solder layer 484. In this step, the solder layer 474 and the pillar connection section 472 of the connection section 47 (specifically, the metal film 472C of the pillar connection section 472) are temporarily bonded by the solid phase diffusion bonding. Similarly, the solder layer 484 and the pillar connection section 482 of the connection section 48 (specifically, the metal film 482C of the pillar connection section 482) are temporarily bonded by the solid phase diffusion bonding.

Next, a bonded interface between the solder layer 474 and the metal film 472C of the pillar connection section 472 and a bonded interface between the solder layer 484 and the metal film 482C of the pillar connection section 482 illustrated in FIG. 21 are bonded by the liquid phase diffusion bonding. The liquid phase diffusion bonding method is as described above, and will not be repeatedly described. As illustrated in FIG. 22, the metal films 472C and 482C illustrated in FIG. 21 turn into alloy layers 472E and 482E formed by eutectic reaction between tin as the main component of the solder layers and the material (such as gold) of the metal films, respectively, because of the liquid phase diffusion bonding. Incidentally, if the flux residue can be cleansed also in the semiconductor-die mounting step, a solder reflow processing using the flux may be performed instead of the combination method of the solid phase diffusion bonding and the liquid phase diffusion bonding.

However, as described in the present embodiment, if the solder layers 473 and 483 for bonding the pillar connection sections 472 and 482 and the die electrodes 417 and 427 are previously sealed by the sealing body 45 in the bridge mounting step, it is particularly preferable to employ the liquid phase diffusion bonding in order to prevent the melting of the sealed solder layers 473 and 483. The liquid phase diffusion bonding can bond the interface between the solder layer 474 and the pillar connection section 472 and the interface between the solder layer 484 and the pillar connection section 482 at a lower temperature than the melting points of the solder layers 473 and 483.

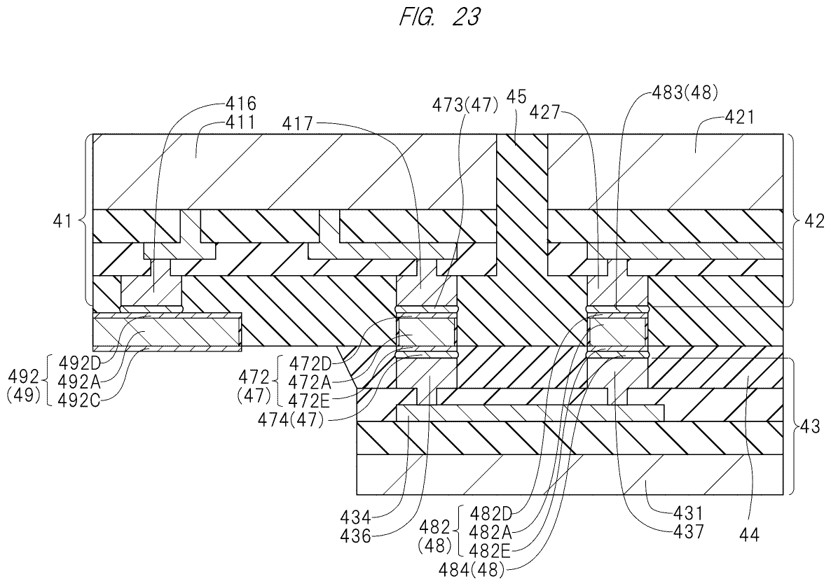

In the second sealing step illustrated in FIG. 7 after the bridge mounting step, as illustrated in FIG. 23, the bridge electrode 436 and the bridge electrode 437 are sealed by the sealing body 44. FIG. 23 is an enlarged cross-sectional view illustrating details of the second sealing step illustrated in FIG. 7. In the example of FIG. 23, the sealing body 44 is underfill resin embedded between the bridge 43 and the sealing body 45. The bridge electrode 436 and the bridge electrode 437 are sealed by the sealing body 44 to protect a part of the pillar connection sections 472 and 482 exposed from the sealing body 45.

However, the form illustrated in FIG. 23 is variously modified. For example, the second sealing step illustrated in FIG. 7 is omitted, and a semiconductor module in the state illustrated in FIG. 22 may be shipped as a product. Alternatively, as illustrated in a modification example of FIG. 24, the bridge electrode 436 and the bridge electrode 437 may be sealed together with a conductor tall pillar 401 by the sealing body 105. The sealing step is generally referred to as mold underfill (MUF). In this modification example, a step of forming the tall pillar 401 is required before the second sealing step. For example, it is preferable that the step of forming the tall pillar is performed after the connection-section exposing step and before the bridge mounting step. The method of forming the tall pillar 401 may be performed similarly as the connection-section forming step described with reference to FIGS. 8 to 12. That is, a resist mask is formed on a lower surface 45b of the sealing body 45 illustrated in FIG. 24. The resist mask includes an opening formed at a position overlapping with a part of the connection section 49. A metal film is deposited in the opening of the mask by a plating method or the like to form the tall pillar 401. In this case, the tall pillar 401 is directly formed on the electrode 492.

In the modification example illustrated in FIG. 24, the entire chip layer 104, the entire integrated layer 100, or the entire chip integrated body 10 illustrated in FIG. 3 may be regarded as the semiconductor module.

In the manufacturing method of performing the bridge mounting step after the first sealing step unifying the plurality of semiconductor dies as illustrated in FIG. 7, the plurality of die electrodes and the plurality of connection sections can be arranged with high positional accuracy, and thus, the IC chips and the bridges can be bonded at higher density. Further, as described with reference to FIG. 4, the structure in which the connection section 47, the connection section 48, the semiconductor die 41, and the semiconductor die 42 are sealed by one sealing body 45 is a structure formed by the manufacturing method described with reference to FIGS. 7 to 24.

### Modification Examples of Sealing Body

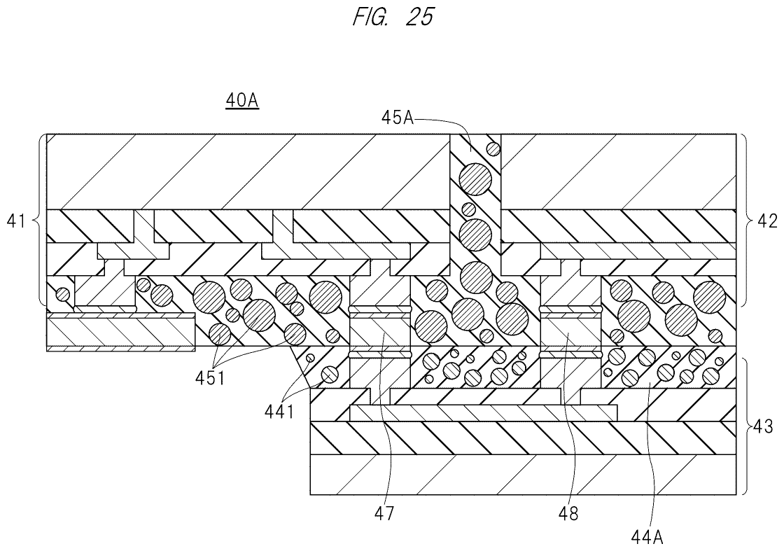

Next, modification examples of the sealing body 45 and the sealing body 44 illustrated in FIG. 4 will be described. Each of FIGS. 25 to 27 is an enlarged cross-sectional view illustrating a modification example of the sealing body illustrated in FIG. 4.

A chip integrated module 40A illustrated in FIG. 25 is different from the chip integrated module 40 illustrated in FIG. 4 in a sealing body 45A and a sealing body 44A. The sealing body 45A contains a plurality of filler particles 451, and the sealing body 44A contains a plurality of filler particles 441. An average particle diameter of the plurality of filler particles 451 is larger than an average particle diameter of the plurality of filler particles 441. Since the sealing body 45A contains the plurality of filler particles 451 with the large average particle diameter as described in this modification example, a linear coefficient of expansion of the entire sealing body 45A can be decreased. Consequently, in the bridge mounting step described with reference to FIGS. 7 and 20 to 22, the positional accuracy of the connection section 47 and the connection section 48 can be further improved. Note that the plurality of filler particles 451 are previously mixed into the sealing resin used in the first sealing step of FIG. 7. Similarly, the plurality of filler particles 441 are previously mixed into the sealing resin used in the second sealing step of FIG. 7.

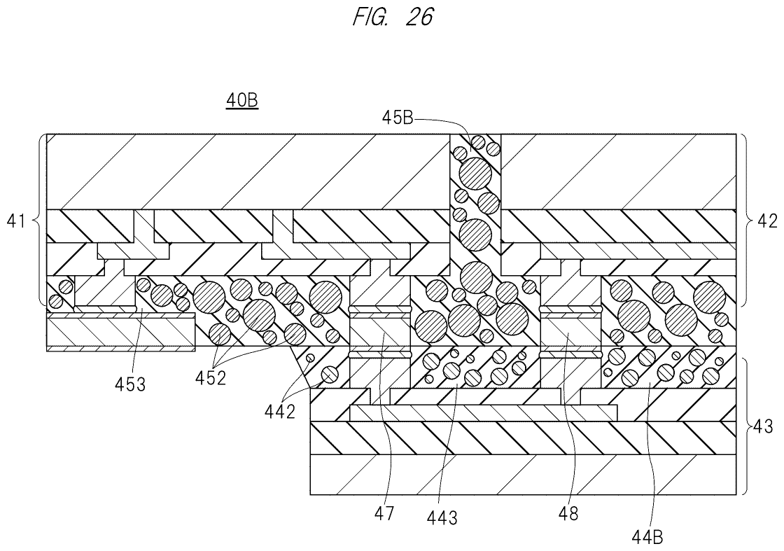

A chip integrated module 40B illustrated in FIG. 26 is different from the chip integrated module 40 illustrated in FIG. 4 in a sealing body 45B and a sealing body 44B. The sealing body 45B contains a plurality of filler particles 452, and the sealing body 44B contains a plurality of filler particles 442. A filling rate of the plurality of filler particles 452 in the sealing body 45B is higher than a filling rate of the plurality of filler particles 442 in the sealing body 44B. The “filling rate of the filler particles 452” is defined as a total volume value of the filler particles 452 included in a volume of the entire sealing body 45B containing a resin 453 and the plurality of filler particles 452. The “filling rate of the filler particles 442” is defined as a total volume value of the plurality of filler particles 442 included in a volume of the entire sealing body 44B containing an insulative resin 443 and the plurality of filler particles 442.

However, in calculating the filling rates, for example, images of cross sections of two or more regions adopted at random in the sealing body 45B are captured, a rate of the cross-section areas of the filler particles 452 relative to the cross-section area of the sealing body 45B is measured in each image-captured region, and an average value among the regions can be regarded as the “filling rate of the filler particles 452”. The “filling rate of the filler particles 442” is also similarly measured. Since the filling rate of the plurality of filler particles 452 in the sealing body 45B is increased as described in the present modification example, a linear coefficient of expansion of the entire sealing body 45B can be decreased. Consequently, in the bridge mounting step described with reference to FIGS. 7 and 20 to 22, the positional accuracy of the connection section 47 and the connection section 48 can be further improved. Note that the plurality of filler particles 452 are previously mixed into the sealing resin used in the first sealing step of FIG. 7. Similarly, the plurality of filler particles 442 are previously mixed into the sealing resin used in the second sealing step of FIG. 7.

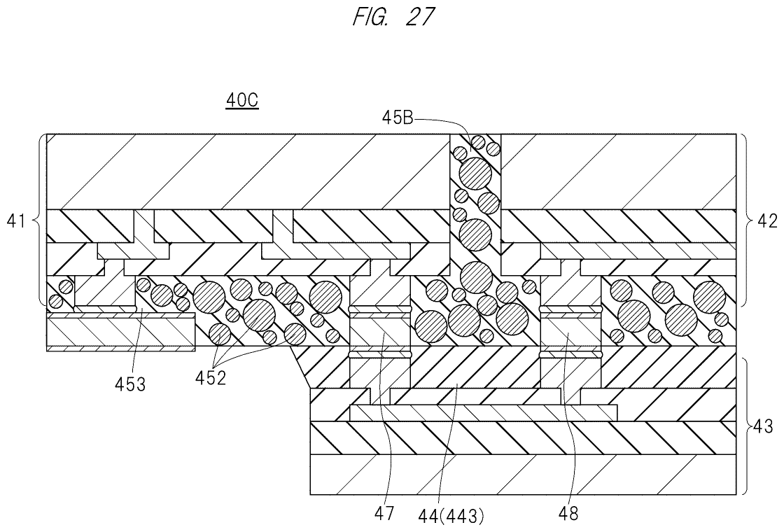

A chip integrated module 40C illustrated in FIG. 27 is different from the chip integrated module 40 illustrated in FIG. 4 in the sealing body 45B. The sealing body 45B contains a plurality of filler particles 452, and the sealing body 44 is the insulative resin 443 containing no filler particles. If the sealing body 45B contains the filler particles irrespective of the presence of filler particles in the sealing body 44 as described in this modification example, the linear coefficient of expansion of the entire sealing body 45B can be decreased. Consequently, in the bridge mounting step described with reference to FIGS. 7 and 20 to 22, the positional accuracy of the connection section 47 and the connection section 48 can be further improved.

### Modification Examples of Manufacturing Method

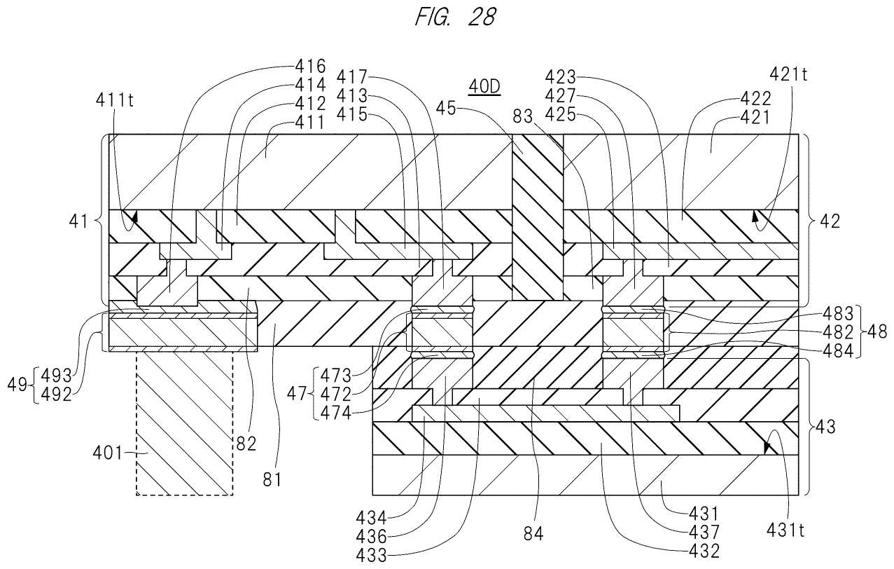

Next, modification examples of the method of manufacturing the chip integrated module 40 described with reference to FIGS. 7 to 23 will be described. FIG. 28 is an enlarged cross-sectional view of a chip integrated module according to another modification example of FIG. 4. A chip integrated module 40D illustrated in FIG. 28 is different from the chip integrated module 40 illustrated in FIG. 4 in that the connection section 47 and the connection section 48 are sealed by an insulative layer 81 while the die electrodes 416, 417 of the semiconductor die 41 and the die electrode 427 of the semiconductor die 42 are sealed by an insulative layer 82 tightly adhered to the insulative layer 81. Further, the chip integrated module 40D is different from the chip integrated module 40 illustrated in FIG. 4 in that the bridge electrode 436 and the bridge electrode 437 of the bridge 43 are sealed in an insulative layer 84 tightly adhered to the insulative layer 81.

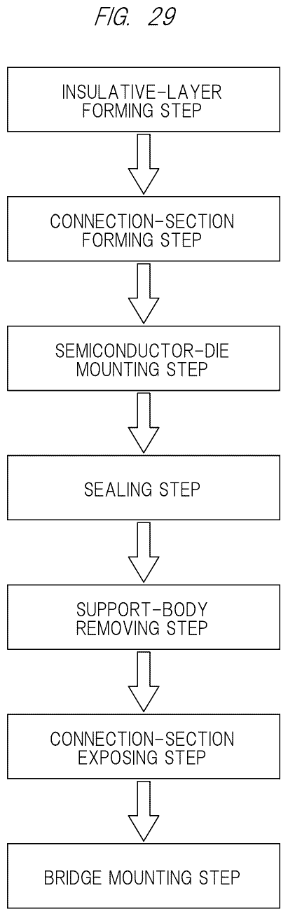

A method of manufacturing the chip integrated module 40D illustrated in FIG. 28 will be described below. In the following description, different points from the method of manufacturing the chip integrated module 40 described with reference to FIGS. 7 to 23 will be mainly described, and the common steps may not be described. FIG. 29 is an explanatory diagram illustrating an outline of steps of manufacturing the chip integrated module illustrated in FIG. 28. As illustrated in FIG. 29, the method of manufacturing the chip integrated module according to this modification example includes an insulative-layer forming step, a connection-section forming step, a semiconductor-die mounting step, a sealing step, a support-body removing step, a connection-section exposing step, and a bridge mounting step.

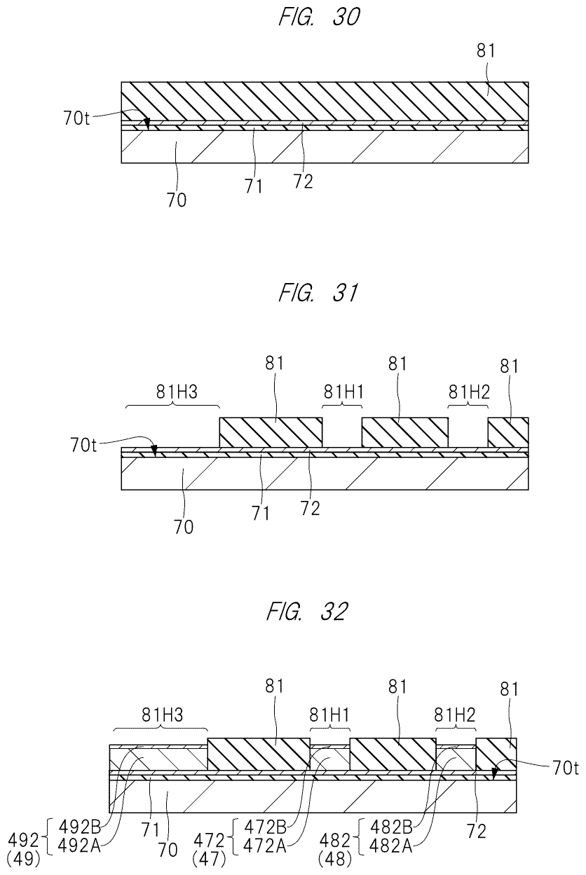

The insulative-layer forming step illustrated in FIG. 29 includes the steps illustrated in FIGS. 30 and 31. Each of FIGS. 30 and 31 is an enlarged cross-sectional view illustrating details of the insulative-layer forming step illustrated in FIG. 29. In the insulative-layer forming step, the insulative layer 81 is formed on the upper surface 70t of the support body 70 as illustrated in FIG. 30, and then, an opening 81H1 and an opening 81H2 are formed in the insulative layer 81 as illustrated in FIG. 31. In the example of FIG. 31, an opening 81H3 is also formed for forming the connection section 49 illustrated in FIG. 28. The insulative layer 81 is bonded to the insulative layer 82 illustrated in FIG. 28 in the semiconductor-die mounting step described later. Thus, it is preferable to use a material with not only electrically insulative characteristics but also high heat resistance as an insulative material used for the insulative layer 82. As such a material, an organic insulative material such as polyimide or polybenzoxazole (PBO) is exemplified. The support body 70, the release layer 71, and the seed layer 72 illustrated in FIGS. 30 and 31 are as previously described with reference to FIG. 8, and will not be repeatedly described.

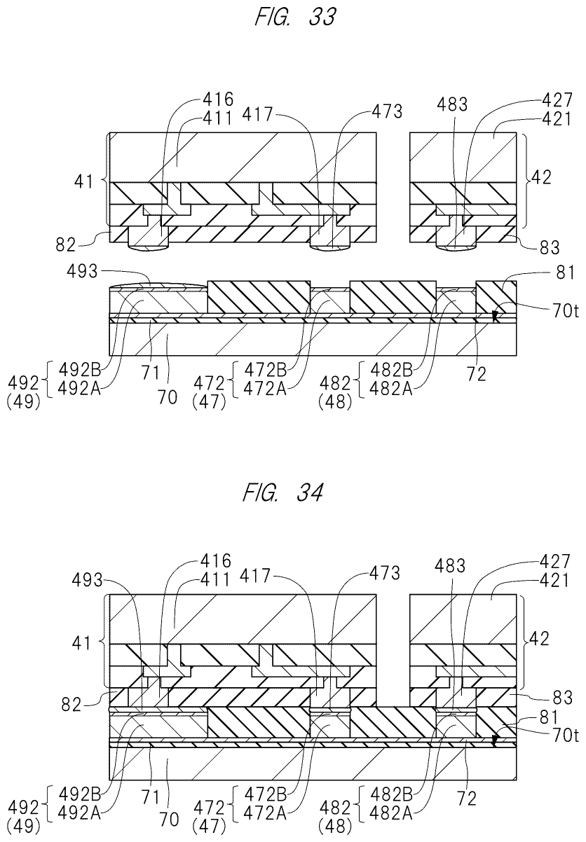

In the connection-section forming step of FIG. 29, as illustrated in FIG. 32, the connection section 47 including the pillar connection section 472 formed in the opening 81H1 and the connection section 48 including the pillar connection section 482 formed in the opening 81H2 are formed. FIG. 32 is an enlarged cross-sectional view illustrating details of the connection-section forming step of FIG. 29. In the example of FIG. 32, the electrode 492 configuring the connection section 49 is formed in the opening 81H3. This modification example is different from the manufacturing method described with reference to FIG. 10 in that the insulative layer 81 is used as a mask instead of the resist mask 73 described with reference to FIG. 10. The configurations of the pillar connection sections 472, 482 and the electrode 492 are as described with reference to FIG. 10, and will not be repeatedly described.

As described above, in this modification example, the connection sections 47, 48, and 49 are formed while the insulative layer 81 is used as the mask. Thus, to this modification example, the step of removing the resist mask 73 described with reference to FIG. 11 and the step of forming the oxide film 72A described with reference to FIG. 12 are not applied.

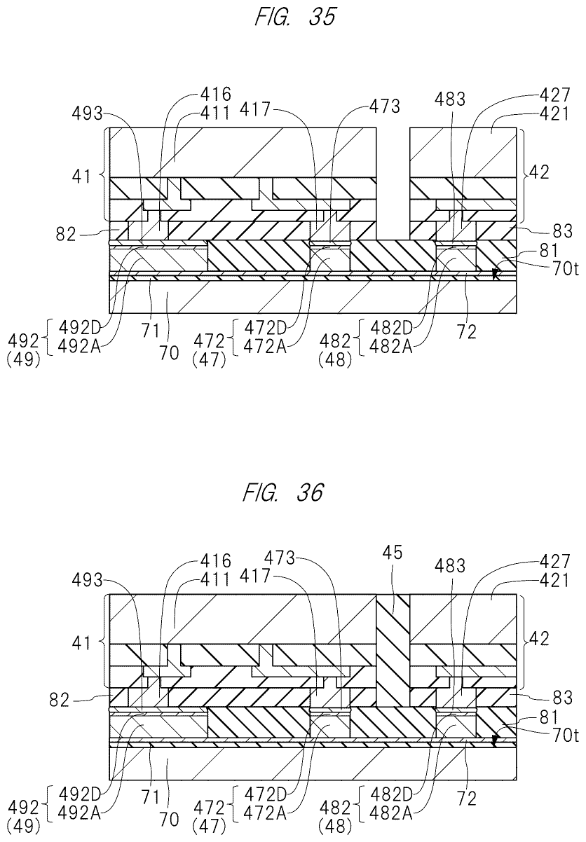

The semiconductor-die mounting step illustrated in FIG. 29 includes the steps illustrated in FIGS. 33 to 35. Each of FIGS. 33 to 35 is an enlarged cross-sectional view illustrating details of the semiconductor-die mounting step illustrated in FIG. 29. In the semiconductor-die mounting step, as illustrated in FIG. 35, the semiconductor die 41 including the IC chip 411 and the die electrode 417 connected to the IC chip 411 and the semiconductor die 42 including the IC chip 421 and the die electrode 427 connected to the IC chip 421 are prepared. Further, in the semiconductor-die mounting step, the semiconductor die 41 and the semiconductor die 42 are mounted on the support body 70 such that the die electrode 417 is arranged on the connection section 47 while the die electrode 427 is arranged on the connection section 48.

Specifically, as illustrated in FIG. 33, firstly, the semiconductor die 41 and the semiconductor die 42 are prepared. This modification example is different from the semiconductor-die mounting step described with reference to FIGS. 13 to 15 in that the insulative layer 82 is formed on the upper surface (die electrode forming surface) of the semiconductor die 41 while the insulative layer 83 is formed on the upper surface (die electrode forming surface) of the semiconductor die 42. In this step, the insulative layer 82 is bonded to the insulative layer 81. It is particularly preferable that the insulative layers 82 and 83 are made of the same material as that of the insulative layer 81 in consideration of bondablity with the insulative layer 81. The detailed configurations of the semiconductor die 41 and the semiconductor die 42 except for the above different points are as previously described with reference to FIG. 4, and will not be repeatedly described.

Next, as illustrated in FIG. 33, the semiconductor die 41 and the semiconductor die 42 are positionally aligned with the support body 70 such that the die electrode 417 is arranged on the connection section 47 while the die electrode 427 is arranged on the connection section 48. The solder layer 473 is formed on the die electrode 417 of the semiconductor die 41. The solder layer 483 is formed on the die electrode 427 of the semiconductor die 42. Incidentally, in the sealing step illustrated in FIG. 29 in this modification example, the sealing body 45 does not contact with the connection section 47, the connection section 48, and the connection section 49. Thus, it is preferable that the solder layer 493 is formed on the bonded surface of the electrode 492 with the larger area than that of the die electrode 416. In this manner, after the semiconductor-die mounting step, a volume of a gap around the solder layer 493 can be decreased. To the contrary, it is preferable that a solder layer is formed also on the die electrode 416 in order to prevent the oxidation of the bonded surface of the die electrode 416.

Next, as illustrated in FIG. 34, the die electrode 417 of the semiconductor die 41 is pressed against the connection section 47 via the solder layer 473. At this time, the die electrode 416 of the semiconductor die 41 is pressed against the solder layer 493. Similarly, the die electrode 427 of the semiconductor die 42 is pressed against the connection section 48 via the solder layer 483. In this step, the solder layer 473 and the pillar connection section 472 of the connection section 47 are temporarily bonded by the solid phase diffusion bonding. Similarly, the solder layer 493 and the electrode 492 of the connection section 49 are temporarily bonded by the solid phase diffusion bonding. Similarly, the solder layer 483 and the pillar connection section 482 of the connection section 48 are temporarily bonded by the solid phase diffusion bonding. At this moment, the insulative layer 81 contacts with the insulative layer 82 and the insulative layer 83, but has not been bonded thereto yet.

Next, the bonded interface between the solder layer 473 and the metal film 472B of the pillar connection section 472, the bonded interface between the solder layer 493 and the metal film 492B of the electrode 492, and the bonded interface between the solder layer 483 and the metal film 482B of the pillar connection section 482 illustrated in FIG. 34 are bonded by the liquid phase diffusion bonding. In this case, as illustrated in FIG. 35, the alloy layer 472D, the alloy layer 482D, and the alloy layer 492D are formed on the bonded interfaces, respectively, by the eutectic reaction. The liquid phase diffusion bonding has been already described in detail, and thus, will not be repeatedly described.

Further, in this modification example, in the semiconductor-die mounting step, the insulative layer 81 and the insulative layer 82 are bonded to each other, and the die electrode 417 is sealed by the insulative layer 81 and the insulative layer 82. Further, in the semiconductor-die mounting step, the insulative layer 81 and the insulative layer 83 are bonded to each other, and the die electrode 427 is sealed by the insulative layer 81 and the insulative layer 83. Timing at which the insulative layer 81 is bonded to the insulative layer 82 and the insulative layer 83 may be almost the same as timing at which the liquid phase diffusion bonding is performed. That is, when the temperature is increased up to a temperature at which the solder layer 473 and the metal film 472B illustrated in FIG. 34 cause the eutectic reaction, the insulative layers 81, 82, and 83 are also heated together. In this manner, the material configuring the insulative layers 81, 82, and 83 is softened, and the contact interfaces thereof are bonded. For a principle of bonding the insulative layers, not only fusion bonding based on dehydration polymerization among hydroxyl groups of the surface of the insulative layer but also softening-or melting-bonding are applicable, depending on materials. If the fusion bonding method is applied, it is desirable that the surface of the insulative layer is activated by plasma before the bonding among the insulative layers.

In this modification example, the connection section 47, the connection section 48, and the connection section 49 are surrounded by the insulative layer 81. Thus, the wet spreading of the solder component during the liquid phase diffusion bonding can be prevented. Therefore, also in this modification example, the die electrodes and the connection sections can be bonded by a small amount of the solder.

In the sealing step illustrated in FIG. 29 after the semiconductor-die mounting step, as illustrated in FIG. 36, the semiconductor die 41 and the semiconductor die 42 are sealed by the sealing body 45. FIG. 36 is an enlarged cross-sectional view illustrating details of the sealing step illustrated in FIG. 29. In this step, the semiconductor die 41 and the semiconductor die 42 are unified by the sealing body 45. In this modification example, the connection section 47, the connection section 48, and the connection section 49 are already sealed, and thus, strictly speaking, the semiconductor die 41 and the semiconductor die 42 are unified via the insulative layer 81. In this step, by the sealing with the sealing body 45, rigidity of the unified structure of the semiconductor die 41 and the semiconductor die 42 is improved.

The volume of the sealing body 45 in this modification example is much smaller than the volume of the sealing body 45 illustrated in FIG. 4. Thus, even when the sealing body 45 thermally expands or thermally shrinks, the connection sections 47, 48, and 49 can maintain high positional accuracy even when being sealed by the sealing body 45.

In the support-body removing step illustrated in FIG. 29 after the sealing step, the support body 70 illustrated in FIG. 36 is removed. The method of removing the support body 70 is similar to the support-body removing step described with reference to FIG. 17, and will not be repeatedly described.

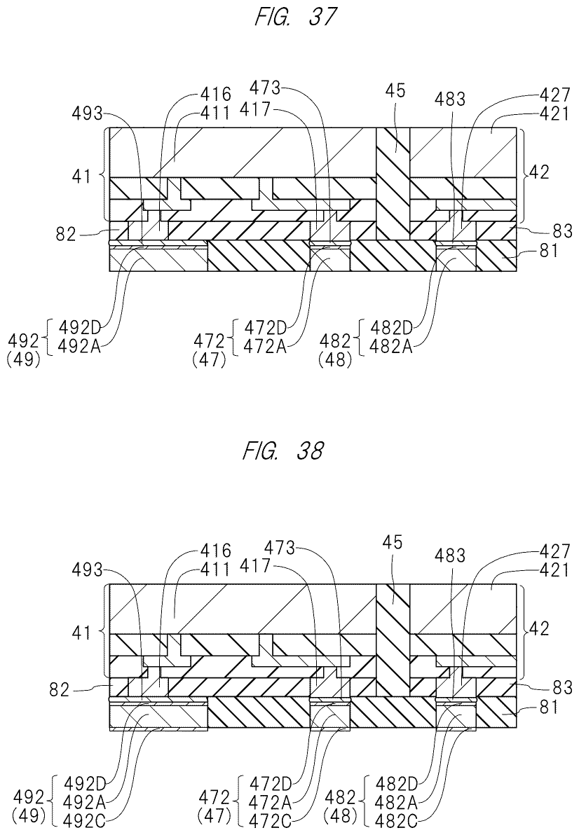

In the connection-section exposing step illustrated in FIG. 29 after the support-body removing step, as illustrated in FIG. 37, a part (the lower surface) of the pillar connection section 472 and a part (the lower surface) of the pillar connection section 482 are exposed from the insulative layer 81. FIG. 37 is an enlarged cross-sectional view illustrating details of the connection-section exposing step illustrated in FIG. 29. In this step, the release layer 71 and the seed layer 72 illustrated in FIG. 36 are removed by, for example, etching. In the example of FIG. 37, in this step, a part (the lower surface) of the electrode 492 is also exposed from the insulative layer 81.

In this step, as illustrated in FIG. 38, it is preferable that the connection sections are exposed from the insulative layer 81, and then, the metal films 472C, 482C, and 492C are formed on the exposed surfaces of the connection sections, respectively. FIG. 38 is an enlarged cross-sectional view illustrating details of the connection-section exposing step continued from FIG. 37. As illustrated in FIG. 38, in this step, the metal film 472C is formed on the surface of the pillar connection section 472 exposed from the sealing body 45. Similarly, the metal film 482C is formed on the surface of the pillar connection section 482 exposed from the sealing body 45. The metal film 492C is formed on the surface of the electrode 492 exposed from the sealing body 45. The metal films 472C, 482C, and 492C are as previously described in detail with reference to FIG. 19, and thus, will not be repeatedly described.

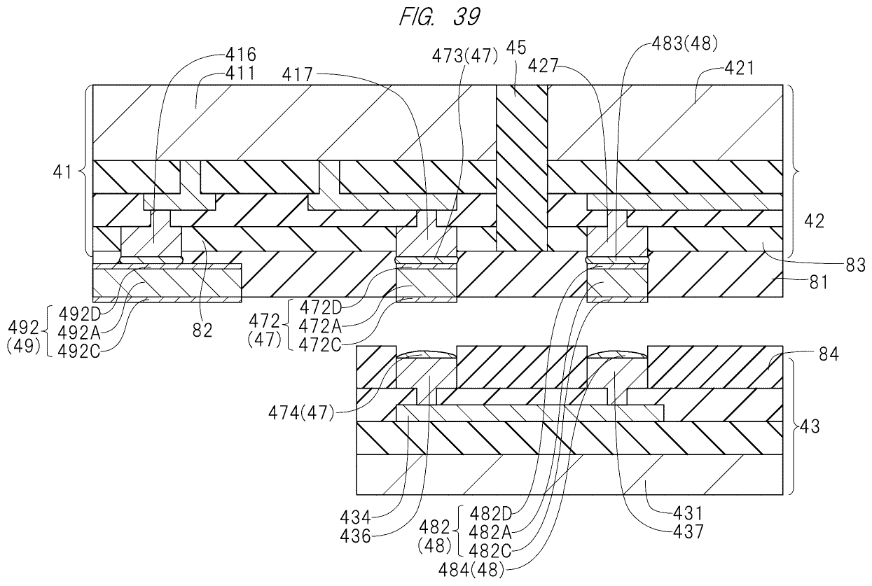

The bridge mounting step illustrated in FIG. 29 includes the steps illustrated in FIGS. 39 to 41. Each of FIGS. 39 to 41 is an enlarged cross-sectional view illustrating details of the bridge mounting step illustrated in FIG. 29. In the bridge mounting step, as illustrated in FIG. 41, the bridge 43 including the bridge electrode 436 connected to the connection section 47 and the bridge electrode 437 connected to the connection section 48 is prepared. Further, in the bridge mounting step after the connection-section exposing step, the bridge 43 is mounted on the structure sealed by the sealing body 45 such that the bridge electrode 436 is arranged on the pillar connection section 472 while the bridge electrode 437 is arranged on the pillar connection section 482.

Specifically, as illustrated in FIG. 39, firstly, the bridge 43 is prepared. This modification example is different from the semiconductor-die mounting step described with reference to FIGS. 13 to 15 in that the insulative layer 84 is formed on the upper surface (bridge electrode forming surface) of the bridge 43 while the bridge electrode 436 and the bridge electrode 437 are sealed by the insulative layer 84. The detailed configuration of the bridge 43 except for the different points is as previously described with reference to FIG. 4, and thus, will not be repeatedly described.

Next, as illustrated in FIG. 39, the bridge 43 and the structure sealed by the sealing body 45 are positionally aligned such that the bridge electrode 436 is arranged on the pillar connection section 472 while the bridge electrode 437 is arranged on the pillar connection section 482. The solder layer 474 is formed on the bridge electrode 436. The solder layer 484 is formed on the bridge electrode 437.

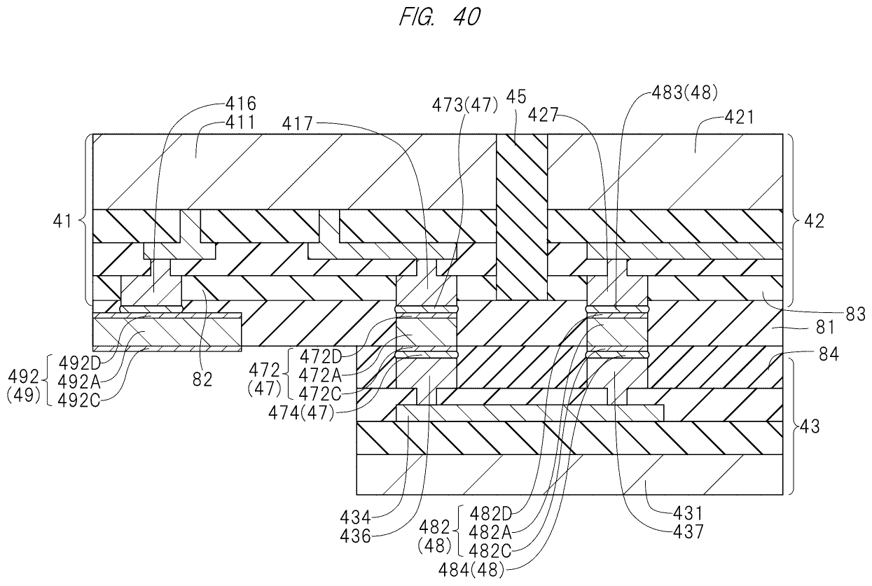

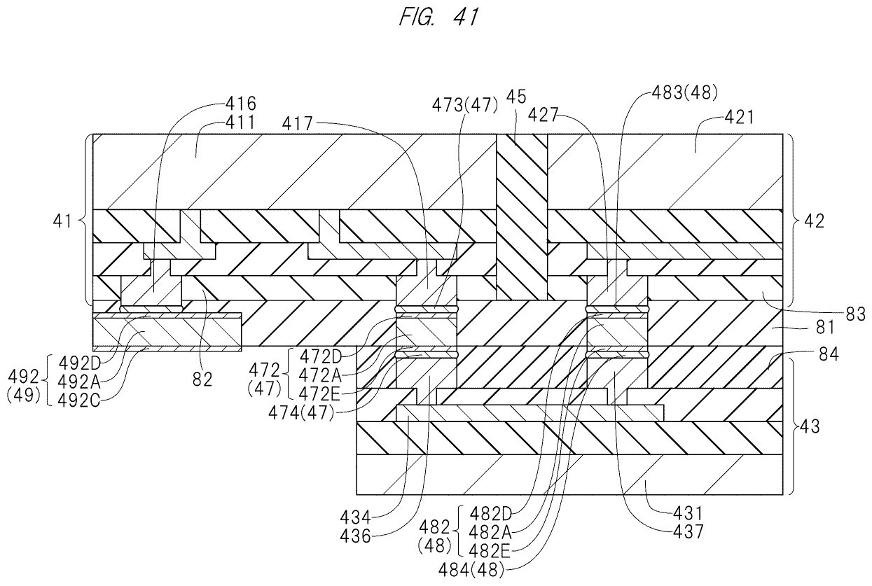

Next, as illustrated in FIG. 40, the bridge electrode 436 of the bridge 43 is pressed against the pillar connection section 472 of the connection section 47 via the solder layer 474. At this time, the bridge electrode 437 of the bridge 43 is pressed against the pillar connection section 482 of the connection section 48 via the solder layer 484. In this step, the solder layer 474 and the pillar connection section 472 (specifically, the metal film 472C of the pillar connection section 472) of the connection section 47 are temporarily bonded by the solid phase diffusion bonding. Similarly, the solder layer 484 and the pillar connection section 482 (specifically, the metal film 482C of the pillar connection section 482) of the connection section 48 are temporarily bonded by the solid phase diffusion bonding.

At this time, in this modification example, the insulative layer 81 and the insulative layer 84 contact with each other. However, at this time, the insulative layer 81 and the insulative layer 84 are not bonded to each other.

Next, the bonded interface between the solder layer 474 and the metal film 472C of the pillar connection section 472 and the bonded interface between the solder layer 484 and the metal film 482C of the pillar connection section 482 illustrated in FIG. 40 are bonded by the liquid phase diffusion bonding. The liquid phase diffusion bonding method is as described above, and thus, will not be repeatedly described. By the liquid phase diffusion bonding, the metal films 472C and 482C illustrated in FIG. 40 turn into the alloy layers 472E and 482E (see FIG. 41) formed by the eutectic reaction between tin as the main component of the solder layers and the material (such as gold) of the metal films, respectively.

Further, in the bridge mounting step in this modification example, the insulative layer 81 and the insulative layer 84 are bonded to each other. Timing at which the insulative layer 81 and the insulative layer 84 are bonded to each other is timing at which the liquid phase diffusion bonding is performed. That is, when the temperature is increased up to a temperature at which the solder layer 474 and the metal film 472C illustrated in FIG. 40 cause the eutectic reaction, the insulative layer 81 and the insulative layer 84 are also heated together. In this manner, the material configuring the insulative layer 81 and the insulative layer 84 is softened, and the contact interfaces thereof are bonded. As a principle of the bonding among the insulative layers, fusion bonding based on the dehydration polymerization among hydroxyl groups on the surface of the insulative layer described above or the like may be applied.

Note that this modification example has been described as the example using the insulative layer 81 to the insulative layer 84 illustrated in FIG. 28. However, the exemplary configuration illustrated in FIG. 4 or the configuration in the modification example described in FIG. 24 may be partially applied. For example, instead of the insulative layer 84 illustrated in FIG. 28, the bridge electrode 436 and the bridge electrode 437 may be sealed by the sealing body 44 illustrated in FIG. 4 or the sealing body 105 illustrated in FIG. 24.

Further, this modification example has been described with reference to the example in which the upper surface of the bridge 43 is covered with the insulative layer 84. However, the insulative layer 84 may not be formed. For example, when a functional insulative film called non-conductive film (NCF) is used instead of the insulative layer 84, the NCF is arranged to cover the insulative layer 81, the connection section 47, and the connection section 48 after the step illustrated in FIG. 38. In this case, in the bridge mounting step, the solid phase diffusion bonding and the liquid phase diffusion bonding are performed in a state in which the bridge electrode 436 and the bridge electrode 437 are penetrated through the NCF to contact with the connection section 47 or the connection section 48 by the pressing of the bridge 43 having the configuration illustrated in FIG. 20 against the NCF, and, as a result, a structure similar to that of the chip integrated module 40D illustrated in FIG. 28 is provided.

### Method of Manufacturing Chip Integrated Body

Next, a method of manufacturing the chip integrated body will be described below with reference to FIG. 3. Firstly, the wide-range wiring layer 102 is formed on the support body not illustrated. A method of forming the wide-range wiring layer 102 is not particularly limited, and, for example, a build-up method of example may be applied. Next, a plurality of electrodes 403 and a plurality of tall pillars 401 are then formed on the wide-range wiring layer 102. The connection-section forming step described with reference to FIGS. 8 to 12 may be applied to the method of forming the electrodes 403 and the tall pillars 401. Further, in this step, the electrode 148 and the conductor post 146 are also formed. If the electrode 148 and the electrode 403 have the same thickness as each other, these electrodes can be collectively formed at the same timing. To the contrary, the conductor post 146 and the tall pillar 401 have a different thickness from each other, and thus, these components are formed separately.

Next, the chip integrated module 40 is then mounted on the tall pillars 401. The tall pillars 401 are connected to the connection section 49 illustrated in FIG. 4. The method of connecting the tall pillars 401 and the connection section 49 is not particularly limited. However, these components may be connected via, for example, a solder layer not illustrated. At this time, it is preferable that the liquid phase diffusion bonding is applied in order to prevent remelting of the solder layers in the chip integrated module 40.

Next, various members formed in the chip layer 104 are sealed by the sealing body 105. In the example of FIG. 3, the conductor posts 146, the electrodes 148, the chip integrated module 40, the tall pillars 401, and the electrodes 403 are sealed by the sealing body 105. Then, the support body not illustrated is removed from the wide-range wiring layer 102. Further, an upper portion of the sealing body 105 is ground to expose the conductor posts 146 and the chip integrated module 40.

Next, the connection layer 106 is formed on the sealing body 105. More specifically, the connection layer 106 is formed on the sealing body 105 such that the wirings included in the connection layer 106 are connected to the exposed parts of the conductor posts 146 or the exposed part of the chip integrated module 40. For example, the electrodes 140 formed on the connection layer 106 are connected to the conductor posts 146 via the conductor vias 142.

Next, the heat radiating mechanism 20 is mounted on the contact section 222. Further, the optical module 13 connected with the optical fiber 600 (see FIG. 5) and the optical fiber 610 (see FIG. 5) is connected to the electrodes 140. The heat radiating member 136 is previously connected to the optical module 13. Next, when the plurality of external terminals 30 are mounted on the wide-range wiring layer 102, the chip integrated body 10 illustrated in FIG. 3 is provided.

### Modification Examples of Chip Integrated Body

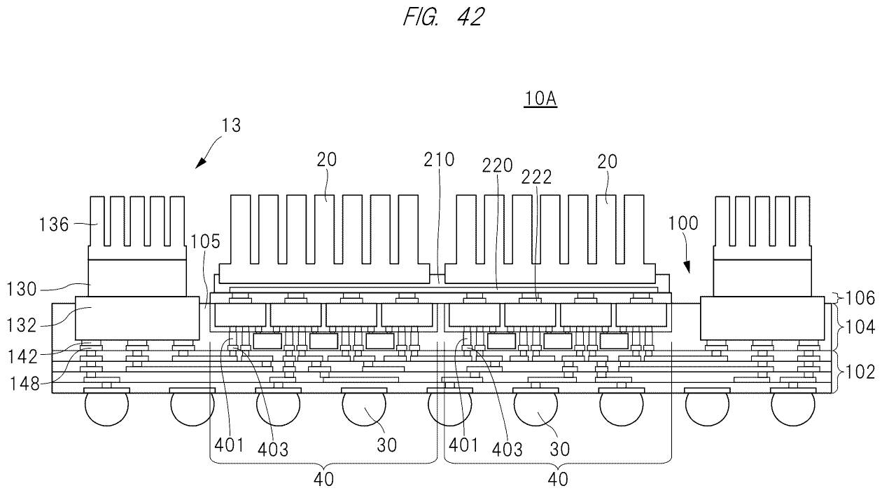

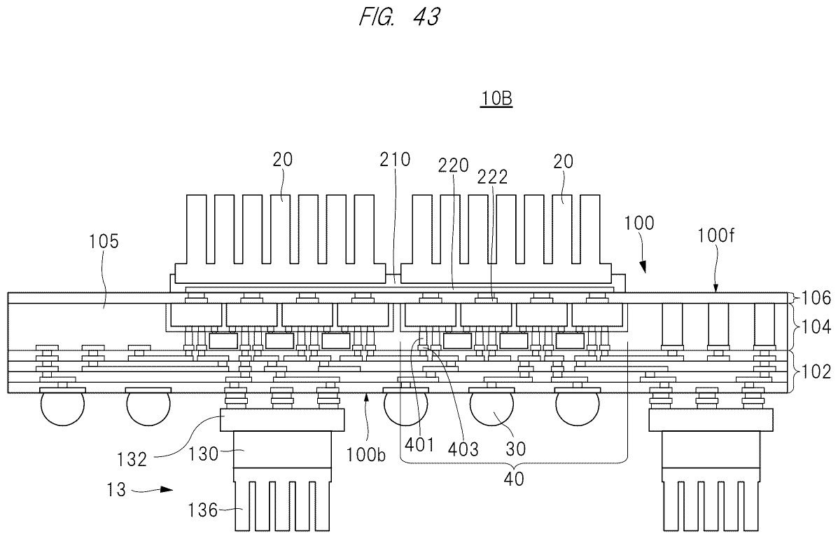

Next, modification examples of the chip integrated body illustrated in FIG. 3 will be described. Each of FIGS. 42 and 43 is an explanatory diagram illustrating a modification example of the chip integrated body illustrated in FIG. 3. A chip integrated body 10A illustrated in FIG. 42 is different from the chip integrated body 10 illustrated in FIG. 3 in that a part of the optical module 13 is embedded in the chip layer 104 of the integrated layer 100. Specifically, the connector 132 of the optical module 13 is sealed by the sealing body 105. The connector 132 and the electrodes 148 are connected via the conductor vias 142. When the connector 132 is embedded in the chip layer 104, the total height of the chip integrated body 10A can be reduced, and the signal transmission characteristics can be improved more than in FIG. 3 by reducing the distance between the chip integrated module and the optical transceiver. Further, the optical transceiver 130 is exposed from the chip layer 104 and the connection layer 106, and thus, the optical transceiver 130 is easily attached and detached.

A chip integrated body 10B illustrated in FIG. 43 is different from the chip integrated body 10 illustrated in FIG. 3 in that the optical module 13 is arranged on a back surface 100b of the integrated layer 100. The integrated layer 100 has a front surface 100f on which the heat radiating mechanism 20 is mounted and the back surface 100b opposite to the front surface 100f. The optical module 13 is mounted on the back surface 100b. When the optical module 13 is arranged on the back surface 100b, the distance between the heat radiating mechanism 20 and the optical module 13 is large, and thus, thermal effects from the heat radiating mechanism 20 can be reduced. Further, in the example of FIG. 43, the optical module 13 is arranged at a position overlapping with the chip integrated module 40 in the thickness direction of the integrated layer 100. In this case, the distance between the chip integrated module 40 and the optical module 13 is small, and thus, electric signal transmission efficiency can be improved.

### Modification Examples of Countermeasures Against Reduction of Parasitic Capacity in Bridge

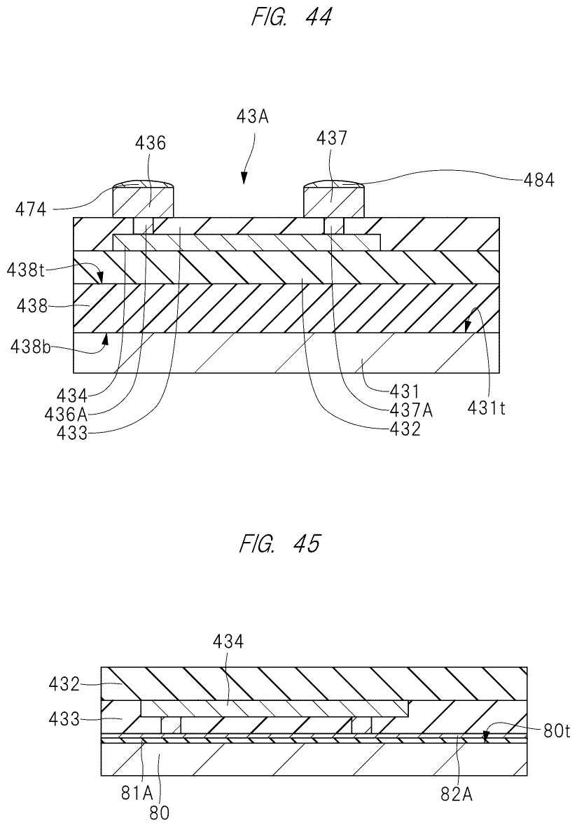

A signal is transmitted at ultra-high speed in the signal transmission path via the bridge 43 illustrated in FIG. 4. In the case of the high-speed signal transmission path, it is preferable to reduce electric parasitic capacity on the signal transmission path. A technique for reducing the parasitic capacity caused between the chip 431 and the wiring 434 illustrated in FIG. 4 will be described below as modification examples. FIG. 44 is a cross-sectional view illustrating a modification example of the bridge illustrated in FIG. 4.

A bridge 43A illustrated in FIG. 44 is different from the bridge 43 illustrated in FIG. 4 in that it further includes an insulative layer 438 between the insulative layer 432 and the chip 431. Other points are similar to those of the bridge 43 illustrated in FIG. 4. The bridge 43A includes the chip 431, the insulative layers 438, 432, and 433 sequentially stacked on the chip 431, and the wiring 434 sandwiched between the insulative layer 432 and the insulative layer 438 and connected to the bridge electrode 436 and the bridge electrode 437. The insulative layer 438 is a thick insulative layer. The insulative layer 438 is thicker than the insulative layer 432 and the insulative layer 433. The insulative layer 438 has a surface 438t adhered to the insulative layer 432 and a surface 438b adhered to the chip 431. Each of the surface 438t and the surface 438b has an adhesion function, and the insulative layer 438 is adhered and fixed to the insulative layer 432 and the chip 431 by the adhesion function of the surface 438t and the surface 438b. The entire insulative layer 438 may be an adhesive layer.

When the insulative layer 438 interposes between the insulative layer 432 and the chip 431 as seen in the bridge 43A, the distance between the wiring 434 and the chip 431 can be increased. Consequently, the parasitic capacity caused between the chip 431 and the wiring 434 can be made less than that of the bridge 43 illustrated in FIG. 4.

The bridge 43A provided with the insulative layer 438 is easier to be warped than the bridge 43 illustrated in FIG. 4. The bridge is warped and deformed by a film forming stress (resin hardening shrinkage or thermal shrinkage) caused in forming the insulative layer 438. It is desirable to use a material with a low elastic modulus for decreasing the warpage deformation. Further, it is preferable to use a resin material with a lower hardening temperature and thermal decomposition temperature than those of the insulative layer 432 and the insulative layer 433 for the same point. For example, when the insulative layer 432 and the insulative layer 433 are made of polyimide resin while the insulative layer 438 is made of epoxy resin, the insulative layer 438 is made of a resin material with a lower hardening temperature and thermal decomposition temperature than those of the insulative layer 432 and the insulative layer 433, and thus, the warpage deformation of the bridge 43A can be suppressed.

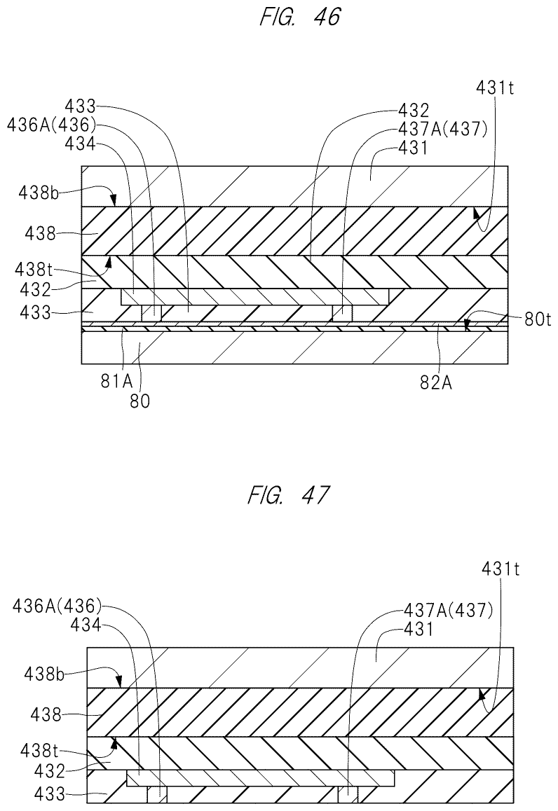

The bridge 43A illustrated in FIG. 44 is manufactured as, for example, follows. Each of FIGS. 45 to 47 is a cross-sectional view illustrating an outline of steps of manufacturing the bridge illustrated in FIG. 44. The method of manufacturing the bridge 43A includes a wiring-layer forming step illustrated in FIG. 45, a wiring-layer transferring step illustrated in FIG. 46, a support-body removing step illustrated in FIG. 47, and a bridge-electrode forming step illustrated in FIG. 44.

Firstly, in the wiring layer forming step, the insulative layer 433, the wiring 434, and the insulative layer 432 are sequentially stacked on a support body 80 illustrated in FIG. 45. Specifically, in the wiring-layer forming step, the support body 80 illustrated in FIG. 45 is prepared. A release layer 81A and a seed layer 82A are previously formed on an upper surface 80t of the support body 80. A material of the support body 80 is not particularly limited if the material is a plate rigid enough not to lose workability in each step until the support-body removing step described later. For example, a semiconductor substrate such as silicon wafer, a plate made of an inorganic material such as glass or sapphire substrate, a resin plate, and the like are exemplified. The release layer 81A is similar to the release layer 71 described with reference to FIG. 8 while the seed layer 82A is similar to the seed layer 72 described with reference to FIG. 8, and thus, these layers will not be repeatedly described.

Further, in the wiring-layer forming step, the support body 80 is prepared, and then, the insulative layer 433 is deposited on the seed layer 82A. Next, an opening is formed in a part of the insulative layer 433, and the wiring 434 is formed in the opening. Although not repeatedly described, the method of forming the opening and the method of forming the wiring 434 in the opening may be achieved by the photolithography technique described with reference to FIGS. 9 and 10. Next, the insulative layer 432 is formed to cover the insulative layer 433 and the wiring 434 to obtain a structure illustrated in FIG. 45.

Next, in the wiring-layer transferring step, as illustrated in FIG. 46, the insulative layer 432 and the chip 431 on the support body 80 are bonded via the insulative layer 438. Note that FIG. 46 illustrates an example in which the divided chip 431 is bonded. However, as a modification example, in this step, a silicon wafer prepared before the division, a glass substrate prepared before the division, or a sapphire substrate prepared before the division may be bonded instead of the chip 431. When the substrate prepared before the division is bonded in this step, a dividing step of dicing the substrate to obtain a plurality of bridges 43A (see FIG. 44) is performed after the bridge-electrode forming step. This modification example is preferable in terms of the improvement in manufacturing efficiency since a large number of bridges 43A can be collectively manufactured. This step including the modification examples can be expressed as follows. That is, in the wiring-layer transferring step, the substrate and the insulative layer 432 on the support body 80 are bonded via the insulative layer 438. The “substrate” described herein includes not only the chip illustrated in FIG. 46 but also a semiconductor substrate such as a silicon wafer prepared before the division, a glass substrate prepared before the division, or a sapphire substrate prepared before the division. As described with reference to FIG. 44, each of the surface 438t and the surface 438b of the insulative layer 438 has the adhesion function, and thus, the chip 431 and the insulative layer 432 on the support body 80 are bonded and fixed via the insulative layer 438. In this modification example, note that the chip 431 and the wiring 434 are not electrically connected. When the chip 431 is not connected to other circuit, the chip 431 illustrated in FIG. 44 may be replaced with a substrate (such as semiconductor substrate or glass substrate) on which an integrated circuit is not formed. Alternatively, a bridge from which the chip 431 is removed may be employed as described later.

Next, in the support-body removing step, as illustrated in FIG. 47, the release layer 81A (see FIG. 46) is decomposed by, for example, giving energy to the release layer 81A. After the support-body removing step, the conductor sections connected to the bridge electrode 437 and the bridge electrode 436 (a conductor section 437A connected to the bridge electrode 437 and a conductor section 436A connected to the bridge electrode 436) are exposed. The conductor section 436A and the conductor section 437A function as contactors for electrically connecting the wiring substrate and the bridge electrodes. In this step, the release layer 81A and the seed layer 82A illustrated in FIG. 46 are removed by, for example, etching.

Next, in the bridge-electrode forming step, as illustrated in FIG. 44, the bridge electrode 437 is formed on the conductor section 437A connected to the wiring 434, and the bridge electrode 436 is formed on the conductor section 436A connected to the wiring 434. Further, in this step, the solder layer 474 is formed at an end surface of the bridge electrode 436, and the solder layer 484 is formed at an end of the bridge electrode 437.

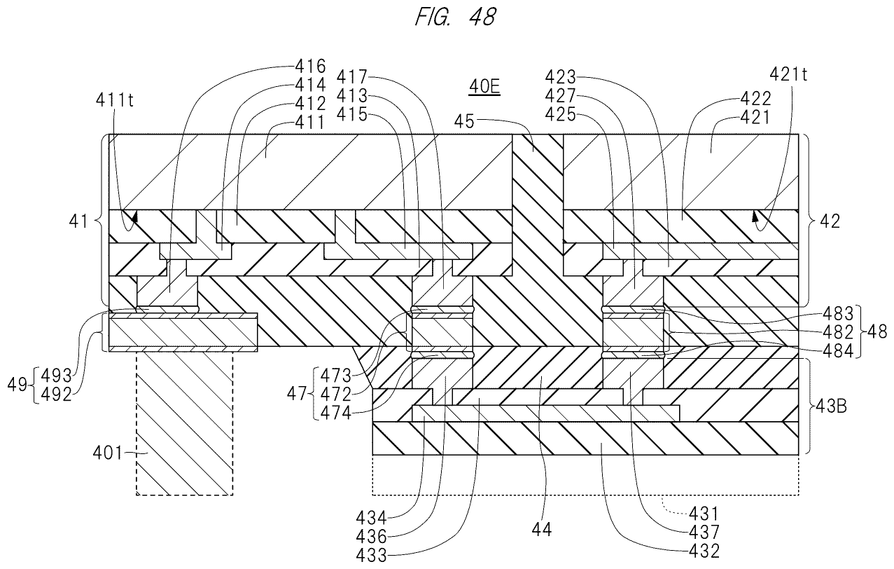

A large-sized wafer or panel is subjected to the above steps, and is divided into predetermined-sized bridges, and, as a result, the bridges 43A illustrated in FIG. 44 can be formed. The bridge 43A can be used in place of, for example, the bridge 43 illustrated in FIG. 4. The replacement of the bridge 43 with the bridge 43A reduces the parasitic capacity between the chip 431 and the wiring 434, and thus, is particularly preferable in the high-speed signal transmission. In this modification example, note that the bridge 43A illustrated in FIG. 44 and a bridge 43B illustrated in FIG. 48 will be described as modification examples of the bridge 43 illustrated in FIG. 4. However, the bridge 43A and the bridge 43B may be replaced with the bridge 43 illustrated in any of the chip integrated module 40A illustrated in FIG. 25, the chip integrated module 40B illustrated in FIG. 26, the chip integrated module 40C illustrated in FIG. 27, and the chip integrated module 40D illustrated in FIG. 28.

FIG. 48 is a cross-sectional view illustrating another modification example of the bridge illustrated in FIG. 4. The bridge 43B illustrated in FIG. 48 is different from the bridge 43 illustrated in FIG. 4 in that a part corresponding to the chip 431 is removed. In the bridge 43B, the chip 431 is not arranged near the wiring 434, and thus, effects of the parasitic capacity on the wiring 434 can be further reduced.

However, the bridge 43B is less rigid than the bridge 43 illustrated in FIG. 4 and the bridge 43A illustrated in FIG. 44. Thus, until the semiconductor die 41 and the semiconductor die 42 are bonded to the bridge 43B while the bridge electrode 436 and the bridge electrode 437 are sealed therearound, it is preferable that each step of manufacturing a chip integrated module 40E is performed as similar to the manufacturing method described with reference to FIGS. 20 to 23 in a state in which the insulative layer 433 is held on the chip 431. Then, in the state illustrated in FIG. 23, the manufacturing method of removing the chip 431 is preferably performed. As the method of removing the chip 431, for example, if the chip 431 is made of silicon, the chip may be removed by dry etching or the like. If the chip 431 is made of an inorganic material such as glass, the chip may be removed by previously providing a release layer between the chip 431 and the insulative layer 433, and then, decomposing (ablating) the release layer by energy beam such as laser. As a modification example of the method of manufacturing the bridge 43B, note that the manufacturing method described with reference to FIGS. 44 to 47 may be used.

### Another Modification Example of Chip Integrated Module

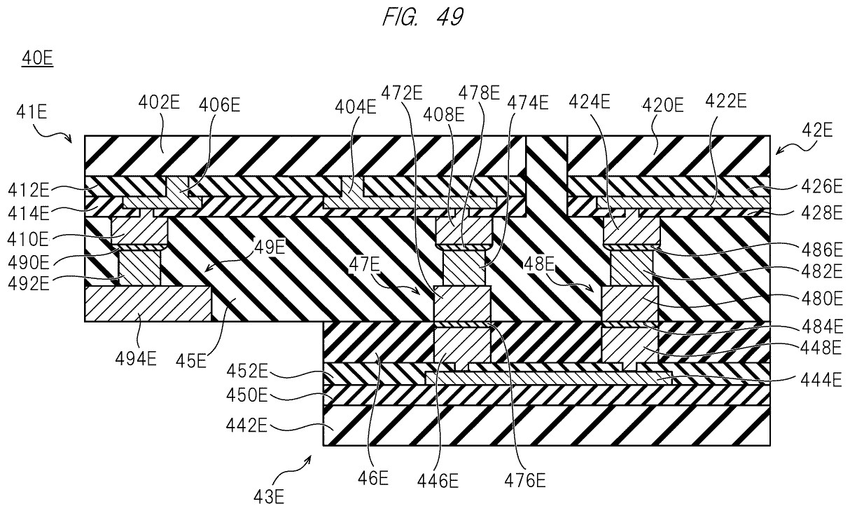

FIG. 49 is a diagram illustrating a configuration of a part of a chip integrated module as a modification example of FIG. 4. As illustrated in FIG. 49, the chip integrated module 40E according to the present embodiment includes a first die 41E, a second die 42E, a bridge 43E, and sealing members 45E and 46E sealing these components. The first die 41E is connected to the bridge 43E via a first connection section 47E. Further, the bridge 43E is connected to the second die 42E via a second connection section 48E. Furthermore, the first die 41E is connected to the outside of the chip integrated module 40E via a third connection section 49E.

The first die 41E includes a first integrated circuit chip 402E, die electrodes 408E and 410E, wirings 404E and 406E connected to the first integrated circuit chip 402E, and insulative layers 412E and 414E in which the wirings 404E and 406E are embedded. The wirings 404E and 406E are different from a wiring layer included in the first integrated circuit chip 402E. More specifically, each of the wirings 404E and 406E may be a thick-film wiring using an insulative film made of organic (or occasionally inorganic) resin, and is called redistribution layer (RDL). Note that the wiring included in the second die and the bridge is also called redistribution layer. Further, a second integrated circuit chip 420E and a third integrated circuit chip 442E described later may also have a similar configuration to that of the first integrated circuit chip 402E.

The second die 42E includes the second integrated circuit chip 420E, a die electrode 424E, a wiring 422E connected to the second integrated circuit chip 420E, and insulative layers 426E and 428E in which the wiring 422E is embedded.

The bridge 43E includes the third integrated circuit chip 442E, bridge electrodes 446E and 448E, a wiring 444E connected to the third integrated circuit chip 442E, and insulative layers 450E and 452E in which the wiring 444E is embedded. In the present embodiment, the wiring 444E configures a part of the bridge electrically connected to the first connection section 47E and the second connection section 48E. The bridge according to the present embodiment is a pillar suspended bridge. The wiring 444E according to the present embodiment is electrically connected to the third integrated circuit chip 442E, and the wiring 444E and the third integrated circuit chip 442E function together as a bridge.

The first connection section 47E includes pillar connection sections 474E and 472E. In the present embodiment, the pillar connection section is a pillar conductor of um size (also referred to as micro-pillar). The pillar connection sections 472E and 474E are pillar conductors facing in a direction from the bridge 43E toward the first die 41E. In the present embodiment, a cross-section area of a portion of the pillar connection section 472E, the portion being connected to the pillar connection section 474E, is larger than a cross-section area of a portion of the pillar connection section 474E, the portion being connected to the pillar connection section 472E. In this modification example, the pillar connection section 474E is connected to the die electrode 408E via solder 478E. Further, the pillar connection section 472E is connected to the bridge electrode 446E via solder 476E.

The second connection section 48E includes pillar connection sections 480E and 482E. The pillar connection sections 480E and 482E are pillar conductors facing in a direction from the bridge 43E toward the second die 42E. In this modification example, a cross-section area of a portion of the pillar connection section 480E, the portion being connected to the pillar connection section 482E, is larger than a cross-section area of a portion of the pillar connection section 482E, the portion being connected to the pillar connection section 480E. In this modification example, the pillar connection section 482E is connected to the die electrode 424E via solder 486E. Further, the pillar connection section 480E is connected to the bridge electrode 448E via solder 484E.

The third connection section 49E includes a pillar connection section 492E. The pillar connection section 492E is a pillar conductor facing in a direction from the first die 41E toward the outside. The pillar connection section 492E is connected to the die electrode 410E via solder 490E. Further, the pillar connection section 492E is connected to an electrode pad 494E connected to the outside (such as the wide-range wiring layer 102). Note that the third connection section 49E may include various components in addition to (or instead of) the components illustrated in FIG. 49. For example, the third connection section 49E may include various components connectable to the wide-range wiring layer 102 (see FIG. 3) such as a deep via, a tall pillar, and a pillar connection section provided to be lower than the electrode pad 494E.

Note that this modification example has been described in the example of the die in which the bridge includes the integrated circuit chip. However, the bridge may not include the integrated circuit chip, and may be mainly made of a wiring and an insulative layer in which the wiring is embedded. Further, the present embodiment has been described in the example in which the die and the bridge are connected via two pillar connection sections with mutually different diameters. The present invention is not limited to this example, and the die and the bridge may be connected via one pillar connection section, or three or more pillar connection sections.

### First Modification Example

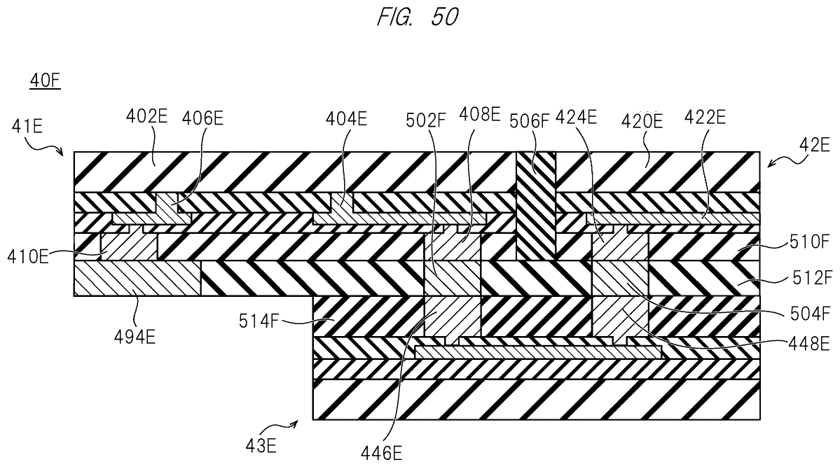

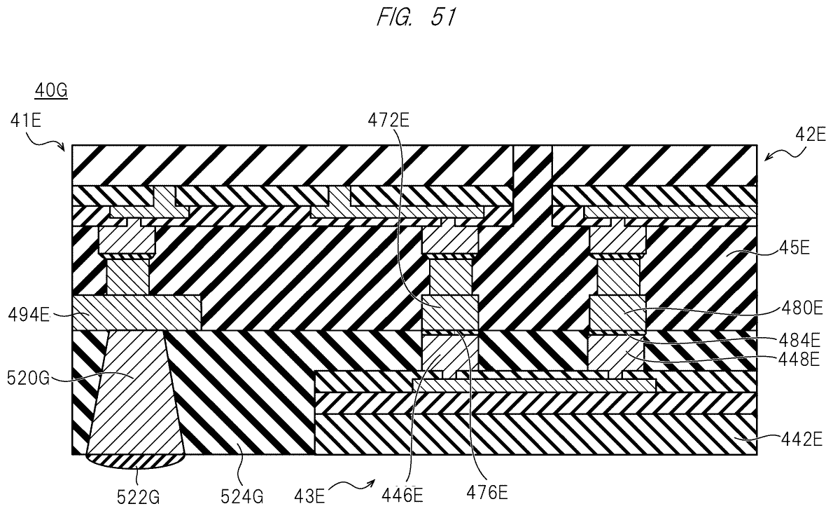

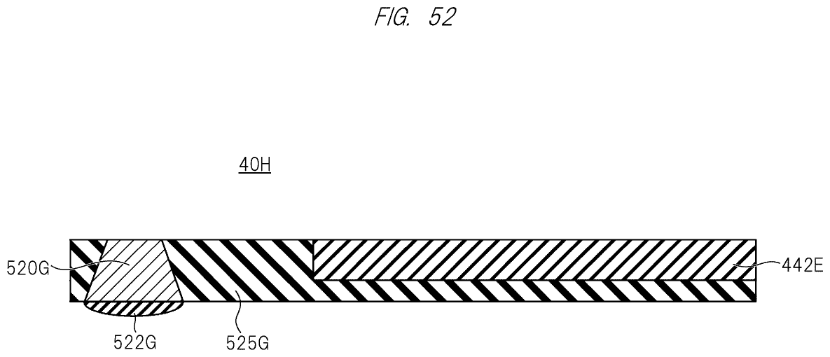

FIG. 50 is a diagram illustrating a configuration of a chip integrated module according to a first modification example of the chip integrated module illustrated in FIG. 49. Of components of a chip integrated module 40F illustrated in FIG. 50, the substantially same components as those of the chip integrated module 40E illustrated in FIG. 49, are denoted with the same reference numerals, and the description thereof will be omitted as needed.

The chip integrated module 40F according to the first modification example is different from the chip integrated module 40E (see FIG. 49) in the configurations of the first connection section, the second connection section, and the third connection section. Specifically, in the first modification example, a pillar connection section or electrode pad is directly connected to other electrode or wiring without via solder. More specifically, in the first connection section according to the first modification example, a pillar connection section 502F is connected to the die electrode 408E and the bridge electrode 446E. Further, in the second connection section, a pillar connection section 504 is connected to the die electrode 424E and the bridge electrode 448E. Furthermore, in the third connection section, the electrode pad 494E is connected to the die electrode 410E. Here, various well-known hybrid bonding techniques may be used to connect between the pillar connection section and the die electrode or the bridge electrode or between the die electrode and the electrode pad.

In the first modification example, various conductors are embedded in insulators. Specifically, the die electrodes 408E, 410E, and 424E are embedded in an insulative film 510F. Further, the electrode pad 494E and the pillar connection sections 502F and 504F are embedded in an insulative layer 512F. Furthermore, the bridge electrodes 446E and 448E are embedded in an insulative film 514F. The first die 41E and the second die 42E are sealed by insulative resin 506F. Appropriate material systems and process conditions are selected in various well-known hybrid bonding techniques to connect and bond the die electrode 408E and the pillar connection section 502F, and the insulative film 510F and the insulative layer 512F. Similarly, also in the bridge, the bridge electrodes 446E and 448E and the insulative layer 512F can be connected and bonded, and the insulative film 514F and the insulative layer 512F can be connected and bonded.

Note that the first modification example has been described in the example in which the bridge includes the integrated circuit chip. However, the present invention is not limited to this example, and the bridge may not include the integrated circuit chip. The bridge may include a solid chip made of various materials such as silicon and glass instead of the integrated circuit chip.

### Second Modification Example

FIG. 51 is a diagram illustrating a configuration of a chip integrated module according to a second modification example of the chip integrated module illustrated in FIG. 49. In a chip integrated module 40G according to the second modification example, a deep via 520G is formed in insulative resin 524G sealing the bridge 43E, and the first die 41E is electrically connected to an outside conductor via the deep via 520G. More specifically, the deep via 520G is connected to the electrode pad 494E connected to the bridge 43E, and solder 522G connected to the outside conductor may be formed at the end of the deep via 520G. Here, the deep via 520G may be formed such that its diameter gradually increases from the electrode pad 494E toward the solder 522G. Further, in the second modification example, the lower surface of the third integrated circuit chip 442E may be exposed.

In the second modification example, the bridges including the bridge 43E are sealed by the insulative resin 524G. Thus, in the second modification example, the bridges are protected by the insulative resin 524G. Further, the connection parts between the bridges and other members can be sealed (underfilled) at the same time of the sealing of the bridges. Furthermore, parts where the terminals of the dies are formed are flattened to make a pitch between the wide-range wiring layer and the connection part narrower.

### Third Modification Example

FIG. 52 is a diagram for explaining a chip integrated module according to a third modification example of the chip integrated module illustrated in FIG. 49. FIG. 52 illustrates vicinity of a part of the deep via 520G and the third integrated circuit chip 442E in a chip integrated module 40H according to a modification example of the chip integrated module 40G illustrated in FIG. 51. The third modification example will be described mainly in different points from the chip integrated module 40G according to the second modification example. Further, the chip integrated module according to the third modification example may include the components of the chip integrated module 40G according to the second modification example. That is, components not illustrated in FIG. 52 may be substantially the same as the components illustrated in FIG. 51. In the chip integrated module 40H according to the third modification example, the lower surface of the third integrated circuit chip 442E is not exposed as different from the second modification example. More specifically, the lower surface of the third integrated circuit chip 442E is covered with insulative resin 525G.

### Fourth Modification Example

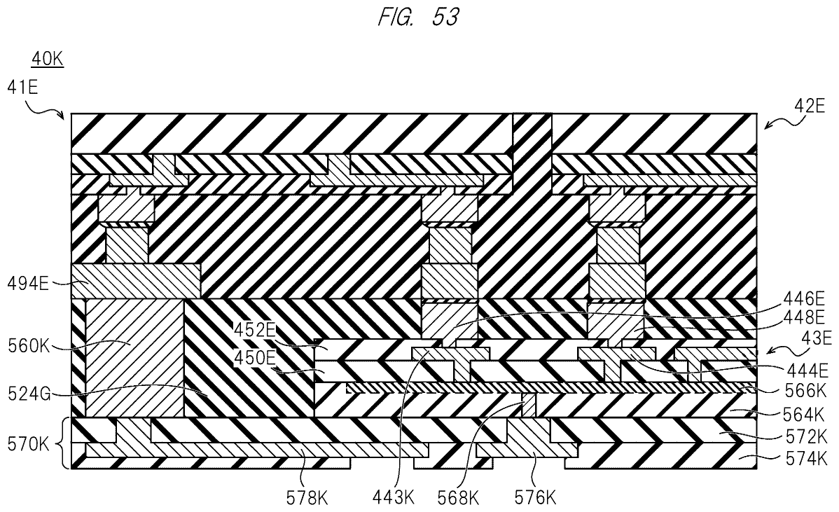

FIG. 53 is a diagram illustrating a chip integrated module according to a fourth modification example of the chip integrated module illustrated in FIG. 49. In a chip integrated module 40K according to the fourth modification example, a wiring layer 570 is formed below the insulative resin 524G in which the bridge 43E is embedded. The first die 41E and the bridge 43E are connected to a wiring formed in the wiring layer 570k.

The wiring layer 570K according to the fourth modification example includes various conductors embedded in insulative layers, and specifically includes a wiring 578K, an electrode 576K, and the like embedded in insulative layers 572K and 574K. The wiring 578K and the electrode 576K may be electrically connected to outside conductors. According to the fourth modification example, for example, a terminal may be arranged in the bridge. Further, for example, power may be supplied from the outside directly to the bridge.

A region surrounded by a broken line in a third integrated circuit chip 564K according to the fourth modification example includes a functional element 566K having various functions. The functional element 566K is connected to the electrode 576K formed in the wiring layer 570K via a via 568K formed inside the third integrated circuit chip 564K. Further, in the present embodiment, the bridge electrode 446E is connected to a wiring 443K, and the bridge electrode 448E is connected to the wiring 444E. In this manner, in the fourth modification example, the first die 41E and the second die 42E are connected via the functional element 566K.

Further, the electrode pad 494E electrically connected to the first die 41E is connected to the wiring 578K of the wiring layer 570K via a tall pillar 560K. As different from the deep via 520G (see FIG. 51) described in the second modification example, a cross-section area size of the tall pillar 560K may be substantially constant from the electrode pad 494E toward the wiring 578K.

### Fifth Modification Example

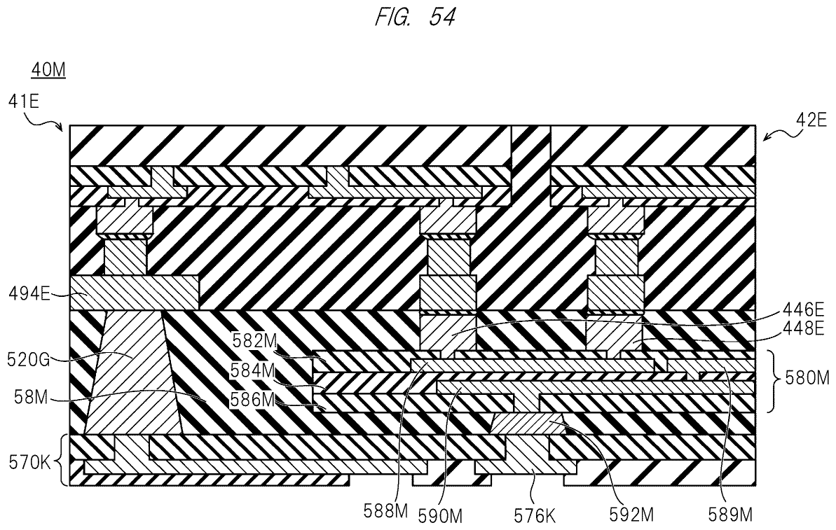

FIG. 54 is a diagram illustrating a chip integrated module according to a fifth modification example of the chip integrated module illustrated in FIG. 49. In a chip integrated module 40M according to the fifth modification example, a bridge mainly includes a wiring. Specifically, a bridge 580M according to the fifth modification example includes various wirings and insulative layers in which the wirings are embedded, but does not include the integrated circuit chip.

The bridge 580M includes a wiring 588M embedded in an insulative layer 582M, and the wiring 588M is connected to the bridge electrodes 446E and 448E. Further, wirings 589M and 590 are embedded in the insulative layers 582M, 584M, and 586M. The wirings 589M and 590M are connected to the electrode 576K of the wiring layer 570K via a contact via 592M.

### Another Modification Examples of Method of Manufacturing Chip Integrated Module

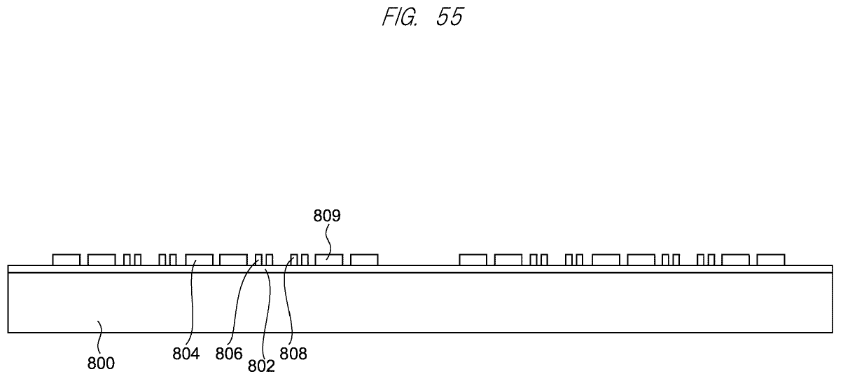

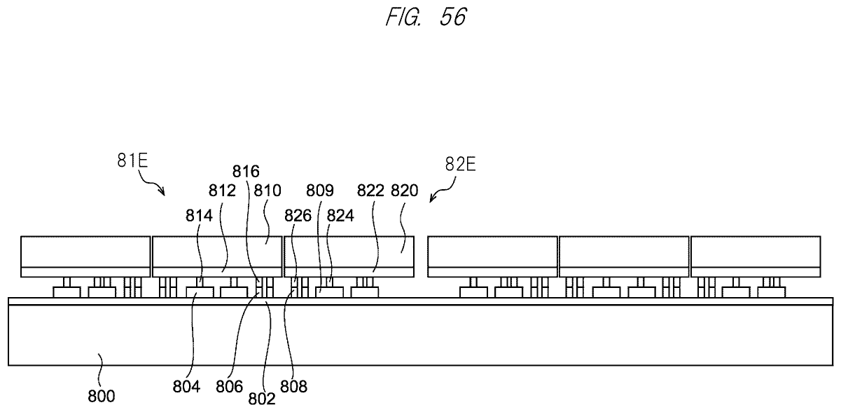

With reference to FIGS. 55 to 60, another modification examples of the method of manufacturing the chip integrated module will be described.

A flat-plate support body 800, a surface of which illustrated in FIG. 55 includes a release film 802 formed thereon, is prepared firstly. Various conductors are formed on the release film 802 (forming step). For the support body, various materials such as glass, silicon, and metal may be employed as needed. For example, pillar connection sections 806 and 808 protruding from the surface of the support body 800 are formed on the release film 802. Further, electrode pads 804 and 809 may be formed on the release film 802.

Next, as illustrated in FIG. 56, a plurality of dies including a first die 81E and a second die 82E are bonded to the various conductors formed on the release film 802. The first die 81E includes a first integrated circuit chip 810, a wiring layer 812 formed thereon, and various electrodes including die electrodes 814 and 816 further formed thereon. Further, the second die 82E includes a second integrated circuit chip 820, a wiring layer 822 formed thereon, and various electrodes including die electrodes 824 and 826 further formed thereon.

In the present embodiment, die electrodes formed in a die are coupled to various conductors (die coupling step). For example, the die electrode 814 and the die electrode 816 in the first die 81E are coupled to the electrode pad 804 and the pillar connection section 806, respectively. Further, the die electrode 824 and the die electrode 826 in the second die 82E are coupled to the electrode pad 809 and the pillar connection section 808, respectively. The die electrodes may be connected to the electrode pad or the pillar connection section via the solder or may be coupled thereto by the hybrid bonding without via the solder.

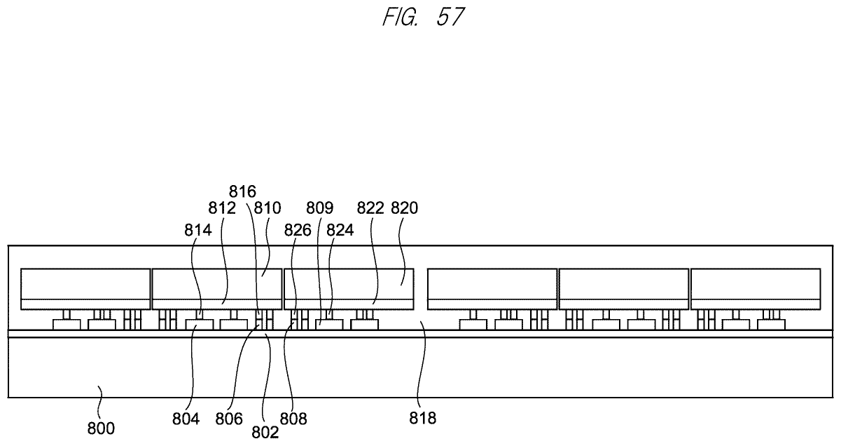

Next, as illustrated in FIG. 57, the various conductors and the plurality of dies that have been formed on the release film 802 are sealed by resin 818 (sealing member) (sealing step). The first die 81E, the second die 82E and the release layer may be sealed before the sealing step using the resin 818 by, for example, injection and hardening based on capillary action (capillary underfill) using a liquid underfill resin or an insulative resin such as non-conductive film (NCF), or these members may be sealed at the same time in the sealing step using the resin 818 (mold underfill). In this manner, the plurality of dies are fixed while being coupled to the pillar connection sections or the metal pads.

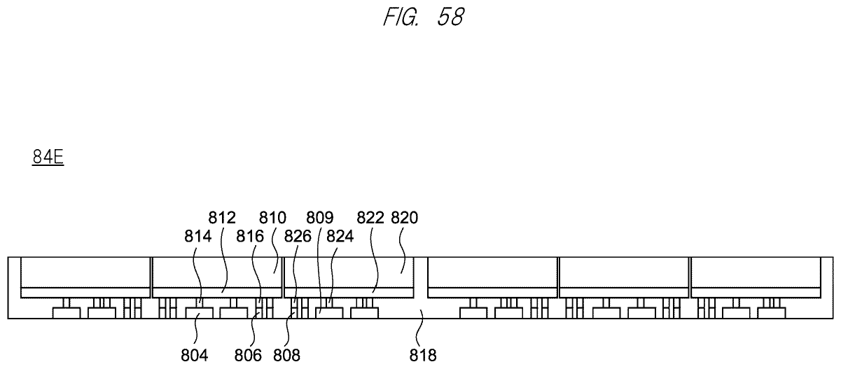

Next, as illustrated in FIG. 58, a processing of removing the release film 802 and the support body 800 and removing the release film remaining on the electrode pads and the like is performed. The method of removing the support body may employ various methods such as a method of mechanically releasing the support body, a method of releasing the release film by laser beam irradiation, or occasionally a method of removing the support body by grinding or etching. In the method by grinding or etching, the release film is occasionally unnecessary. Further, the resin 818 on the surface of the die is ground. In this manner, the die can be exposed. The resin in which various conductors and the plurality of dies are embedded as illustrated in FIG. 58 and which is ground by the method described with reference to FIGS. 55 to 58 will be also referred to as intermediate body 84E below.

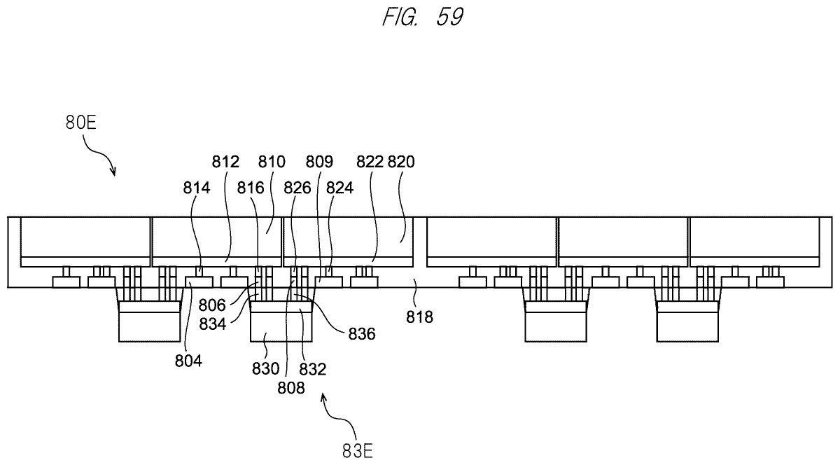

Next, as illustrated in FIG. 59, the bridge is coupled to the plurality of pillar connection sections (bridge coupling step). In the present embodiment, the plurality of dies including a bridge 83E are used as the bridge, and the bridge is coupled to each lower portion of the plurality of pillar connection sections. In the present embodiment, the bridge 83E includes a third integrated circuit chip 830, a wiring layer 832 formed thereon, and bridge electrodes (including bridge electrodes 834 and 836) further formed thereon.

The bridge electrode 834 of the bridge 83E is coupled to the pillar connection section 806 connected to the first die 81E. Further, the bridge electrode 836 of the bridge 83E is bonded to the pillar connection section 808 connected to the second die 82E. In this manner, the bridge 83E functions as the bridge electrically connected to the first die 81E and the second die 82E, and a structure having the feature of the suspended bridge using the pillar is formed. Note that the bridge electrodes may be coupled to the pillar connection sections via the solder or may be coupled thereto by the hybrid bonding without via the solder.

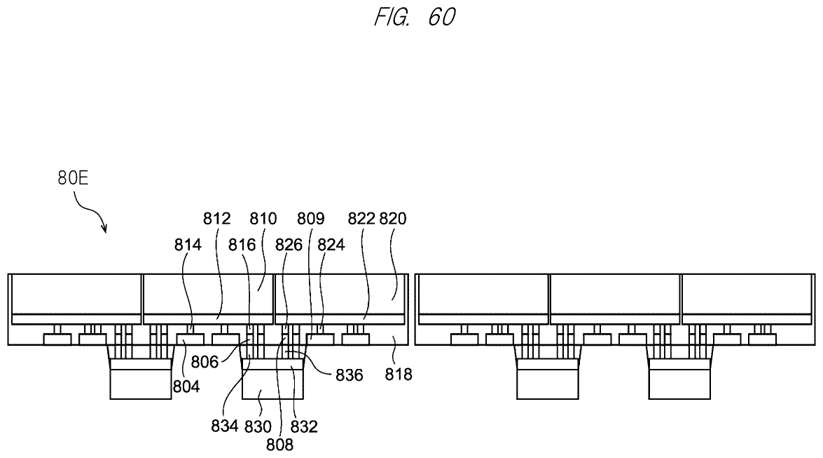

Next, as illustrated in FIG. 60, the resin 818 is cut to be divided into chip integrated modules 80. In this manner, each chip integrated module is individually formed.

In the method of manufacturing the chip integrated module according to the present embodiment, as described with reference to FIG. 57, the first die, the second die, and the pillar connection sections are fixed by the resin, and then, the subsequent steps are performed. Thus, in the subsequent steps, a plurality of dies are not positionally misaligned, and the integrated circuit chips can be connected with higher accuracy. Further, simpler steps and handling are enabled. Furthermore, an external terminals can be directly formed immediately below the integrated circuit chip, and excellent properties in terms of power integrity (PI) and signal integrity (SI) are promising. Moreover, relative positional accuracy of dies can be stably secured irrespective of a size of a module. Thus, the present embodiment can be easily developed to large Panel-Scale chip integration.

### Sixth Modification Example

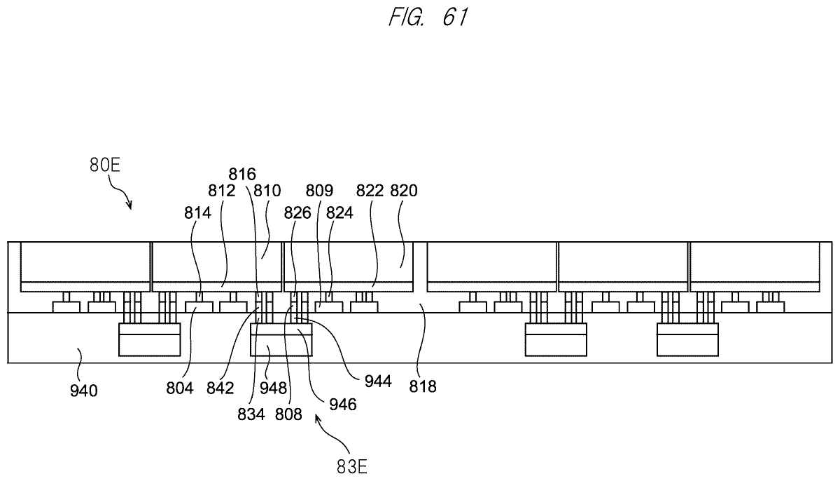

Each of FIGS. 61 to 64 is a diagram for explaining a method of manufacturing a chip integrated module according to a sixth modification example of the method of manufacturing the chip integrated module illustrated in FIGS. 55 to 60. In the sixth modification example, a method of manufacturing a chip integrated module having a similar configuration to that of the chip integrated module 40F according to the second modification example described with reference to FIG. 50 will be described.

Firstly, similarly to the method described above with reference to FIGS. 55 to 58, a plurality of intermediate bodies 84E embedded in the resin 818 are prepared.

A next step will be described with reference to FIG. 61. Firstly, the bridge is connected to the pillar connection section. The bridge according to the sixth modification example includes a wiring layer 946 and an integrated circuit chip 948. The wiring layer 946 includes a wiring (not illustrated in FIG. 61), and the wiring is connected to a plurality of bridge electrodes. The bridge electrodes are connected to the pillar connection section. For example, a bridge electrode 942 is connected to the pillar connection section 806, and a bridge electrode 944 is connected to the pillar connection section 808. In this manner, the bridge electrodes 942 and 944 the wiring layer 946, and the integrated circuit chip function as the bridge.

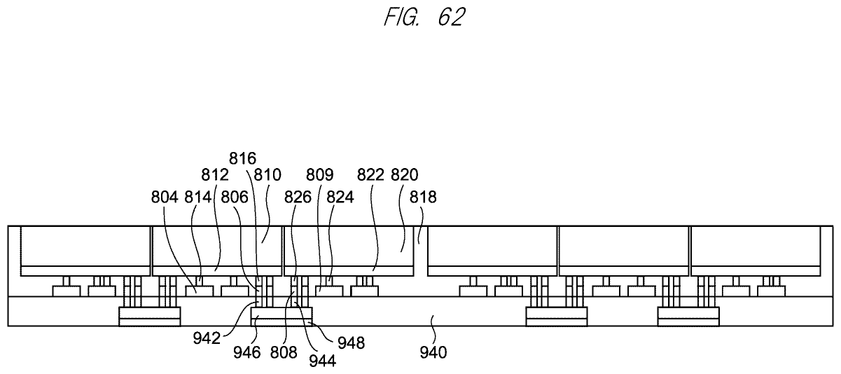

Further, the resin sealing is performed to cover the die electrode, the wiring layer, and the integrated circuit chip (FIG. 61). Furthermore, the integrated circuit chip is exposed by grinding or the like (FIG. 62).

A next step will be described with reference to FIG. 62. In FIG. 61, a lower surface of the integrated circuit chip is covered by resin 940. The lower surface of the integrated circuit chip and the resin 940 on the lower surface are ground. In this manner, as illustrated in FIG. 62, the lower surface of the integrated circuit chip is exposed.

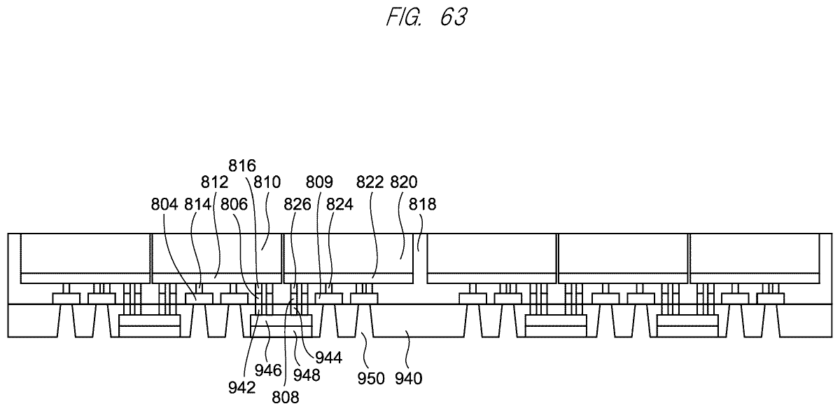

A next step will be described with reference to FIG. 63. In this step, a via opening 950 is formed in the resin 940 in which the integrated circuit chip is embedded. For example, the opening 950 may be formed in the resin by laser irradiation on the resin 940. The opening 950 may be formed such that, for example, the electrode pad 809 connected to the integrated circuit chip is exposed. Further, the via opening 950 may be formed such that its diameter gradually increases downward from the electrode pad 809.

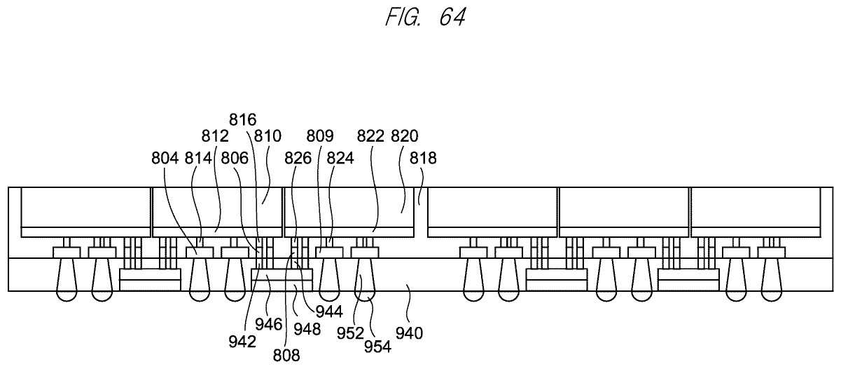

A next step will be described with reference to FIG. 64. In this step, metal is formed on the opening in the resin 940 by, for example, plating or the like, and its end is provided with solder. In this manner, as illustrated in FIG. 64, a deep via 952 provided with solder 954 at its end is formed in the resin 940. Further, the resin 818 and 940 are cut to achieve the divided chip integrated modules with a desired size.

Note that the sixth modification example has been described in the example in which the lower surface of the integrated circuit chip and the resin 940 on the lower surface are ground. However, the present invention is not limited to this example. The opening 950 may be formed without the grinding of the resin 940 or the like, and the deep via provided with solder at its end may be formed. In this manner, the chip integrated module described in the third modification example may be manufactured.

### Seventh Modification Example

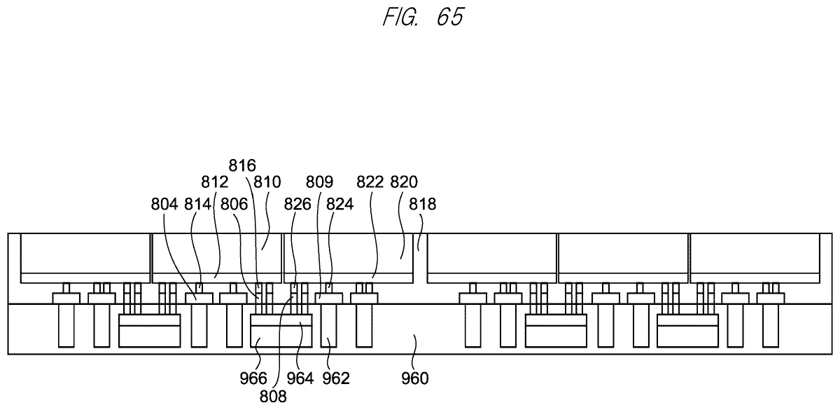

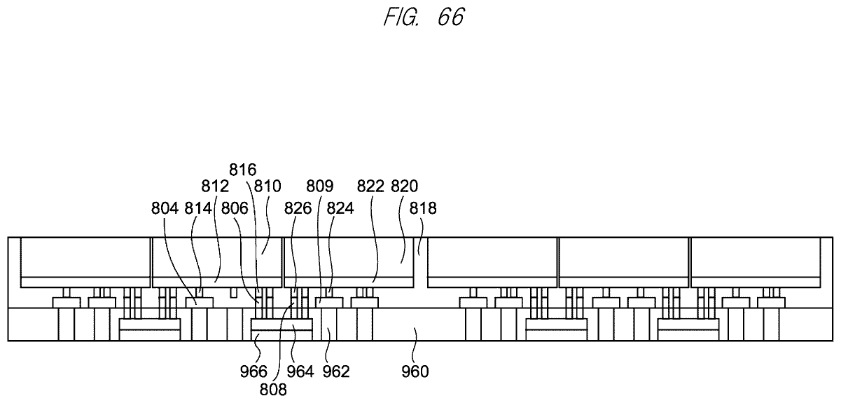

A method of manufacturing a chip integrated module according to a seventh modification example will be described with reference to FIGS. 65 and 66. In the seventh modification example, firstly, the intermediate body 84E is manufactured as described with reference to FIGS. 55 to 58.

A next step will be described with reference to FIG. 65. In this step, a tall pillar 962 is formed in the electrode pad 809 embedded in the resin 818, and the bridge is bonded to the connection section. The bridge according to the seventh modification example includes a wiring layer 964 and an integrated circuit chip 966. The wiring layer 964 includes a wiring, and the bridge electrode provided on a surface of the wiring is connected to the pillar connection sections 806 and 808 to function as the bridge.

Further, the resin sealing is performed to cover the formed bridge coupled to the tall pillar and the pillar connection section formed (FIG. 64). Furthermore, the tall pillar and the bridge are exposed by grinding or the like (FIG. 65).

A next step will be described with reference to FIG. 66. In this step, resin 960 sealing the tall pillar and the bridge, the tall pillar, and the integrated circuit chip are ground. In this manner, as illustrated in FIG. 66, the surfaces of the tall pillar and the integrated circuit chip are exposed on the surface of the resin 960. Further, the resin 818 and 960 are cut to achieve the divided chip integrated modules with a desired size.

### Eighth Modification Example

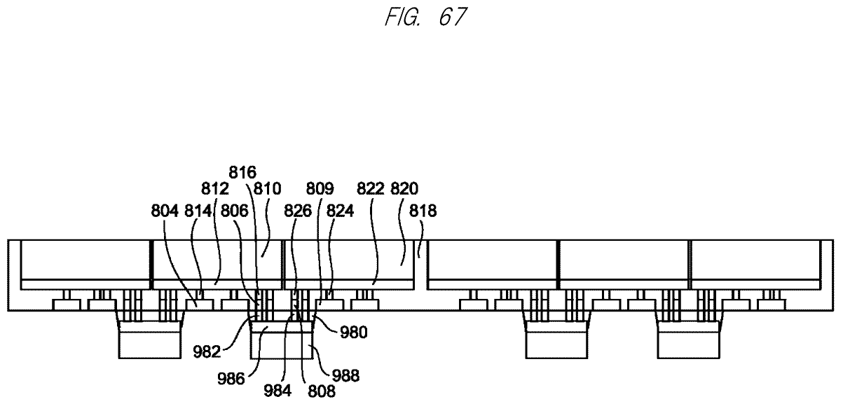

A method of manufacturing a chip integrated module according to an eighth modification example will be described with reference to FIGS. 67 to 69. In the eighth modification example, firstly, the intermediate body 84E is prepared as described with reference to FIGS. 55 to 58.

A next step will be described with reference to FIG. 67. In this step, the bridge is bonded to the connection section embedded in the resin 818. The bridge according to the eighth modification example includes a wiring layer 986 and an integrated circuit chip 988. The wiring layer 986 includes a wiring. The bridge electrode provided on a surface of the wiring is connected to the pillar connection sections 806 and 808 to function the bridge electrode and the wiring layer 986 as the bridge.

Further, the resin sealing is performed to cover the wiring layer 986 and the bridge electrode formed on the wiring layer 986. In this manner, as illustrated in FIG. 67, the bridge is connected to the pillar connection section while the die electrode and the wiring layer 986 are fixed by resin 980.

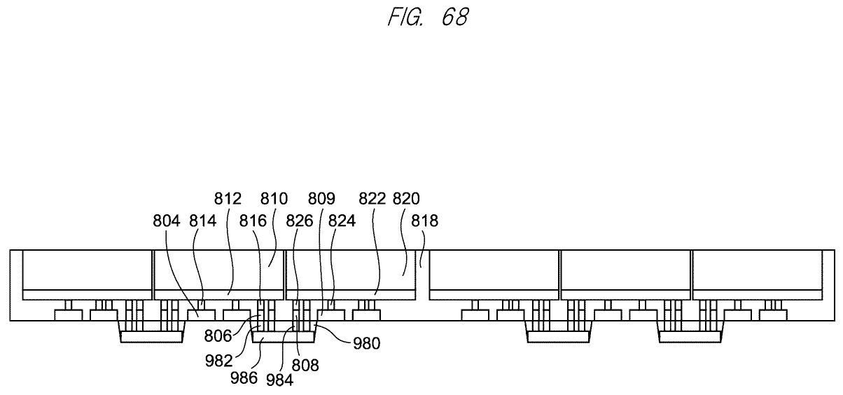

A next step will be described with reference to FIG. 68. In this step, the integrated circuit chip 988 is removed from the wiring layer 986. Further, the resin 818 is cut to manufacture the chip integrated modules with a desired size.

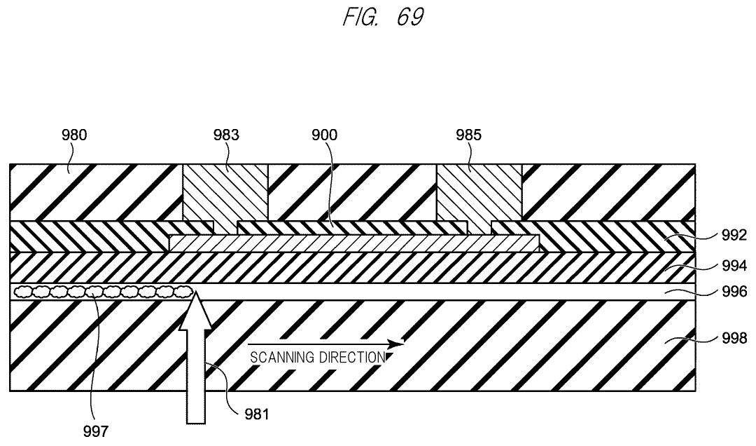

With reference to FIG. 69, a step of removing the integrated circuit chip 988 from the wiring layer 986 will be described in detail. In the eighth modification example, a release layer 996 is provided between the integrated circuit chip 988 and an insulative layer 994. By irradiation with energy particles 981 (such as laser beam) to the release layer 996, at least a part of the release layer 996 can be decomposed (altered). When a region to be irradiated with the energy particles is moved in a scanning direction indicated by an arrow, the release layer 996 can be entirely decomposed. In this manner, the integrated circuit chip 988 can be removed from the insulative layer 994.

Note that this description has been made regarding the example in which the release layer 996 is decomposed by scanning the region to be irradiated with the energy particles. However, the present invention is not limited to this example. The entire release layer 996 may be irradiated with the energy particles at one time without the scanning.

### Method of Manufacturing Optical Module

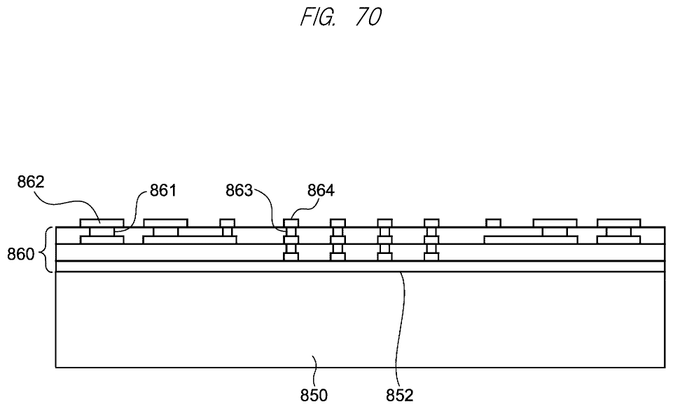

With reference to FIGS. 70 to 74, a method of manufacturing an optical module according to one embodiment of the present invention will be described.

Firstly, a support body 850, a surface of which includes a release layer 852 formed thereon, is prepared. Next, as illustrated in FIG. 70, a wiring layer 860 is formed on the surface of the release layer 852. The wiring layer 860 may have a two-layer structure. More specifically, the wiring layer 860 may have substantially the same structure as that of the wiring layer 630 described with reference to FIG. 5. In the present embodiment, a plurality of conductor vias are formed in an upper layer of the wiring layer 630, and electrodes are coupled to the conductor vias, respectively. For example, a conductor via 861 is coupled with an electrode 862 connected with a conductor post, and a conductor via 863 is coupled with an electrode 864 connected with an optical element driving chip.

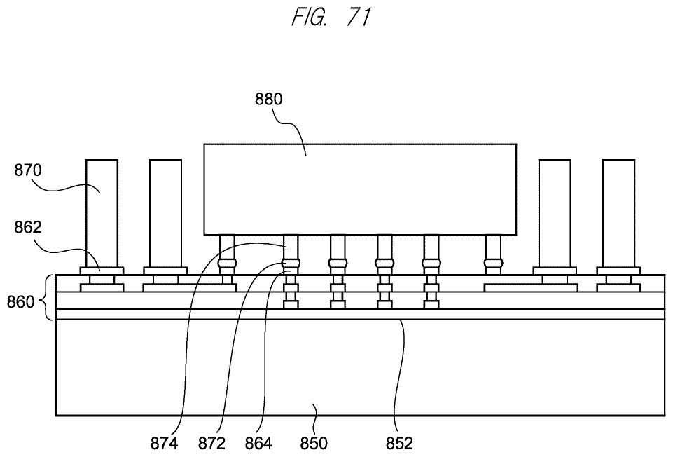

Next, as illustrated in FIG. 71, a conductor post 870 and an optical element driving chip 880 are coupled to electrodes. For example, the conductor post 870 is coupled to the electrode 862. Further, the optical element driving chip 880 includes a plurality of electrode terminals 874. The electrode terminal 874 is connected via solder 782 to an electrode 872 formed on the surface of the wiring layer 860.

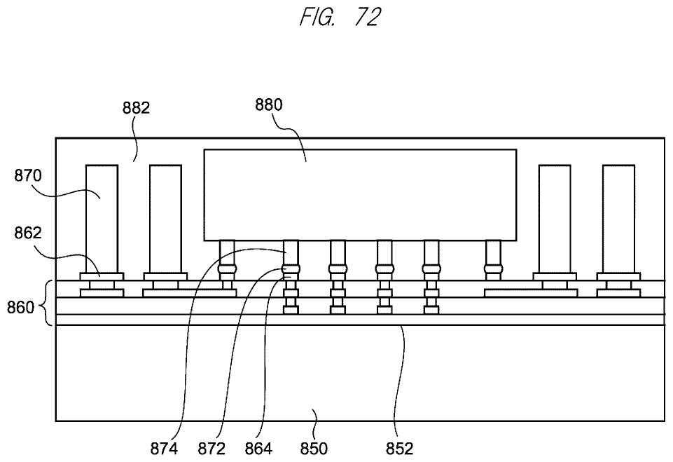

Next, as illustrated in FIG. 72, the plurality of conductor posts 870 and the optical element driving chip 880 are sealed by resin 882. In this manner, the plurality of conductor posts 870 and the optical element driving chip 880 are fixed.

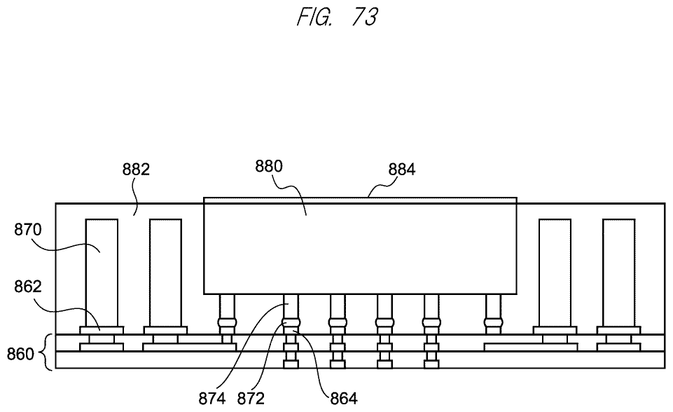

Next, a processing of removing the release layer 852 and the support body 850 and removing the release layer 852 remaining on a lower surface of the wiring layer 860 is performed. Further, an upper surface of the resin 882 is ground to form a metal layer 884 on an upper surface of the optical element driving chip 880 as illustrated in FIG. 73.

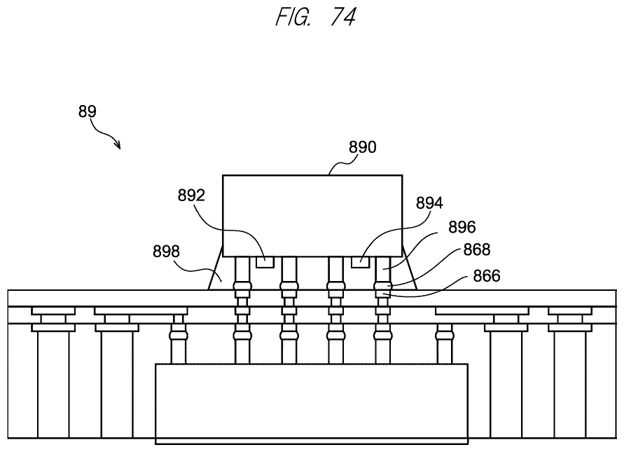

Next, as illustrated in FIG. 74, the entire structure is flipped upside down such that the metal layer 884 is a lower surface, and an optical element chip 890 is bonded to an upper surface of the wiring layer 860. The optical element chip 890 is provided with a light emitting element 892, a light receiving element 894, and a plurality of electrode terminals 896. The electrode terminals 896 are bonded to electrodes 866 of the wiring layer 860 via solder 868, respectively, and thus, the optical element chip 890 is bonded to the wiring layer 860. Further, a lower side of the optical element chip 890, the light emitting element 892, the light receiving element 894, and the plurality of electrode terminals 896 are sealed by resin 898. In this manner, an optical module 89 is manufactured.

### Modification Example of Method of Manufacturing Chip Integrated Body

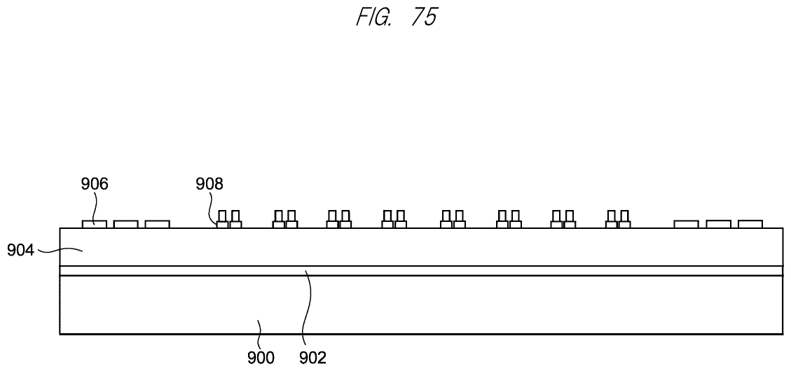

With reference to FIGS. 75 to 79, a method of manufacturing a chip integrated body according to another embodiment will be described.

Firstly, as illustrated in FIG. 75, a support body 900, a surface of which includes a release layer 902 formed thereon, is prepared, and various conductors are formed on a surface of the release layer 902. Specifically, an electrode 906 connected with the conductor post, a pillar connection section 908 (tall pillar) connected with the chip integrated module, and the like are formed.

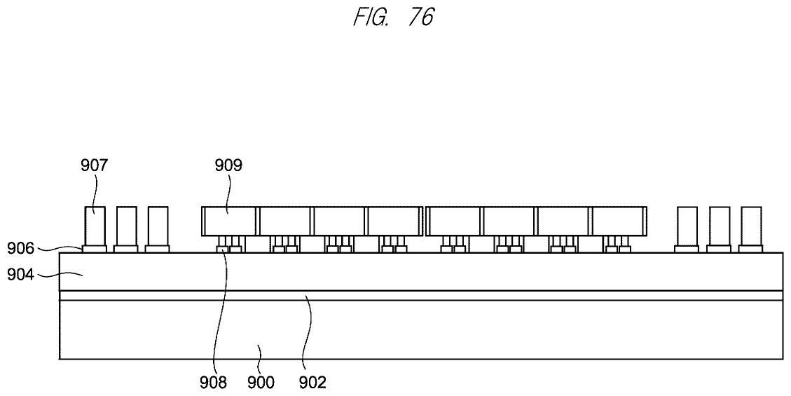

Next, as illustrated in FIG. 76, various members are formed on the various conductors formed on the release layer 902. For example, a conductor post 907 may be formed on an electrode 906, or a chip integrated modules 909 may be connected to the pillar connection section 908. The chip integrated module 909 may be connected to the pillar connection section 908 by solder provided on the pillar connection section 908. When the bridge of the chip integrated module is sufficiently thin, the pillar connection section 908 may be replaced with a lower solder bump.

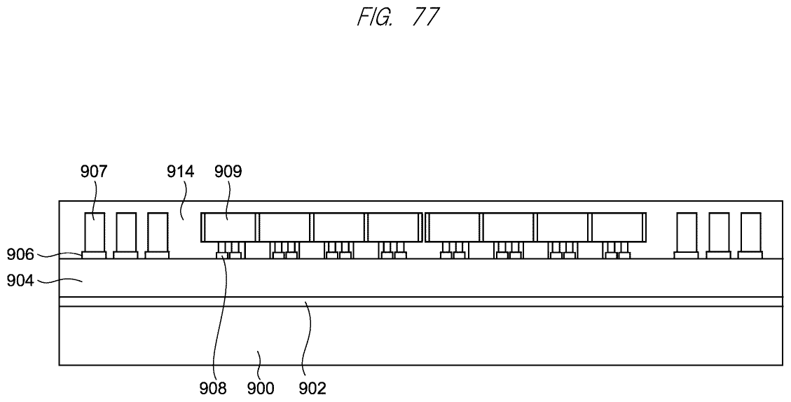

Next, as illustrated in FIG. 77, the formed various members are sealed by resin. Specifically, the conductor post 907, the pillar connection section 908, the chip integrated module 909, and the like may be sealed by resin 914. Then, the support body 900 is removed together with the release layer 902 from a wiring layer 904. Further, the resin 914 is ground such that the conductor post 907 and the chip integrated module 909 are exposed.

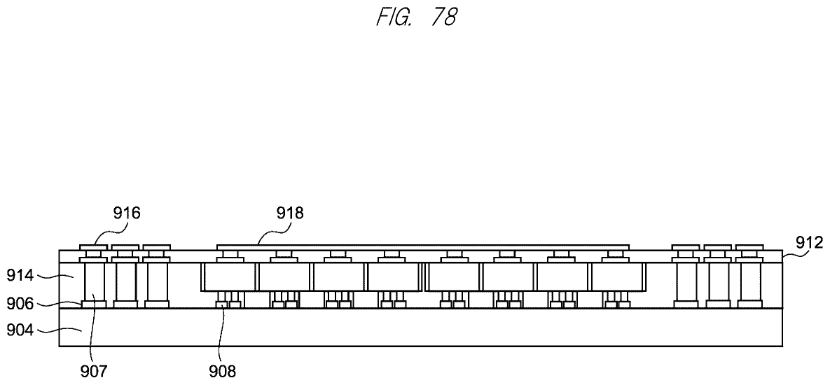

Next, as illustrated in FIG. 78, a wiring layer 912 is formed on the resin 914. More specifically, the wiring layer 912 is formed on the resin 914 such that a wiring included in the wiring layer 912 is connected to an exposed part of the conductor post 907 or an exposed part of the chip integrated module 909. For example, an electrode 916 formed on the wiring layer 912 may be connected to the conductor post 907 via a conductor via. Further, a contact metal 918 may be connected to the chip integrated module 909 via the conductor via.

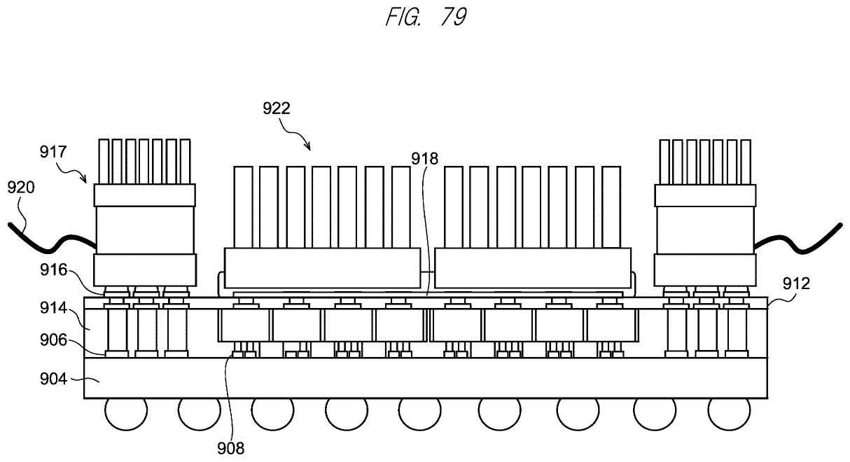

Next, as illustrated in FIG. 79, a heat radiating mechanism 922 is mounted on the contact metal 918. Further, an optical module 917 connected with an optical wiring 920 is connected to the electrode 916. In this manner, a chip integrated body according to the present embodiment is manufactured.

### Integrated Circuit Chip

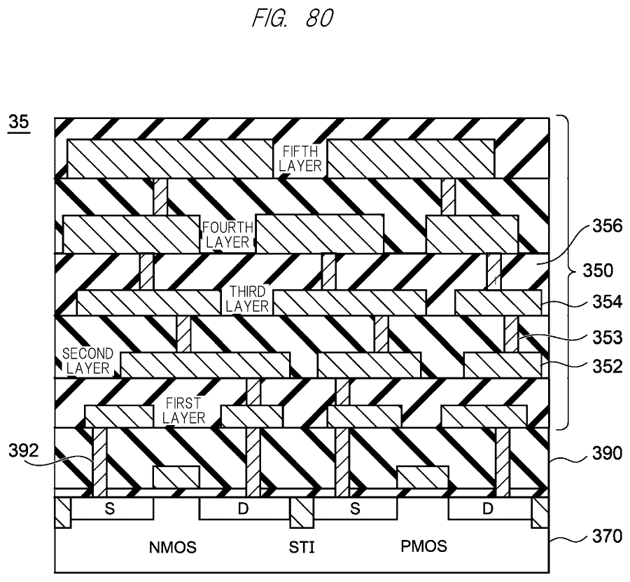

FIG. 80 is a diagram illustrating an exemplary configuration of an integrated circuit chip according to one embodiment. An integrated circuit chip 35 includes a wiring layer 350, a transistor 370, and a connection layer 390 connecting the wiring layer 350 and the transistor 370.

The wiring layer 350 has a stacked structure of five layers, and each layer includes: a film insulating the layers; a wiring embedded in the film; and a via connecting wirings of layers that are adjacent to each other in the up and down direction. For example, a wiring 352 of the second layer and a wiring 354 of the third layer are connected to each other via a via 353, and the wiring 354 is embedded in an insulative film 356. The film of each layer may be made of boron-phosphorous silicate glass (BPSG) or the like. The wiring of each layer may be made of a metal such as copper. Note that the wirings of upper layers (such as the fifth layer and the fourth layer) serve as power source or ground, and thus, may not be always finer than the wirings of the other layers.

Some typical embodiments have been described above with reference to the drawings. However, the above-described embodiments and modification examples additionally include various modification examples. A part of the embodiments may be changed as needed within the scope consistent with the above description. Further, for example, combination of a part of the embodiments and modification examples with a part of another embodiment is applicable.

The above embodiments have been described mainly in the example in which the various pillar connection sections face in the substantially vertical direction of the surface of the die. The present invention is not limited to this example. The various pillar connection sections may face in any direction heading toward other dies. Further, various dimensions, cross-sectional shapes, aspect ratios (ratio between the dimension in the cross-sectional direction and the dimension in the direction perpendicular to this direction), and the like may be set as needed, depending on demands for performance, reliability and the like, selectable manufacture processes, and the like.

The above embodiments have been described mainly in the example in which the bridge, if including the chip, mainly includes the wiring, via which the chip is electrically connected to the bridge electrode. The present invention is not limited to this example. The bridge may not include the wiring, and the chip may be directly connected to the bridge electrode.

Further, the above embodiments have been described mainly in the example in which the various dies (such as the first die and the second die) include the wirings. The present invention is not limited to this example. The die may not include the wiring. In this case, the integrated circuit chip of the die may be directly connected to the die electrode.

In the above embodiment, the thin wiring layer formed on the support body 900 is used as the wiring 904. However, the wiring 904 is not only this but also may be any of various well-known interposer or wiring substrate.

### INDUSTRIAL APPLICABILITY

The present invention is widely applicable to a semiconductor module and the like.

While the present disclosure has been illustrated and described with respect to a particular embodiment thereof, it should be appreciated by those of ordinary skill in the art that various modifications to this disclosure may be made without departing from the spirit and scope of the present disclosure.

1. A method of manufacturing a semiconductor module, comprising steps of:
(a) on a first surface of a first support body, forming a first connection section including a first pillar connection section extending in an out-of-surface direction of the first surface and a second connection section including a second pillar connection section extending in an out-of-surface direction of the first surface;
(b) preparing a first semiconductor die including a first IC chip and a first die electrode connected to the first IC chip and a second semiconductor die including a second IC chip and a second die electrode connected to the second IC chip, and mounting the first semiconductor die and the second semiconductor die on the first support body such that the first die electrode is arranged on the first connection section while the second die electrode is arranged on the second connection section;
(c) after the step (b), sealing the first semiconductor die, the second semiconductor die, the first connection section, and the second connection section by a first sealing body;
(d) after the step (c), removing the first support body, and exposing a part of the first pillar connection section and a part of the second pillar connection section from the first sealing body; and
(e) preparing a bridge including a first bridge electrode connected to the first connection section and a second bridge electrode connected to the second connection section, and after the step (d), mounting the bridge on a structure sealed by the first sealing body such that the first bridge electrode is arranged on the first pillar connection section while the second bridge electrode is arranged on the second pillar connection section.

2. The method of manufacturing the semiconductor module according to claim 1, further comprising a step of:
(f) after the step (e), sealing the first bridge electrode and the second bridge electrode by a second sealing body.

3. The method of manufacturing the semiconductor module according to claim 2,
wherein the first sealing body contains a plurality of first filler particles,
the second sealing body contains a plurality of second filler particles, and
an average particle diameter of the plurality of first filler particles is larger than an average particle diameter of the plurality of second filler particles.

4. The method of manufacturing the semiconductor module according to claim 1,
wherein, in the step (a), the first connection section and the second connection section are formed on a seed layer that is a base, and
in the step (b), a side surface of the first connection section and a side surface of the second connection section are covered with an oxide film.

5. The method of manufacturing the semiconductor module according to claim 4,
wherein, in the step (b),
the first die electrode is bonded to the first connection section via a solder material, and
the second die electrode is bonded to the second connection section via a solder material.

6. The method of manufacturing the semiconductor module according to claim 4,
wherein, in the step (e),
the first bridge electrode is bonded to the first connection section via a solder material, and
the second bridge electrode is bonded to the second connection section via a solder material.

7. The method of manufacturing the semiconductor module according to claim 1,
wherein, in the step (e) of preparing the bridge further includes steps of:
(e1) sequentially stacking a first insulative layer, a wiring, and a second insulative layer on a second support body;
(e2) after the step (e1), bonding a substrate and the second insulative layer on the second support body via a third insulative layer thicker than the second insulative layer;
(e3) after the step (e2), removing the second support body; and
(e4) after the step (e3), on the first insulative layer, forming the first bridge electrode and the second bridge electrode which are electrically connected to the wiring.

8. A method of manufacturing a semiconductor module, comprising steps of:
(a) forming a first insulative layer on a first surface of a first support body, and then, forming a first opening and a second opening in the first insulative layer;
(b) forming a first connection section including a first pillar connection section formed inside the first opening and a second connection section including a second pillar connection section formed inside the second opening;
(c) preparing a first semiconductor die including a first IC chip, a first die electrode connected to the first IC chip, and a second insulative layer sealing the first die electrode, and a second semiconductor die including a second IC chip, a second die electrode connected to the second IC chip, and a third insulative layer sealing the second die electrode, and mounting the first semiconductor die and the second semiconductor die on the first support body such that the first die electrode is arranged on the first connection section while the second die electrode is arranged on the second connection section;
(d) after the step (c), sealing the first semiconductor die and the second semiconductor die by a first sealing body;
(e) after the step (d), removing the first support body, and exposing a part of the first pillar connection section and a part of the second pillar connection section from the first insulative layer; and
(f) preparing a bridge including a first bridge electrode connected to the first connection section and a second bridge electrode connected to the second connection section, and after the step (e), mounting the bridge on a structure sealed by the first sealing body such that the first bridge electrode is arranged on the first pillar connection section while the second bridge electrode is arranged on the second pillar connection section,
wherein, in the step (c),
the first insulative layer and the second insulative layer are bonded to each other while the first die electrode is sealed by the first insulative layer and the second insulative layer, and
the first insulative layer and the third insulative layer are bonded to each other while the second die electrode is sealed by the first insulative layer and the third insulative layer.

9. The method of manufacturing the semiconductor module according to claim 8,
wherein, in the step (b),
the first die electrode is bonded to the first connection section via a solder material, and
the second die electrode is bonded to the second connection section via a solder material.

10. The method of manufacturing the semiconductor module according to claim 9,
wherein the bridge prepared in the step (f) further includes a fourth insulative layer sealing a part of the first bridge electrode and a part of the second bridge electrode, and
in the step (f),
the first bridge electrode is bonded to the first connection section via a solder material,
the second bridge electrode is bonded to the second connection section via a solder material, and
the first insulative layer and the fourth insulative layer are bonded to each other.

11. A semiconductor module comprising:
a first semiconductor die including a first IC chip and a first die electrode connected to the first IC chip;
a second semiconductor die including a second IC chip and a second die electrode connected to the second IC chip;
a first connection section electrically connected to the first die electrode;
a second connection section electrically connected to the second die electrode;
a bridge including a first bridge electrode connected to the first connection section and a second bridge electrode connected to the second connection section; and
a first sealing body sealing the first semiconductor die and the second semiconductor die;
wherein the first connection section includes a first pillar connection section which is arranged between the first semiconductor die and the bridge and which extends in a direction from one of the first semiconductor die and the bridge toward the other of the first semiconductor die and the bridge,
the second connection section includes a second pillar connection section which is arranged between the second semiconductor die and the bridge and which extends in a direction from one of the second semiconductor die and the bridge toward the other of the first second semiconductor die and the bridge,
the first bridge electrode and the second bridge electrode are exposed from the first sealing body, and
the first pillar connection section and the second pillar connection section are sealed by the first sealing body.

12. The semiconductor module according to claim 11,
wherein the first bridge electrode and the second bridge electrode are sealed by a second sealing body.

13. The semiconductor module according to claim 11,
wherein the first sealing body contains a plurality of first filler particles,
the second sealing body contains a plurality of second filler particles, and
an average particle diameter of the plurality of first filler particles is larger than an average particle diameter of the plurality of second filler particles.

14. The semiconductor module according to claim 11,
wherein a side surface of the first connection section and a side surface of the second connection section are covered with an oxide film.

15. The semiconductor module according to claim 11,
wherein the bridge includes:
a chip;
a first insulative layer, a second insulative layer, and a third insulative layer which are sequentially staked on the chip, and
a wiring which is sandwiched between the second insulative layer and the third insulative layer and which is connected to the first bridge electrode and the second bridge electrode, and
a thickness of the first insulative layer is larger than a thickness of the second insulative layer.

16. An electronic apparatus comprising:
a first die including a first electrode;
a second die including a second electrode;
a first connection section electrically connected to the first electrode;
a second connection section electrically connected to the second electrode; and
a bridge electrically connected to the first connection section and the second connection section,
wherein the first connection section includes a pillar connection section facing in a direction from the bridge toward the first die.

17. The electronic apparatus according to claim 16,
wherein the pillar connection section includes:
a first pillar connection section facing in a direction from the bridge toward the first electrode; and
a second pillar connection section which is connected to an end of the first pillar connection section and which faces in a direction from the end of the first pillar connection section toward the first electrode, and
a cross-sectional area of a part of the first pillar connection section, the part being connected to the second pillar connection section, is larger than a cross-sectional area of a part of the second pillar connection section, the part being connected to the first pillar connection section.

18. The electronic apparatus according to claim 16, further comprising:
a sealing member collectively sealing the first die and the second die, the first connection section and the second connection section.

19. The electronic apparatus according to claim 16 further comprising:
a first sealing member collectively sealing the first die and the second die; and
a second sealing member collectively sealing the first connection section and the second connection section.

20. The electronic apparatus according to claim 16,
wherein the bridge is connected to the pillar connection section via solder.

21. The electronic apparatus according to claim 16,
wherein the first die is connected to the first connection section by hybrid bonding,
the second die is connected to the second connection section by hybrid bonding, and
the first die and the second die are collectively sealed by a sealing member.

22. An electronic module comprising:
the electronic apparatus according to claim 16;
a wiring layer provided with a wiring therein; and
a connection section electrically connecting the wiring and the electronic apparatus.

23. The electronic module according to claim 22,
wherein the first die includes a third electrode to which a third connection section is electrically connected,
the first die, the third electrode, and the third connection section are collectively sealed by a sealing member, and
the third connection section penetrates through the sealing member, and is connected to the wiring layer.

24. A method of manufacturing an electronic apparatus, comprising:
a forming step of, on a support body, forming a first connection section including a pillar connection section protruding from the support body, and a second connection section;
a die coupling step of coupling a first electrode of a first die to the first connection section, and coupling a second electrode of a second die to the second connection section;
a sealing step of sealing the first die, the second die, and the first connection section by resin; and
a bridge coupling step of coupling a bridge to a lower part of the first connection section and a lower part of the second connection section.

25. The method of manufacturing the electronic apparatus according to claim 24,
wherein the first connection section includes a first pillar connection section and a second pillar connection section,
the forming step includes:
a step of forming the first connection section on the support body such that the first connection section protrudes from the support body toward the first die; and
a step of forming a second connection section on the first connection section such that the second pillar connection section protrudes from the first pillar connection section toward the first die,
a cross-sectional area of a part of the first pillar connection section, the part being connected to the second pillar connection section, is larger than a cross-sectional area of a part of the second pillar connection section, the part being connected to the first pillar connection section, and
the die coupling step includes a step of connecting the first die to the second pillar connection section.
